(19) United States
(12) Patent Application Publication
(10) Pub. No.: US 2026/0333870 A1
(43) Pub. Date: Oct. 22, 2026

(54) ARRAY SUBSTRATE, DISPLAY PANEL, AND DISPLAY DEVICE

(71) Applicant: Xiamen Tianma Optoelectronics Co., Ltd., Xiamen (CN)

(72) Inventors: Wenqing LIN, Xiamen (CN); Wenxing XI, Xiamen (CN); Jixiang CHEN, Xiamen (CN); Wenjing ZHU, Xiamen (CN)

(21) Appl. No.: 19/407,371

(22) Filed: Dec. 3, 2025

(30) Foreign Application Priority Data
Apr. 18, 2025 (CN) 202510494462.1
Jul. 29, 2025 (CN) 202511052817.8

(51) Int. Cl. H10D 86/40; G02F 1/1362; G02F 1/1368

(52) U.S. Cl. CPC H10D 86/441; G02F 1/136227; G02F 1/1368

(57) ABSTRACT

The present disclosure provides an array substrate, a display panel, and a display device. The array substrate includes a substrate, a first metal layer, a first conductive layer, a first insulating layer and a second conductive layer. The first metal layer includes metal patterns; the first conductive layer includes blocking patterns; a first type through-hole exposes at least a portion of a blocking pattern; and the second conductive layer includes conductive patterns. A conductive pattern is electrically connected to the blocking pattern and a metal pattern, respectively; the conductive pattern is in a contact with the blocking pattern at least through the first type through-hole; and along a first direction, the conductive pattern, the blocking pattern, and the metal pattern are overlapped with each other; and the first direction is perpendicular to a plane of the substrate.

### CROSS-REFERENCE TO RELATED APPLICATION

The present disclosure claims the priority of Chinese Patent Application No. 202510494462.1, filed on Apr. 18, 2025, and No. 202511052817.8, filed on Jul. 29, 2025, the content of all of which is incorporated herein by reference in their entirety.

### TECHNICAL FIELD

The present disclosure generally relates to the field of display technology and, more particularly, relates to an array substrate, a display panel, and a display device.

### BACKGROUND

A liquid-crystal display device mainly includes a liquid-crystal display panel and a backlight module. The liquid-crystal display panel may not emit light itself, and the backlight module may provide the liquid-crystal display panel with a backlight source. The liquid-crystal display panel may adjust the amount of light emitted by each sub-pixel to achieve display.

The liquid-crystal display panel may include an array substrate. Current design of the array substrate has reliability problems and needs further improvement.

### SUMMARY

One aspect of the present disclosure provides an array substrate. The array substrate includes a substrate; a first metal layer, on a side of the substrate, where the first metal layer includes metal patterns; a first conductive layer, on a side of the first metal layer away from the substrate, where the first conductive layer includes blocking patterns; a first insulating layer, on a side of the first conductive layer away from the substrate, where the first insulating layer is configured with first type through-holes; and a first type through-hole exposes at least a portion of a blocking pattern; and a second conductive layer, on a side of the first insulating layer away from the substrate. The second conductive layer includes conductive patterns; a conductive pattern is electrically connected to the blocking pattern and a metal pattern, respectively; the conductive pattern is in a contact with the blocking pattern at least through the first type through-hole; along a first direction, the conductive pattern, the blocking pattern, and the metal pattern are overlapped with each other; and the first direction is perpendicular to a plane of the substrate.

Another aspect of the present disclosure provides an array substrate. The array substrate includes a substrate; a source-drain electrode layer and a first conductive layer, configured in separate layers, where the source-drain electrode layer and the first conductive layer are both on a side of the substrate; the source-drain electrode layer includes a first electrode and a second electrode of a thin-film transistor; and the first conductive layer includes a pixel electrode which is in a direct contact with the first electrode of the thin-film transistor; a first insulating layer, on a side of the source-drain electrode layer and the first conductive layer away from the substrate, where the first insulating layer includes first through-holes; along a first direction, a first through-hole is overlapped with both the pixel electrode and the first electrode of the thin-film transistor; the first direction is a direction perpendicular to a plane of the substrate; and the first through-hole exposes at least a portion of the pixel electrode; and a second conductive layer, on a side of the first insulating layer away from the substrate, where the second conductive layer includes a first conductive sub-portion; at least a portion of the first conductive sub-portion is in the first through-hole and in a contact with the pixel electrode.

Another aspect of the present disclosure provides a display panel including an array substrate. The array substrate includes a substrate; a first metal layer, on a side of the substrate, where the first metal layer includes metal patterns; a first conductive layer, on a side of the first metal layer away from the substrate, where the first conductive layer includes blocking patterns; a first insulating layer, on a side of the first conductive layer away from the substrate, where the first insulating layer is configured with first type through-holes; and a first type through-hole exposes at least a portion of a blocking pattern; and a second conductive layer, on a side of the first insulating layer away from the substrate. The second conductive layer includes conductive patterns; a conductive pattern is electrically connected to the blocking pattern and a metal pattern, respectively; the conductive pattern is in a contact with the blocking pattern at least through the first type through-hole; along a first direction, the conductive pattern, the blocking pattern, and the metal pattern are overlapped with each other; and the first direction is perpendicular to a plane of the substrate. The array substrate further includes a counter substrate and a liquid-crystal layer, where the liquid-crystal layer is between the array substrate and the counter substrate.

Another aspect of the present disclosure provides a display device including the display panel mentioned above.

Other aspects of the present disclosure may be understood by those skilled in the art in the light of the description, the claims, and the drawings of the present disclosure.

### BRIEF DESCRIPTION OF THE DRAWINGS

To clearly explain embodiments of the present disclosure or the technical solutions in the existing technology, the drawings needed for describing embodiments or the existing technology are briefly introduced hereinafter. Obviously, the drawings in the following description are merely embodiments of the present disclosure. Other drawings may also be obtained by those skilled in the art without any creative work according to provided drawings.

FIG. 1 illustrates a top-view structural schematic of an array substrate according to various embodiments of the present disclosure.

FIG. 2 illustrates an enlarged structural schematic of a Q0 region in FIG. 1.

FIG. 3 illustrates a cross-sectional structural schematic of an array substrate along a cross-sectional line O1-P1 in FIG. 2.

FIG. 4 illustrates an enlarged structural schematic of a Q1 region in FIG. 1.

FIG. 5 illustrates a cross-sectional structural schematic of an array substrate along a cross-sectional line A1-B1 in FIG. 4.

FIG. 6 illustrates another enlarged structural schematic of a Q1 region in FIG. 1.

FIG. 7 illustrates a cross-sectional structural schematic of an array substrate along a cross-sectional line E1-F1 in FIG. 6.

FIG. 8 illustrates another enlarged structural schematic of a Q1 region in FIG. 1.

FIG. 9 illustrates a cross-sectional structural schematic of an array substrate along a cross-sectional line E2-F2 in FIG. 8.

FIG. 10 illustrates an enlarged structural schematic of a Q2 region in FIG. 1.

FIG. 11 illustrates a cross-sectional structural schematic of an array substrate along a cross-sectional line C1-D1 in FIG. 10.

FIG. 12 illustrates another enlarged structural schematic of a Q2 region in FIG. 1.

FIG. 13 illustrates a cross-sectional structural schematic of an array substrate along a cross-sectional line C2-D2 in FIG. 12.

FIG. 14 illustrates another enlarged structural schematic of a Q2 region in FIG. 1.

FIG. 15 illustrates a cross-sectional structural schematic of an array substrate along a cross-sectional line C3-D3 in FIG. 14.

FIG. 16 illustrates another enlarged structural schematic of a Q2 region in FIG. 1.

FIG. 17 illustrates a cross-sectional structural schematic of an array substrate along a cross-sectional line C4-D4 in FIG. 16.

FIG. 18 illustrates another enlarged structural schematic of a Q2 region in FIG. 1.

FIG. 19 illustrates a cross-sectional structural schematic of an array substrate along a cross-sectional line C5-D5 in FIG. 18.

FIG. 20 illustrates another enlarged structural schematic of a Q2 region in FIG. 1.

FIG. 21 illustrates a cross-sectional structural schematic of an array substrate along a cross-sectional line C6-D6 in FIG. 20.

FIG. 22 illustrates a flowchart of a formation process of an array substrate according to various embodiments of the present disclosure.

FIG. 23 illustrates another enlarged structural schematic of a Q1 region in FIG. 1.

FIG. 24 illustrates a cross-sectional structural schematic of an array substrate along a cross-sectional line A2-B2 in FIG. 23.

FIG. 25 illustrates another enlarged structural schematic of a Q2 region in FIG. 1.

FIG. 26 illustrates a cross-sectional structural schematic of an array substrate along a cross-sectional line C7-D7 in FIG. 25.

FIG. 27 illustrates another enlarged structural schematic of a Q2 region in FIG. 1.

FIG. 28 illustrates a cross-sectional structural schematic of an array substrate along a cross-sectional line C8-D8 in FIG. 27.

FIG. 29 illustrates another enlarged structural schematic of a Q2 region in FIG. 1.

FIG. 30 illustrates a cross-sectional structural schematic of an array substrate along a cross-sectional line C9-D9 in FIG. 29.

FIG. 31 illustrates another enlarged structural schematic of a Q2 region in FIG. 1.

FIG. 32 illustrates a cross-sectional structural schematic of an array substrate along a cross-sectional line C10-D10 in FIG. 31.

FIG. 33 illustrates another enlarged structural schematic of a Q2 region in FIG. 1.

FIG. 34 illustrates a cross-sectional structural schematic of an array substrate along a cross-sectional line C11-D11 in FIG. 33.

FIG. 35 illustrates another enlarged structural schematic of a Q2 region in FIG. 1.

FIG. 36 illustrates a cross-sectional structural schematic of an array substrate along a cross-sectional line C12-D12 in FIG. 35.

FIG. 37 illustrates a circuit principle diagram of an electrostatic protection circuit in an array substrate according to various embodiments of the present disclosure.

FIG. 38 illustrates a layout structural schematic of an electrostatic protection circuit in FIG. 37.

FIG. 39 illustrates another top-view structural schematic of an array substrate according to various embodiments of the present disclosure.

FIG. 40 illustrates an enlarged structural schematic of a Q3 region in FIG. 39.

FIG. 41 illustrates a cross-sectional structural schematic of an array substrate along a cross-sectional line C13-D13 in FIG. 40.

FIG. 42 illustrates an enlarged structural schematic of a Q4 region in FIG. 1.

FIG. 43 illustrates another enlarged structural schematic of a Q1 region in FIG. 1.

FIG. 44 illustrates a cross-sectional structural schematic of an array substrate along a cross-sectional line E3-F3 in FIG. 43.

FIG. 45 illustrates another flowchart of a formation process of an array substrate according to various embodiments of the present disclosure.

FIG. 46 illustrates another enlarged structural schematic of a Q1 region in FIG. 1.

FIG. 47 illustrates a cross-sectional structural schematic of an array substrate along a cross-sectional line E4-F4 in FIG. 46.

FIG. 48 illustrates another enlarged structural schematic of a Q1 region in FIG. 1.

FIG. 49 illustrates a cross-sectional structural schematic of an array substrate along a cross-sectional line E5-F5 in FIG. 48.

FIG. 50 illustrates another enlarged structural schematic of a Q2 region in FIG. 1.

FIG. 51 illustrates a cross-sectional structural schematic of an array substrate along a cross-sectional line C14-D14 in FIG. 50.

FIG. 52 illustrates another enlarged structural schematic of a Q2 region in FIG. 1.

FIG. 53 illustrates a cross-sectional structural schematic of an array substrate along a cross-sectional line C15-D15 in FIG. 52.

FIG. 54 illustrates another enlarged structural schematic of a Q1 region in FIG. 1.

FIG. 55 illustrates a cross-sectional structural schematic of an array substrate along a cross-sectional line A3-B3 in FIG. 54.

FIG. 56 illustrates another enlarged structural schematic of a Q1 region in FIG. 1.

FIG. 57 illustrates a cross-sectional structural schematic of an array substrate along a cross-sectional line A4-B4 in FIG. 56.

FIG. 58 illustrates another enlarged structural schematic of a Q2 region in FIG. 1.

FIG. 59 illustrates a cross-sectional structural schematic of an array substrate along a cross-sectional line C16-D16 in FIG. 58.

FIG. 60 illustrates another enlarged structural schematic of a Q2 region in FIG. 1.

FIG. 61 illustrates a cross-sectional structural schematic of an array substrate along a cross-sectional line C17-D17 in FIG. 60.

FIG. 62 illustrates another enlarged structural schematic of a Q1 region in FIG. 1.

FIG. 63 illustrates a cross-sectional structural schematic of an array substrate along a cross-sectional line A5-B5 in FIG. 62.

FIG. 64 illustrates another enlarged structural schematic of a Q1 region in FIG. 1.

FIG. 65 illustrates a cross-sectional structural schematic of an array substrate along a cross-sectional line A6-B6 in FIG. 64.

FIG. 66 illustrates another enlarged structural schematic of a Q1 region in FIG. 1.

FIG. 67 illustrates a cross-sectional structural schematic of an array substrate along a cross-sectional line A7-B7 in FIG. 66.

FIG. 68 illustrates another enlarged structural schematic of a Q1 region in FIG. 1.

FIG. 69 illustrates a cross-sectional structural schematic of an array substrate along a cross-sectional line A8-B8 in FIG. 68.

FIG. 70 illustrates another enlarged structural schematic of a Q1 region in FIG. 1.

FIG. 71 illustrates a cross-sectional structural schematic of an array substrate along a cross-sectional line A9-B9 in FIG. 70.

FIG. 72 illustrates another enlarged structural schematic of a Q1 region in FIG. 1.

FIG. 73 illustrates a cross-sectional structural schematic of an array substrate along a cross-sectional line G1-H1 in FIG. 72.

FIG. 74 illustrates another enlarged structural schematic of a Q1 region in FIG. 1.

FIG. 75 illustrates a structural schematic of a display panel according to various embodiments of the present disclosure.

FIG. 76 illustrates a structural schematic of a display device according to various embodiments of the present disclosure.

### DETAILED DESCRIPTION

To clearly understand the solutions of the present disclosure, the technical solutions in various embodiments of the present disclosure are clearly and completely described below in conjunction with accompanying drawings in various embodiments of the present disclosure. Obviously, described embodiment may be only a part of embodiments of the present disclosure, not all embodiments of the present disclosure. Based on embodiments in the present disclosure, all other embodiments obtained by those skilled in the art without creative work should belong to the protection scope of the present disclosure.

It is obvious to those skilled in the art that various modifications and changes may be made in the present disclosure without departing from the spirit or scope of the present disclosure. Therefore, the present disclosure may be intended to cover modifications and changes of the present disclosure that fall within the scope of corresponding claims (technical solutions claimed for protection) and equivalents. It should be noted that implementation manners provided in embodiments of the present disclosure may be combined with each other without contradiction.

It should be noted first that, unless otherwise defined, technical terms or scientific terms used in the present disclosure should be the common meaning understood by those skilled in the art in the field to which the present disclosure belongs. The terms “first”, “second” and the like used in embodiments of the present disclosure may not indicate any order, quantity or importance, but may be only used to distinguish different components. The terms “include”, and the like may indicate that the elements or objects appearing before the terms include the elements or objects and their equivalents listed after the terms, without excluding other elements or objects. The terms “connect”, “connection” and the like may be not limited to physical or mechanical connections but may include direct or indirect electrical connections. The terms “up”, “down”, “left”, “right” and the like may be only used to indicate relative positional relationships. When absolute position of described object changes, relative positional relationship may also change accordingly. Furthermore, the shapes and dimensions of components in accompanying drawings may not reflect actual proportions, and the objective may be only to illustrate the content of the present disclosure.

In liquid-crystal display panels, through-holes may be needed on the array substrate to electrically connect two structures on different film layers. Through-holes may be relatively vulnerable points, which may easily cause reliability risks and even result in display defects.

To improve the reliability of through-holes, embodiments of the present disclosure provide an array substrate. The array substrate may include a substrate, a first metal layer, a first conductive layer, a first insulating layer, and a second conductive layer; the first metal layer may be on the side of the substrate; the first metal layer may include metal patterns; the first conductive layer may be on the side of the first metal layer away from the substrate; the first conductive layer may include blocking patterns; the first insulating layer may be on the side of the first conductive layer away from the substrate; the first insulating layer may be configured with first type through-holes; the first type through-hole may expose at least a portion of the blocking pattern; the second conductive layer may be on the side of the first insulating layer away from the substrate; the second conductive layer may include conductive patterns; the conductive pattern may be electrically connected to the blocking pattern and the metal pattern, respectively; the conductive pattern may be in a contact with the blocking pattern at least through the first type through-hole; along the first direction, the conductive pattern, the blocking pattern, and the metal pattern may be overlapped with each other; and the first direction may be perpendicular to the plane where the substrate is located.

Adopting above-mentioned solution, the blocking patterns in the first conductive layer may be configured as an etch blocking structure for the first insulating layer. After dry etching the first insulating layer to form the first type through-hole, the blocking pattern may prevent an etching gas from further etching the portion of an underlying film layer covered by the blocking pattern, thereby improving the reliability of through-holes. With reference to accompanying drawings, a detailed solution for improving the reliability of through-holes is described hereinafter.

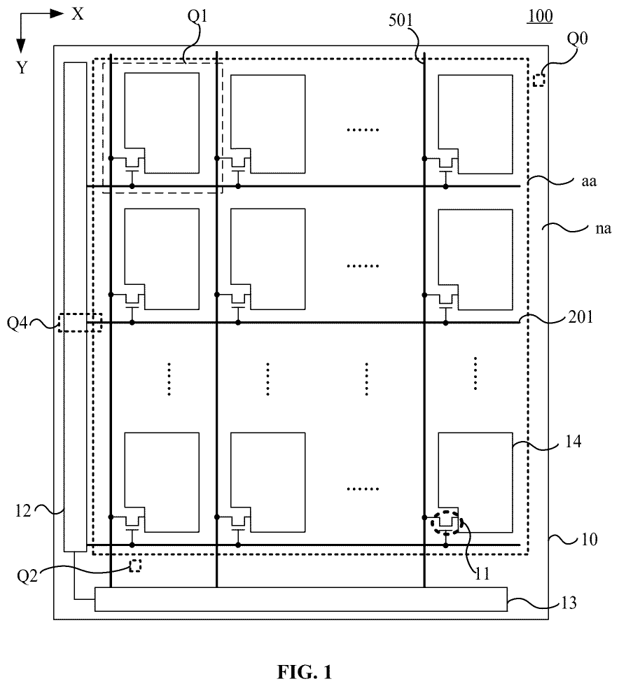

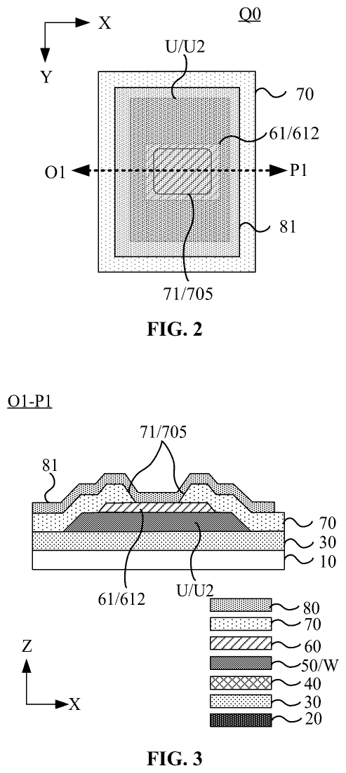

FIG. 1 illustrates a top-view structural schematic of an array substrate according to various embodiments of the present disclosure; FIG. 2 illustrates an enlarged structural schematic of a Q0 region in FIG. 1; and FIG. 3 illustrates a cross-sectional structural schematic of the array substrate along a cross-sectional line O1-P1 in FIG. 2. Referring to FIGS. 1-3, an array substrate 100 provided by embodiments of the present disclosure may include a substrate 10, a first metal layer W, a first conductive layer 60, a first insulating layer 70, and a second conductive layer 80; the first metal layer W may be on the side of the substrate 10; the first metal layer W may include metal patterns U; the first conductive layer 60 may be on the side of the first metal layer W away from the substrate 10; the first conductive layer 60 may include blocking patterns 61; the first insulating layer 70 may be on the side of the first conductive layer 60 away from the substrate 10; the first insulating layer 70 may be configured with first type through-holes 71; the first type through hole 71 may expose at least a portion of the blocking pattern 61; the second conductive layer 80 may be on the side of the first insulating layer 70 away from the substrate 10; the second conductive layer 80 may include conductive patterns 81; the conductive pattern 81 may be electrically connected to the blocking pattern 61 and the metal pattern U, respectively; the conductive pattern 81 may be in a contact with the blocking pattern 61 at least through the first type through-hole 71; the conductive pattern 81, the blocking pattern 61, and the metal pattern U may be overlapped with each other along the first direction Z; and the first direction Z may be perpendicular to the plane where the substrate 10 is located.

It should be noted that, unless otherwise specified, the proximity or distance between different film layers in the array substrate may be based on a formation order of the film layers. “The film layer 1” being located on the side of “the film layer 2” away from the substrate 10 may indicate that “the film layer 1” may be formed after “the film layer 2.” Such two layers may be configured to be adjacent or non-adjacent. For example, “the film layer 1” may be in a direct contact with “the film layer 2”, or other film layers may be configured between “the film layer 1” and “the film layer 2”. For example, the first conductive layer 60 may be on the side of the first metal layer W away from substrate 10. It may be understood as the formation order of the first conductive layer 60 may be after the formation order of the first metal layer W; and same interpretation may apply to other similar situations.

Optionally, the array substrate of a liquid-crystal display panel may include at least two metal layers. It should be noted that the “the first metal layer” may include only one metal layer or at least two metal layers arranged in different layers, which may be not limited in embodiments of the present disclosure; and any metal layer located between the first conductive layer 60 and the substrate 10 may be configured as the first metal layer W. When the first metal layer W includes two or more metal layers, the first conductive layer 60 may be on the side of the first metal layer W away from the substrate 10, which indicates that the first conductive layer 60 may be formed after the metal layer farthest from the substrate 10 is formed.

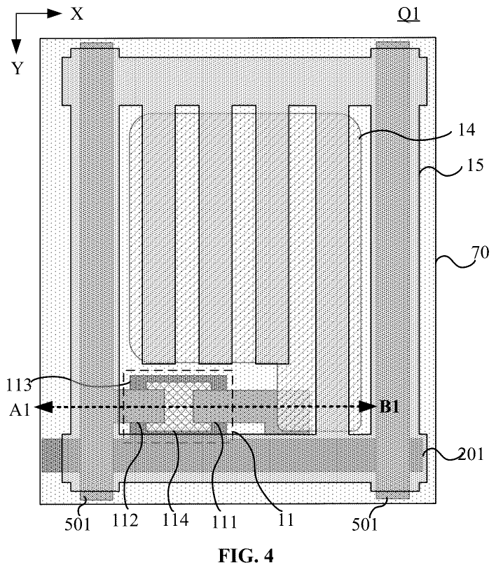

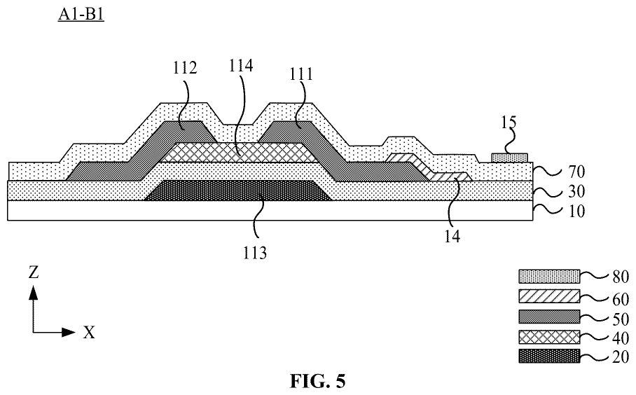

Exemplarily, FIG. 4 illustrates an enlarged structural schematic of a Q1 region in FIG. 1; and FIG. 5 illustrates a cross-sectional structural schematic of the array substrate along a cross-sectional line A1-B1 in FIG. 4. Referring to FIGS. 1, 4 and 5, a plurality of array-arranged thin-film transistors 11 may be configured in the array substrate; and the thin-film transistor 11 may include a first electrode 111, a second electrode 112, a gate electrode 113 and an active layer pattern 114. The first electrode 111, the second electrode 112 and the gate electrode 113 may be all made of metal materials. Accordingly, the array substrate may include a gate metal layer 20 and a source-drain electrode layer 50; the gate metal layer 20 may include the gate electrode 113 of the thin-film transistor 11; the source-drain electrode layer 50 may include the first electrode 111 and the second electrode 112 of the thin-film transistor 11; and the source-drain electrode layer 50 may be on the side of the gate metal layer 20 away from the substrate 10. The array substrate may further include an active layer 40 and a second insulating layer 30. The active layer 40 may be on the side of the gate electrode 113 away from the substrate 10 and include an active layer pattern 114 of the thin-film transistor 11. The second insulating layer 30 (i.e., the gate insulating layer) may be located between the gate metal layer 20 and the active layer 40. The source-drain electrode layer 50 may be on the side of the active layer 40 away from the substrate 10. The first electrode 111 and the second electrode 112 may respectively form ohmic contact with the active layer pattern 114.

Optionally, the gate metal layer 20 may be made of at least one of aluminum, silver, gold, nickel, copper, titanium, and molybdenum. The gate metal layer 20 may be a single metal layer or stacked multiple metal layers, which may be not limited in embodiments of the present disclosure.

Optionally, the source-drain electrode layer 50 may be made of at least one of molybdenum, aluminum, copper, and titanium. The source-drain electrode layer 50 may be a single metal layer or stacked multiple metal layers, which may be not limited in embodiments of the present disclosure. One of the first electrode 111 and the second electrode 112 may be configured as the source electrode of the thin-film transistor 11, and another one of the first electrode 111 and the second electrode 112 may be configured as the drain electrode of the thin-film transistor 11, which may be not limited in embodiments of the present disclosure.

As disclose above, optionally, the metal layer in the array substrate may at least include the gate metal layer 20 and the source-drain electrode layer 50. Taking the array substrate including the gate metal layer 20 and the source-drain electrode layer 50 as an example, the first metal layer W may include at least one of the gate metal layer 20 and the source-drain electrode layer 50.

Furthermore, referring to FIGS. 2-3, the first metal layer W may include the metal pattern U, and the second conductive layer 80 may include the conductive pattern 81. In some designs, the metal pattern U may need to be electrically connected to the conductive pattern 81 through the through-hole (i.e., via). When the metal pattern U and the conductive pattern 81 may be electrically connected through the through-hole, the through-hole may have the reliability problem, which may be solved in embodiments of the present disclosure.

In one embodiment, the metal patterns U may be different structures and in different film layers at different designs; similarly, the conductive patterns 81 may be different structures and in different film layers at different designs. The configuration of the metal patterns U and the conductive patterns 81 may be determined based on actual conditions. For example, in some designs, a wiring may not be routed consistently in a single film layer. In such scenario, the wiring may be switched from one film layer to another film layer by a punch-hole manner; and the metal pattern U and the conductive pattern 81 may refer to wiring segments in different film layers and configured to transmit same signal.

It should be understood that, at least one insulating layer (for example, at least the first insulating layer 70) may be located between the first metal layer W and the second conductive layer 80. Etching may be needed to form the through-holes passing through such insulating layer. In such way, the material of the second conductive layer 80 may fill the through-holes after forming the second conductive layer 80, thereby realizing electrical connection between the conductive patterns 81 and the metal patterns U. If there are a large quantity of insulating layers and multiple insulating layers are etched in same process to form the through-holes, the second conductive layer 80 may have relatively large slope (i.e., extending) depth at the through-holes, which may increase the risk of slope fracture and result in reliability problems. Furthermore, the through-holes may be formed in the insulating layer using a dry etching manner; and the gases of the dry etching manner may include oxygen. The metal patterns U in the first metal layer W may be exposed after forming the through-holes. The metal patterns U's prolonged exposure to oxygen may result in oxidation, which may increase impedance and adversely affect electrical signal transmission. To solve above-mentioned reliability problems of the through-holes, the solutions are provided in embodiments of the present disclosure.

Referring to FIG. 3, in embodiments of the present disclosure, the first conductive layer 60 may be configured between the first metal layer W and the first insulating layer 70. The blocking patterns 61 may be formed in the first conductive layer 60. The first type through-hole 71 in the first insulating layer 70 may expose at least a portion of the blocking pattern 61. The conductive pattern 81 may be in a contact with the blocking pattern 61 at least through the first type through-hole 71. Furthermore, the conductive pattern 81, the blocking pattern 61, and the metal pattern U may be overlapped along the first direction Z; and the conductive pattern 81 may be electrically connected to the blocking pattern 61 and the metal pattern U, respectively.

The overlapping of the conductive pattern 81, the blocking pattern 61, and the metal pattern U along the first direction Z may indicate that the conductive pattern 81, the blocking pattern 61, and the metal pattern U may have a common overlapping region along the first direction Z. Referring to FIG. 3, along the first direction Z, the overlapping portion of the conductive pattern 81 and the blocking pattern 61 may be overlapped with the overlapping portion of the metal pattern U and the blocking pattern 61.

It may be understood that the first type through-hole 71 in the first insulating layer 70 may expose the top surface of the blocking pattern 61. The first type through-hole 71 may expose at least a portion of the blocking pattern 61. For example, the first type through-hole 71 may expose a portion of the upper surface of the blocking pattern 61 or expose entire upper surface of the blocking pattern 61. In FIG. 3, the first type through-hole 71 exposes a portion of the upper surface of the blocking pattern 61, which may be taken as an example for illustration.

Referring to FIG. 2, when the first type through-hole 71 exposes a portion of the blocking pattern 61, the orthographic projection of the contour of the first type through-hole 71 on the substrate 10 may be within the orthographic projection of the blocking pattern 61 on the substrate 10. In FIG. 2, the contour of the first type through-hole 71 is a quadrilateral, which may be taken as an example for illustration. In other embodiments, the contour of the first type through-hole 71 may also have other shapes, such as a circle, an ellipse, or other polygonal shape, which may not be described in detail herein. The shapes of other through-holes may have same description, which may not be described in detail in the following.

Referring to FIGS. 2-3, during the formation process of the first type through-hole 71, the portion of the first insulating layer 70 away from the substrate 10 may be more exposed to the etching gas. Therefore, the diameter of the upper opening of the first type through-hole 71 may be slightly greater than the diameter of the lower opening of the first type through-hole 71. In the cross-sectional view, the first type through-hole 71 may appear to be an inverted trapezoid. Therefore, it may be understood that at different depths of the first insulating layer 70, the cutoff positions of the first insulating layer 70 corresponding to the first type through-hole 71 may be different; that is, the contours of the first type through-hole 71 may be different. In one embodiment, the orthographic projection of the contour of the first type through-hole 71 on the substrate 10 may be within the orthographic projection of the blocking pattern 61 on the substrate 10. For example, the orthographic projection of the contour of the lower opening of the first type through-hole 71 on the substrate 10 may be within the orthographic projection of the blocking pattern 61 on the substrate 10.

Referring to FIGS. 2-3, the first type through-hole 71 may expose at least a portion of the blocking pattern 61, and the conductive pattern 81 may be located on the side of the first insulating layer 70 away from the substrate 10, such that the conductive pattern 81 may be in a contact with the blocking pattern 61 at least through the first type through-hole 71. In some embodiments, the conductive patterns 81 may be also in a contact with the blocking patterns 61 by the first type through-holes 71 and through-holes in other insulating layers, which may be exemplarily illustrated subsequently. In FIG. 3, the conductive pattern 81 may be in a contact with the blocking pattern 61 through the first type through-hole 71, which may be taken as an example for illustration.

Referring to FIG. 3, optionally, the dimension of the conductive pattern 81 may be greater than the dimension of the first type through-hole 71. That is, the orthographic projection of the conductive pattern 81 on the substrate 10 may be overlapped with the orthographic projection of the region where the first type through-hole 71 is located.

In one embodiment, the blocking pattern 61 in the first conductive layer 60 may be configured as an etch blocking structure for the first insulating layer 70. After etching the first insulating layer 70 to form the first type through-hole 71, the blocking pattern 61 may prevent the etching gas from further etching the portion of underlying film layer covered by the blocking pattern 61, thereby improving the reliability of the through-holes.

For example, referring to FIG. 3, in embodiments of the present disclosure, the first conductive layer 60 may be configured between the first insulating layer 70 and the first metal layer W, and the blocking pattern 61 may be formed in the first conductive layer 60, such that the blocking pattern 61, the metal pattern U, and the conductive pattern 80 may be overlapped with each other along the first direction Z. In such way, through-holes may be formed in the insulating layer above the region where the metal pattern U is located and may be configured for subsequent electrical connection between the metal pattern U and the conductive pattern 81. After the first insulating layer 70 is dry etched to form the first type through-holes 71, at least a portion of the blocking pattern 61 may be exposed. Furthermore, the blocking pattern 61 may be not removed by the dry etching gas, such that the blocking pattern 61 may be used to protect underlying film layer covered by the blocking pattern 61, which may prevent the etching gas from contacting the film layer covered by the blocking pattern 61, thereby improving reliability of the through-holes.

In one embodiment, the first conductive layer 60 may be a newly added film layer or reuse an original conductive film layer in the array substrate, which may be not limited in embodiments of the present disclosure. Although both the first conductive layer 60 and the second conductive layer 80 are referred to as conductive layers, the first conductive layer 60 and the second conductive layer 80 may be made of same or different materials, which may be also not limited in embodiments of the present disclosure.

Optionally, the material of the first conductive layer 60 may be a conductive metal oxide. Metal oxide films may be optionally patterned using a wet etching process, while insulating layers may be optionally processed using a dry etching process for through-holes. The metal oxide may be selected as the material of the first conductive layer 60, which may not be etched and oxidized by the etching gas. The material of the second conductive layer 80 may be either a metal or a metal oxide, which may depend on actual needs.

Referring to FIGS. 1, 4, and 5, the array substrate may include pixel electrodes 14. The pixel electrode 14 may be electrically connected to the first electrode 111 of the thin-film transistor 11.

For the liquid-crystal display device, the LCD panel may not emit light on its own; instead, the LCD panel may receive backlight from a backlight module to realize light-emission. Referring to FIG. 1, in the array substrate 100, the pixel electrode 14 may include a portion in a light-transmitting region, and the light provided by the backlight may be pass through the pixel electrode 14. For example, the pixel electrodes 14 may have one-to-one correspondence with the sub-pixels and may be electrically connected to the thin-film transistors 11. The array substrate may be primarily configured to adjust the data voltage values on the pixel electrodes 14 corresponding to all thin-film transistors 11 by controlling the switching states of all thin-film transistors 11, thereby adjusting the brightness of all sub-pixels and further achieving image display.

For the positional definition of the pixel electrodes 14, referring to FIGS. 1 and 4, optionally, the gate metal layer 20 may include a plurality of scan lines 201 extending along the second direction X and arranged along the third direction Y; the second direction X may intersect the third direction Y; the second direction X and the third direction Y may both in parallel with the plane where the substrate 10 is located; the source-drain electrode layer 50 may include a plurality of data lines 501 extending along the third direction Y and arranged along the second direction X; the orthographic projection of the pixel electrode 14 on the substrate 10 may be located within the projection range defined by two adjacent scan lines 201 and two adjacent data lines 501 on the substrate 10.

Referring to FIGS. 1 and 4, the gate electrode of the thin-film transistor 11 may be electrically connected to the scan line 201; the first electrode 111 of the thin-film transistor 11 may be electrically connected to the pixel electrode 14; the second electrode 112 of the thin-film transistor 11 may be electrically connected to the data line 501; the plurality of scan lines 201 may be electrically connected to the gate driver circuit 12; and the gate driver circuit 12 and the plurality of data lines 501 may be electrically connected to a driver chip 13. The thin-film transistor 11 and the plurality of pixel electrodes 14 may be in the display region aa, and the gate driver circuit 12 and the driver chip 13 may be in the non-display region na.

Referring to FIG. 4, optionally, the scan line 201 and the gate electrode 113 of the thin-film transistor 11 may be formed into a single piece; and optionally, the data line 501 and the second electrode 112 may be formed into a single piece.

Referring to FIG. 1, the process of writing data voltages to the pixel electrodes 14 may be as follows. During the display of one single frame, the driver chip 13 may sequentially transmit scan enable signals to the plurality of scan lines 201 via the gate driver circuit 12, thereby enabling row-by-row conduction of thin-film transistors 11; simultaneously, the driver chip 13 may also transmit data signals to the thin-film transistors 11 in conduction state via the plurality of data lines 501, thereby writing data voltages needed to the pixel electrodes 14 row by row.

Furthermore, the liquid-crystal display panel may be configured with a liquid-crystal layer and a common electrode receiving a common voltage signal. An electric field may be generated between the pixel electrode 14 and the common electrode. By adjusting the magnitude of the data voltage on the pixel electrodes 14, the magnitude of the electric field between the pixel electrode 14 and the common electrode may be adjusted, thereby adjusting the deflection angle of the liquid-crystal molecules and further controlling the light output (brightness) of the sub-pixels and displaying images. The display principle is further described subsequently in conjunction with embodiments of the display panel, and the above is merely brief overview of the display principle.

Referring to FIG. 4, optionally, the array substrate may include a common electrode 15. The pixel electrode 14 and the common electrode 15 may be arranged in separate layers and overlapped with each other along the first direction Z. Both the pixel electrode 14 and the common electrode 15 may be configured on the array substrate, which may be beneficial for wide-viewing angle display.

Referring to FIG. 4, furthermore, optionally, one of the pixel electrode 14 and the common electrode 15 may be in the first conductive layer 60; and another one of the pixel electrode 14 and the common electrode 15 may be in the second conductive layer 80. That is, one of the first conductive layer 60 and the second conductive layer 80 may include the pixel electrode 14; and another one of the first conductive layer 60 and the second conductive layer 80 may include the common electrode 15.

The film layers where the pixel electrode 14 and the common electrode 15 are located may be optionally made of transparent indium tin oxide, which may ensure the conductivity of the pixel electrode 14 and the common electrode 15, and ensure the light transmittance of the light-transmitting region of the array substrate. One of the first conductive layer 60 and the second conductive layer 80 may include the pixel electrode 14, and another one of the first conductive layer 60 and the second conductive layer 80 may include the common electrode 15, which may satisfy the design requirement of using the first conductive layer 60 as an etch blocking layer for the first insulating layer 70 in the present disclosure (since the indium tin oxide material is not removed or oxidized by the etching gas), and may also allow for the film layer reuse, avoid excessive increase in the quantity of film layers on the array substrate, thereby being beneficial for thin product design.

Exemplarily, in FIG. 4, the first conductive layer 60 may include the pixel electrode 14, and the second conductive layer 80 may include the common electrode 15, which may be taken as an example for illustration. In other embodiments, optionally, the first conductive layer 60 may include the common electrode, and the second conductive layer 80 may include the pixel electrode.

Exemplarily, in FIG. 3, the source-drain electrode layer 50 may be the first metal layer W, the source-drain electrode layer 50 may include the metal pattern U, and the metal pattern U may be electrically connected to the conductive pattern 81 in the second conductive layer 80 via the first type through-hole 71, which may be taken as an example for illustration. In an existing solution, no blocking pattern 61 may be configured, and the first type through-hole 71 may expose the metal pattern U. In such scenario, if the etching time is excessively long when the first type through-hole 71 is processed, the metal pattern U may be exposed to oxygen environment for a long time, which may result in oxidation of the metal pattern U and increase the connection impedance between the conductive pattern 81 and the metal pattern U. The technical solution shown in FIG. 3 of the present disclosure, the first conductive layer 60 may be configured between the source-drain electrode layer 50 (the first metal layer W) and the first insulating layer 70, and the blocking pattern 61 may be formed in the first conductive layer 60, such that the blocking pattern 61, the conductive pattern 81, and the metal pattern U may be overlapped with each other along the first direction Z. In such way, after the first type through-hole 71 is formed, even if the etching process is not yet complete or a large amount of oxygen is still present in the chamber, the blocking pattern 61 may protect the metal pattern U and prevent oxygen from oxidizing the metal pattern U, which may prevent increased impedance and improve the reliability of the through-holes.

It should be noted that, unless otherwise specified, the electrical connection between two different structures in the array substrate may be direct electrical connection or indirect electrical connection. For example, when two structures are in a contact with each other, two structures may be directly connected to each other; and when two structures are not in a contact with each other, two structures may be indirectly connected to each other. For example, in above-mentioned electrical connection between the conductive pattern 81 and each of the blocking pattern 61 and the metal pattern U, since the conductive pattern 81 is in a contact with the blocking pattern 61 via the first type through-hole 71, the conductive pattern 81 may be directly and electrically connected to the blocking pattern 61; and the electrical connection between the conductive pattern 81 and the metal pattern U may be direct electrical connection or indirect electrical connection. In FIG. 3, the conductive pattern 81 may be indirectly and electrically connected to the metal pattern U via the blocking pattern 61, which may merely be taken as an example for illustration.

As disclosed above, in embodiments of the present disclosure, the first conductive layer may be configured between the first metal layer and the first insulating layer; the blocking pattern may be formed in the first conductive layer; the first type through-hole in the first insulating layer may expose at least a portion of the blocking pattern; and the conductive pattern may be in a contact with the blocking pattern at least through the first type through-hole. Furthermore, the conductive pattern, the blocking pattern, and the metal pattern may be overlapped with each other along the first direction; and the conductive pattern may be electrically connected to the blocking pattern and the metal pattern, respectively. In such way, the blocking pattern in the first conductive layer may configured as an etch blocking structure of the first insulating layer; and after dry etching the first insulating layer to form the first type through-hole, the blocking pattern may prevent the etching gas from further etching the portion of underlying film layer covered by the blocking pattern, thereby improving the reliability of the through-holes.

Referring to FIG. 5, optionally, the first electrode 111 and the second electrode 112 may be in a direct contact with the active layer pattern 114.

The term “direct contact” is used in contrast to “contact through the through-hole.” For example, the first electrode 111 and the second electrode 112 may be in a direct contact with the active layer pattern 114, which may indicate that there may be no dielectric layer between the source-drain electrode layer 50 and the active layer 40. In the source-drain electrode layer 50, a portion of the first electrode 111 and a portion of the second electrode 112 may be formed directly on the active layer pattern 114 in the active layer 40, such that both the first electrode 111 and the second electrode 112 may be in a direct contact with the active layer 113. In such scenario, the insulating layer between the gate metal layer 20 and the source-drain electrode layer 50 may only include the second insulating layer 30.

Compared to the solution that the dielectric layer is configured between the source-drain electrode layer 50 and the active layer 40, and the first electrode 111/the second electrode 112 are in a contact with the active layer pattern 114 via the thorough-holes passing through the dielectric layer, the solution that the first electrode 111 and the second electrode 112 are in a direct contact with the active layer pattern 114 may be beneficial for reducing the quantity of film layers in the array substrate and the thickness of the array substrate. Furthermore, the direct contact solution, rather than the indirect contact solution via the through-holes passing through the dielectric layer, may be used to eliminate the region needed for the through-holes and reduce the dimensions of the thin-film transistors.

Referring to FIGS. 1, 4, and 5, when the first conductive layer 60 includes the pixel electrode 14, optionally, the pixel electrode 14 may be in a direct contact with the first electrode 111.

In one embodiment, the first conductive layer 60 may include the pixel electrode 14 and the blocking pattern 61. For example, the blocking pattern 61 may be configured in same insulated layer as the pixel electrode 14. In such way, the film layer originally used to form the pixel electrode 14 may be reused as an etch blocking layer for the first insulating layer 70. Forming above-mentioned blocking pattern 61 may improve the reliability of the through-holes. Such solution may not need additional film layer to form the blocking pattern 61, thereby avoiding increasing the quantity of film layers in the array substrate and being beneficial for thin design of the LCD panel.

Furthermore, as disclosed above, the pixel electrode 14 may be in a direct contact with the first electrode 111, which may indicate that no dielectric layer may be between the first conductive layer 60 where the pixel electrode 14 is located and the source-drain electrode layer 50 where the first electrode 111 is located. In such way, compared to the manner that the pixel electrodes 14 are connected to the first electrodes 111 by the punch-holes, the quantity of dielectric layers needed may be reduced, the thickness of the array substrate may be reduced, the region needed for punching holes may be eliminated, and the dimensions of the thin-film transistors may be reduced.

It should be noted that when the pixel electrode 14 is in a direct contact with the first electrode 111, the film layer relationship between the pixel electrode 14 and the first electrode 111 may be that the pixel electrode 14 may be located on the side of the first electrode 111 away from the substrate 10 (as shown in FIG. 5) , or may be that the first electrode 111 may be located on the side of the pixel electrode 14 away from the substrate 10 (as shown in t following drawings), which may not be limited in embodiments of the present disclosure.

Hereinafter, based on the film layer configuration that the first electrode 111 and the second electrode 112 are respectively in a direct contact with the active layer pattern 114, and the pixel electrode 14 is in the first conductive layer 60 and in a direct contact with the first electrode 111, when the metal patterns U in the first metal layer W are electrically connected to the conductive patterns 81 in the second conductive layer 80 through through-holes, the configuration of the blocking patterns and through-holes is described in detail in combination with different application scenarios.

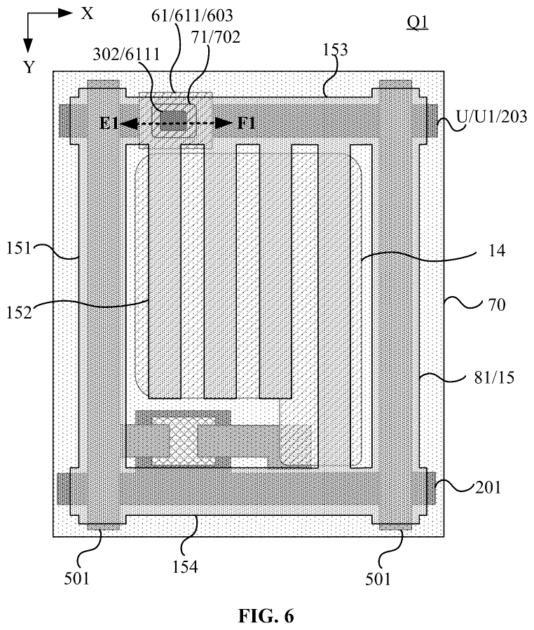

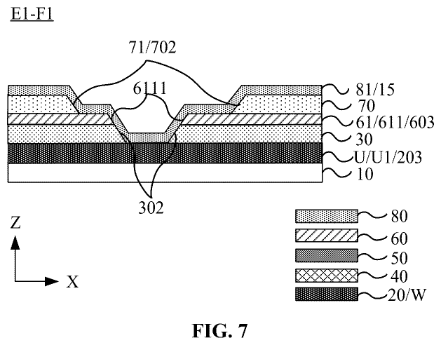

FIG. 6 illustrates another enlarged structural schematic of a Q1 region in FIG. 1; and FIG. 7 illustrates a cross-sectional structural schematic of an array substrate along a cross-sectional line E1-F1 in FIG. 6. Referring to FIGS. 6-7, optionally, the first metal layer W may include the gate metal layer 20; the metal patterns U may include first type metal patterns U1 located at the gate metal layer 20; the array substrate may further include the second insulating layer 30 located between the gate metal layer 20 and the first conductive layer 60; the first type through-holes 71 may include the first through-hole 702, the second insulating layer 30 may be configured with the second through-hole 302; the first through-hole 702 may be configured to be connected to the second through-hole 302; the blocking patterns 61 may include the first type blocking pattern 611; the first through-hole 702 may expose at least a portion of the first type blocking pattern 611; the portion of the conductive pattern 81 may be in a contact with and electrically connected to the first type blocking pattern 611 at least through the first through-hole 702, and may be electrically connected to the first type metal pattern U1 through the first through-hole 702 and the second through-hole 302 which are connected to each other.

In the configuration of the array substrate, a portion of the second conductive layer 80 may be electrically connected to a portion of the gate metal layer 20 by the through-hole (i.e., the through-hole formed by connecting the first through-hole 702 and the second through-hole 702) that pass through the first insulating layer 70 and the second insulating layer 30 (hereinafter referred to as deep-hole connection). In one embodiment, the first type metal pattern U1 may refer to the metal pattern in the gate metal layer 20 that needs to be electrically connected to the conductive pattern 81 in the second conductive layer 80 via the deep hole. It should be noted that the first type metal pattern U1 and the gate electrode 113 of the thin-film transistor 11 may be insulated from each other and may be separate metal patterns in the gate metal layer 20. It may be understood that the orthographic projection of the region, where the second through-hole 302 is located, on the substrate 10 may be within the orthographic projection of the first type metal pattern U1 on the substrate.

Referring to FIG. 7, in one embodiment, the insulating layers between the gate metal layer 20 and the second conductive layer 80 may include the first insulating layer 70 and the second insulating layer 30. Therefore, above-mentioned “deep-hole” may refer to a through-hole connecting the first through-hole 702 with the second through-hole 302. In other embodiments, if more insulating layers are between the first type metal pattern U and the conductive pattern 81, the deep hole may refer to a deeper through-hole formed by connecting through-holes in such insulating layers.

For deep hole connection configuration, due to relatively large depth of the through-hole, the second conductive layer 80 covering the inner wall of the through-hole may have slope cracking risk, which may affect signal transmission. Furthermore, if the etching time is excessively long, the first type metal pattern U1 in the gate metal layer 20 may be oxidized, which may increase the connection impedance.

To solve above-mentioned problems, in one embodiment, the first type blocking pattern 611 may be formed in the first conductive layer 60. The first type blocking pattern 611 may refer to the blocking pattern in the first conductive layer 60 corresponding to the deep hole. At least a portion of the first type blocking pattern 611 may be exposed by the first through-hole 702 at the deep hole. In FIG. 7, a portion of the first type blocking pattern 611 may be exposed by the first through-hole 702, which may be taken as an example for illustration.

In one embodiment, by configuring the first type blocking pattern 611, the first type metal pattern U1, the first type blocking pattern 611, and the conductive pattern 81 may be overlapped along the first direction Z. In such way, the first through-hole 702 may expose at least a portion of the first type blocking pattern 611; and a portion of the conductive pattern 81 may be in a contact with and electrically connect to the first type blocking pattern 611 at least through the first through-hole 702, and may be electrically connect to the first type metal pattern U1 through the first through-hole 702 and the second through-hole 302 which are connected to each other. The first type blocking pattern 611 may be used as an etch blocking structure for the first insulating layer 70. After the first through-hole 702 is formed, the first type blocking pattern 611 may prevent the etching gas from further etching a portion of underlying film layer (the second insulating layer 30 and the gate metal layer 20) covered by the first type blocking pattern 611, which may improve the reliability problems at the deep hole. The reliability problems may include, for example, slope cracking risk of the second conductive layer 80 at the deep hole and oxidation of the first type metal pattern U1 by the etching gas.

In one embodiment, the first through-hole 702 and the second through-hole 302 may be formed in same process or different processes, which may be not limited in embodiments of the present disclosure.

Hereinafter, the first through-hole 702 and the second through-hole 302 may be formed in same process to further describe the principle of improving the reliability of deep holes in the present disclosure.

The first through-hole 702 and the second through-hole 302 may be formed in same process, which may indicate that the first through-hole 702 and the second through-hole 302 may be processed together in same process. For example, after entire first insulating layer 70 is formed, a patterned photoresist may be configured to define the processing position of the first through-hole 702. Such position may be then etched by an etching gas. After the etching gas etches through the first insulating layer 70 to form the first through-hole 702, the second insulating layer 30 may be then etched until the second insulating layer 30 is etched through to form the second through-hole 302.

Referring to FIGS. 6-7, when the first through-hole 702 and the second through-hole 302 are formed in same process, the second through-hole 302 may expose a portion of the first type metal pattern U1, and the conductive pattern 81 may be in a contact with the first type metal pattern.

In such scenario, at least a portion of the first type metal pattern U1 exposed by the second through-hole 302 may not be overlapped with the first type blocking pattern 611 along the first direction Z, and such portion of the first type metal pattern U1 may be in a contact with the conductive pattern 81. That is, when the first through-hole 702 and the second through-hole 302 are formed in same process, the first type metal pattern U1 and the conductive pattern 81 may be in a contact with and electrically connected to each other via the first through-hole 702 and the second through-hole 302 which are connected to each other.

Referring to FIG. 7, as disclosed above, it should be understood that when the first through-hole 702 and the second through-hole 302 are formed in same process, the inner walls of the first through-hole 702 and the second through-hole 302 may be continuous (the diameter of the lower opening of the first through-hole 702 may be equal to the diameter of the upper opening of the second through-hole 302). In such way, the second conductive layer 80 may easily have slope crack at the deep hole to cause reliability problems.

In one embodiment, the first type blocking pattern 611 may be formed to protect the second insulating layer 30 covered by the first type blocking pattern 611. For example, during the deep hole formation process, when the first through hole 702 is processed to be formed and the etching process continues to downward etch the second insulating layer 30, the second insulating layer 30 covered by the first type blocking pattern 611 may not be etched, such that the diameter dimension of the second through hole 302 may be limited by the first type blocking pattern 611. In such way, the diameter dimension of the second through hole 302 may be not completely affected by the diameter dimension of the first through hole 702, thereby realizing the design of different dimensions of the first through hole 702 and the second through hole 302, realizing the adjustment of the deep hole shapes, and reducing the cracking problem of the second conductive layer 80 at the deep hole.

Referring to FIGS. 6-7, optionally, at the position of at least a portion of the contour of the second through-hole 302, the cutoff position (i.e., end or stop position) of the first type blocking pattern 611 may be substantially identical to the cutoff position of the second insulating layer 30.

Referring to FIGS. 6-7, as disclosed above, above-mentioned contour of the second through-hole 302 may be understood as the contour of the edge line of the upper opening of the second through-hole 302. Accordingly, the cutoff position of the second insulating layer 30 may be understood as the cutoff position of the upper surface of the second insulating layer 30 at the second through-hole 302. The cutoff position of the first type blocking pattern 611 may be understood as the cutoff position of the lower surface of the first type blocking pattern 611 at the second through-hole 302.

The cutoff position of the first type blocking pattern 611 may be substantially identical to the cutoff position of the second insulating layer 30. That is, some process tolerance may be between the cutoff position of the first type blocking pattern 611 and the cutoff position of the second insulating layer 30, but the cutoff position of the first type blocking pattern 611 and the cutoff position of the second insulating layer 30 may be substantially identical. For example, referring to FIG. 7, the first through-hole 702 may expose a portion of the first type blocking pattern 611. Therefore, a significant difference may be between the cutoff position of the first insulating layer 70 at the first through-hole 702 and the cutoff position of the first type blocking pattern 611. However, at the position of at least a portion of the contour of the second through-hole 302, the cutoff position of the first type blocking pattern 611 and the cutoff position of the second insulating layer 30 may be almost identical, with only a slight process tolerance. That is, the position of the second insulating layer 30 for at least a portion of the contour of the second through-hole 302 may be determined by the cutoff position of the first type blocking pattern 611.

For example, referring to FIG. 7, the first through-hole 702 may expose a portion of the first type blocking pattern 611, such that at the position of at least a portion of the contour of the second through-hole 302, the cutoff position of the first type blocking pattern 611 may be configured to be substantially identical as the cutoff position of the second insulating layer 30 in one embodiment. After the first through-hole 702 is processed to be formed, the first type blocking pattern 611 may protect a portion of the second insulating layer 30 from etching. In such way, the diameter dimension of the second through-hole 302 may be not completely affected by the diameter dimension of the first through-hole 702, which may realize that the orthographic projection of the first through-hole 702 on the substrate 10 is greater than the orthographic projection of the second through-hole 302 on the substrate to generate steps on the inner walls of the deep hole (the step surface may be formed by a portion of the upper surface of the first type blocking pattern 611), thereby reducing the slope (extending) difficulty of the second conductive layer 80, reducing the cracking risk of the conductive pattern 81, and improving the reliability of the through-holes.

In an optional implementation manner, at the position of entire contour of the second through-hole 302, the cutoff position of the first type blocking pattern 611 may be configured to be substantially identical as the cutoff position of the second insulating layer 30. Or, at the position of a portion of the contour of the second through-hole 302, the cutoff position of the first type blocking pattern 611 may be configured to be substantially identical as the cutoff position of the second insulating layer 30, which may be not limited in embodiments of the present disclosure.

In an optional implementation manner, as shown in FIGS. 6-7, optionally, the first type blocking pattern 611 may be configured with the first opening 6111; and the first opening 6111 may be overlapped with the second through-hole 302 along the first direction Z.

In one embodiment, the first opening 6111 may be configured in the internal region of the first type blocking pattern 611. For example, in one embodiment, along the first direction Z, the first opening 6111 may be located between the first through-hole 702 and the second through-hole 302; the first opening 6111, the first through-hole 702 and the second through-hole 302 may be overlapped with each other; and the first through-hole 702, the first opening 6111, and the second through-hole 302 may be connected to each other. At this point, at the position of entire contour of the second through-hole 302, the cutoff position of the first type blocking pattern 611 may be substantially identical as the cutoff position of the second insulating layer 30; and the diameter dimension of the second through-hole 302 may be determined by the dimension of the first opening 6111.

As shown in FIGS. 6-7, furthermore, optionally, the orthographic projection of the region, where the first through-hole 702 is located, on the substrate may be greater than the orthographic projection of the region, where the second through-hole 302 is located, on the substrate; the orthographic projection of the region where the first opening 6111 is located on the substrate may be within the orthographic projection of the region, where the first through-hole 702 is located, on the substrate; and the first through-hole 702 may expose a portion of the first type blocking pattern 611. In such way, closed steps may be formed on the inner walls of the deep hole. For example, the first type blocking pattern 611 exposed by the first through-hole 702 in FIGS. 6 and 7 may form a rectangular and circular step surface, which may greatly reduce the slope (extending) difficulty of the second conductive layer 80, decrease the cracking risk of the conductive pattern 81, and ensure product reliability.

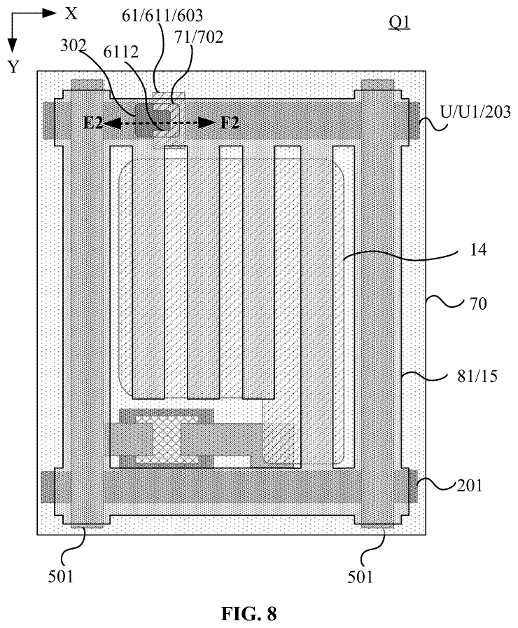

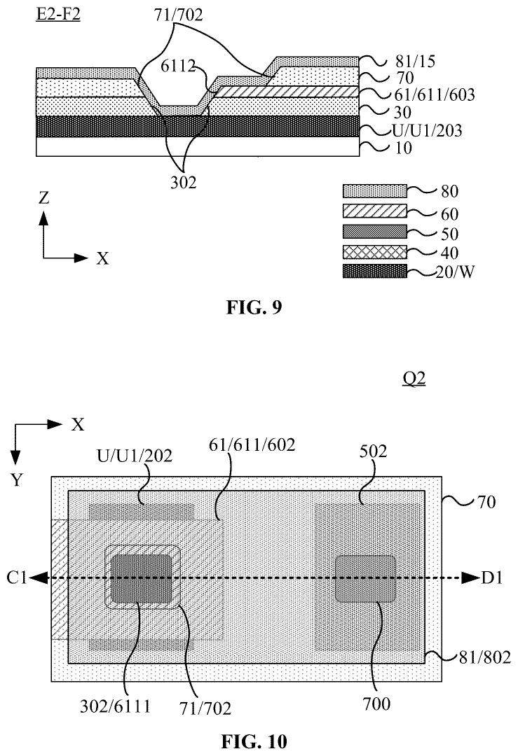

FIG. 8 illustrates another enlarged structural schematic of a Q1 region in FIG. 1; and FIG. 9 illustrates a cross-sectional structural schematic of the array substrate along a cross-sectional line E2-F2 in FIG. 8. Referring to FIGS. 8-9, optionally, the first type blocking pattern 611 may be configured with the first notch 6112; and along the first direction Z, the first notch 6112 may be overlapped with the second through-hole 302.

In one embodiment, the first notch 6112 may be located at the edge of either side of the first type blocking pattern 611. The orthographic projection of the first notch 6112 on the substrate may be less than the orthographic projections of the second through-hole 302 and the first through-hole 702. Along the first direction Z, the first notch 6112 may be located between the first through-hole 702 and the second through-hole 302; and the first notch 6112, the first through-hole 702 and the second through-hole 302 may be overlapped with and connected to each other.

As shown in FIGS. 8-9, in one embodiment, at the position of the first notch 6112 of the first type blocking pattern 611, the contour of the second through hole 302 may be coincident with the contour of the first notch 6112; that is, the cutoff position of the second insulating layer 30 may be substantially identical as the cutoff position of the first type blocking pattern 611. In the region of the second insulating layer 30 not covered by the first type blocking pattern 611, the contour of the second through hole 302 may be coincident with the contour of the first through hole 702; that is, the cutoff position of the second insulating layer 30 may be substantially identical as the cutoff position of the first insulating layer 70. At this point, at the position of a portion of the contour of the second through hole 302, the cutoff position of the first type blocking pattern 611 may be substantially identical as the cutoff position of the second insulating layer 30, and the diameter dimension of the second through hole 302 may be defined by both the first through hole 702 and the first notch 6112.

As shown in FIGS. 8-9, furthermore, optionally, the orthographic projection of the region, where the first through-hole 702 is located, on the substrate may be greater than the orthographic projection of the region, where the second through-hole 302 is located, on the substrate; the orthographic projection of the region where the first notch 6112 is located on the substrate may be within the orthographic projection of the region, where the first through-hole 702 is located, on the substrate; and the first through-hole 702 may expose a portion of the first type blocking pattern 611. In such way, steps may be formed on a portion of the inner walls of the deep hole, which may reduce the slope (extending) difficulty of the second conductive layer 80 to certain extent, reduce the cracking risk of the conductive pattern 81, and ensure product reliability.

Furthermore, in some embodiments, if the first conductive layer 60 has other structures (e.g., wirings) disposed adjacent to the first through-hole 702 and the second through-hole 703, the cutoff position of the first type blocking pattern 611 may be configured to be substantially identical as the cutoff position of the second insulating layer 30 at the position of a portion of the contour of the second through-hole 302, which may effectively avoid such structures, thereby preventing the first type blocking pattern 611 from interfering with configuration of existing structures.

As disclosed above, in above-mentioned embodiments, based on that the first through-hole 702 and the second through-hole 302 are formed in same process, the configuration manner of the through-holes and the first type blocking patterns in each insulating layer at the deep holes is described in detail. Referring to FIGS. 6-9, as disclosed above, when the first through-hole 702 and the second through-hole 302 are formed in same process, while ensuring interconnection between the first through-hole 702 and the second through-hole 302, the orthographic projection of the region, where the second through-hole 302 is located, on the substrate may be within the orthographic projection of the first type metal pattern U1 on the substrate. At the position of at least a portion of the contour of the second through-hole 302, the cutoff position of the first type blocking pattern 611 may be substantially identical as the cutoff position of the second insulating layer 30. The orthographic projection of the contour of the first through-hole 702 on the substrate may be within the orthographic projection of the first type blocking pattern 611 on the substrate. The orthographic projection of the region, where the first through-hole 702 is located, on the substrate may be within the orthographic projection of the conductive pattern 81 corresponding to the first type metal pattern U1 on the substrate.

The dimensional relationship between the metal pattern U (the first type metal pattern U1), the blocking pattern 61 (the first type blocking pattern 611), and the conductive pattern 81 may be not limited in embodiments of the present disclosure. The dimensional relationship between such three elements in the accompanying drawings may be for illustrative purposes only and may not be limited in the present disclosure. The dimensional relationship between such three elements may not be described subsequently.

The technical solutions of embodiments of the present disclosure are further described with reference to deep-hole connection solution.

Referring to FIGS. 6-9, optionally, the conductive pattern 81 may include the common electrode 15; the first type metal pattern U1 may include a common signal line 203; and the first type blocking pattern 611 may include a first blocking pattern 603. The common electrode 15 may be in a contact with and electrically connected to the first blocking pattern 603 via the first through-hole 702 and may be in a contact with and electrically connected to the common signal line 203 via the first through-hole 702 and the second through-hole 302 which are connected to each other.

For example, in one embodiment, the deep hole (the first through-hole 702 and the second through-hole 302 connected to each other) may be configured to electrically connect the common electrode 15 in the second conductive layer 80 to the common signal line 203 in the gate metal layer 20. When the first through-hole 702 and the second through-hole 302 are formed in same process, the second through-hole 302 may expose a portion of the common signal line 203.

In one embodiment, the common electrode 15 may be configured in the second conductive layer 80, and the common signal line 203 may be configured in the gate metal layer 20. In such way, the common electrode 15 and the common signal line 203 may be electrically connected through the first through-hole 702 and the second through-hole 302 which are connected to each other. Therefore, the low resistance advantage of metal common signal line 203 may be utilized, and the common signal may be transmitted through the common signal line 203, thereby reducing the IR (current resistance) drop of the common signal.

Referring to FIGS. 6-7, when the second conductive layer 80 includes the common electrode 15, the gate metal layer 20 includes the common signal line 203, and the common electrode 15 is electrically connected to the common signal line 203, optionally, the gate metal layer 20 may include at least one common signal line 203; and the common signal line 203 may be insulated from the scan line 201 and extend along same direction as the scan line 201.

For example, the common signal line 203 may be in the display region aa; and the gate metal layer 20 may include only one common signal line 203. The common signal line 203 may be electrically connected to the common electrode 15 via one or more deep holes (one deep hole includes the first through-hole 702 and the second through-hole 302 which are connected to each other). Or the gate metal layer 20 may include a plurality of common signal lines 203; and each common signal line 203 may be electrically connected to the common electrode 15 via one or more deep holes, thereby being beneficial for improving signal uniformity at different positions on the common electrode 15.

Furthermore, the common signal line 203 and the scan line 201 may be configured to extend along same direction and be insulated at same layer, the common electrode 15 and the common signal line 203 may be easily connected by a punch-hole manner, which may be also beneficial for ensuring that the projections of the common signal line 203 and the pixel electrode 14 are not overlapped with each other along the first direction Z, thereby preventing interference with the electric field between the pixel electrode and the common electrode.

As disclosed above, when the first through hole 702 and the second through hole 302 are formed in same process, the inner walls of the first through hole 702 and the second through hole 302 may be continuous (the diameter of the lower opening of the first through hole 702 may be equal to the diameter of the upper opening of the second through hole 302). In such way, the common electrode 15 may easily have slope crack at the deep hole, which may affect the connection reliability between the common electrode 15 and the common signal line 203. To solve above problems, in embodiments of the present disclosure, the first blocking pattern 603 may be configured in the first conductive layer 60, and the first blocking pattern 603 may be configured as an etch blocking structure for the first insulating layer 70. After the first through hole 702 is formed, the first blocking pattern 603 may be configured to protect the second insulating layer 30 under the first blocking pattern 603 from being etched. Without affecting the formation process of the second through hole 302, the diameter dimension of the second through hole 302 may be not completely affected by the diameter dimension of the first through hole 702, thereby realizing that the orthographic projection range of the first through hole 702 on the substrate 10 is greater than the orthographic projection range of the second through hole 302 on the substrate. The steps may be formed on the inner walls of the deep hole, which may decrease the slope (extending) difficulty of the second conductive layer 80, and reduce the cracking problem of the common electrode 15 at the deep hole.

Referring to FIG. 6, optionally, the common electrode 15 may include a portion (the first portion 151) overlapped with the projection of the data line 501, a portion (the second portion 152) overlapped with the projection of the pixel electrode 14, a portion (the third portion 153) overlapped with the projection of the common signal line 203, and a portion (the fourth portion 154) overlapped with the projection of the scan line 201. The second portion 152 of the common electrode 15 may include a plurality of electrode strips spaced apart with each other along the extension direction (the second direction X) of the scan line 201. Each electrode strip may be connected to at least one of the third portion 153 and the fourth portion 154 of the common electrode 15 and may be not overlapped with the region where the thin-film transistor is located. The first portion 151 of the common electrode 15 may be connected to the third portion 153 and the fourth portion 154 of the common electrode 15, respectively. In one embodiment, the film layer (the second conductive layer 80) where the common electrode 15 is located may be on the side of the film layer (the first conductive layer 60) where the pixel electrode 14 is located, away from the substrate, such that a grid-like common electrode may be configured, which may prevent the common electrode 15 from blocking the electric field.

As disclosed above, optionally, at the position of at least a portion of the contour of the second through-hole 302, the cutoff position of the first blocking pattern 603 may be substantially identical as the cutoff position of the second insulating layer 30.

As an optional implementation manner, referring to FIGS. 6-7, optionally, the first blocking pattern 603 may be configured with the first opening 6111; and along the first direction Z, the first opening 6111 may be overlapped with the second through-hole 302. In such scenario, at the position of entire contour of the second through-hole 302, the cutoff position of the first blocking pattern 603 may be substantially identical as the cutoff position of the second insulating layer 30; and the diameter dimension of the second through-hole 302 may be completely determined (defined) by the diameter dimension of the first opening 6111.

As an optional implementation manner, referring to FIGS. 8-9, optionally, the first blocking pattern 603 may be configured with the first notch 6112; and the first notch 6112 may be overlapped with the second through-hole 302 along the first direction Z. In such scenario, at the position of partial contour of the second through-hole 302, the cutoff position of the first blocking pattern 603 may be substantially identical as the cutoff position of the second insulating layer 30; and the diameter of the second through-hole 302 may be determined (defined) by the first through-hole 702 and the first notch 6112.

It should be noted that FIGS. 6-9 illustrate only the example of the first conductive layer 60 being located on the side of the source-drain electrode layer 50 away from the substrate 10. Relevant solutions may be also applicable when the source-drain electrode layer 50 is located on the side of the first conductive layer 60 away from the substrate 10.

It should also be noted that in the array substrates, the deep-hole connection solution may be not limited to electrical connection between the common electrodes and the common signal lines. Other structures may also be electrically connected to each other via deep holes according to actual design needs. It may be understood that the deep-hole connection configurations in different regions may be independent and may not affect each other.

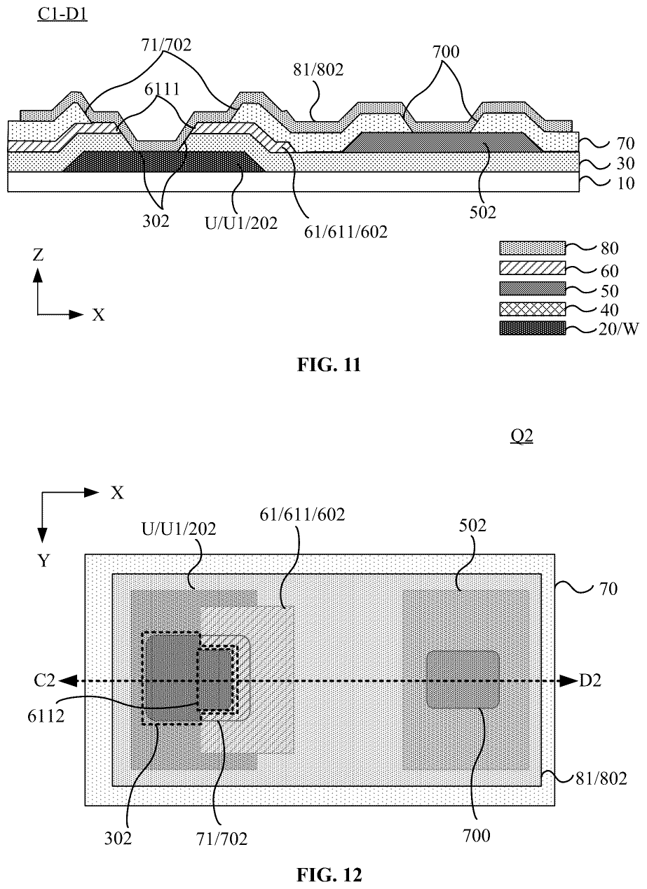

Exemplarily, FIG. 10 illustrates an enlarged structural schematic of a Q2 region in FIG. 1; and FIG. 11 illustrates a cross-sectional structural schematic of the array substrate along a cross-sectional line C1-D1 in FIG. 10. Referring to FIGS. 10-11, optionally, the conductive patterns 81 may include the first conductive pattern 802; the first type metal patterns U1 may include the first metal pattern 202; the source-drain electrode layer 50 may include the second metal pattern 502; the first metal pattern 202 and the second metal pattern 502 may be bridged by the first conductive pattern 802; the first type blocking patterns 611 may include the second blocking pattern 602; the second blocking pattern 602 may be configured to be insulated from the pixel electrode 11; the first conductive pattern 802 may be in a contact with and electrically connected to the second blocking pattern 602 via the first through-hole 702, and may be in a contact with and electrically connected to the first metal pattern 202 via the first through-hole 702 and the second through-hole 302 which are connected to each other.

The deep-hole connection solution in one embodiment may, for example, refer to the deep-hole connection portion of the deep-shallow-hole bridging solution. For example, the first metal pattern 202 and the second metal pattern 502 may belong to different metal layers. To achieve electrical connection between the first metal pattern 202 and the second metal pattern 50, the first conductive pattern 802 may be configured in the second conductive layer 80, such that the first metal pattern 202 and the second metal pattern 502 may be electrically connected to the first conductive pattern 802 through a punch-hole manner, respectively, thereby achieving bridging between the first metal pattern 202 and the second metal pattern 50, that is, the electrical connection between the first metal pattern 202 and the second metal pattern 50. Referring to FIG. 11, the first insulating layer 70 and the second insulating layer 30 may be included between the first metal pattern 202 and the first conductive pattern 802. The through-holes between the first metal pattern 202 and the first conductive pattern 802 must pass through both the first insulating layer 70 and the second insulating layer 30. However, the first insulating layer 70 may be located between the second metal pattern 502 and the first conductive pattern 802. The through-holes between the second metal pattern 502 and the first conductive pattern 802 may only need to pass through the first insulating layer 70. Therefore, the first metal pattern 202 and the first conductive pattern 802 may be electrically connected via the deep hole (e.g., the first through-hole 702 and the second through-hole 302 connected to each other) (i.e., the deep hole connection portion in the deep-shallow-hole bridging solution), while the second metal pattern 502 and the first conductive pattern 802 may be electrically connected via the shallow hole (e.g., the through-hole 700) (i.e., the shallow hole connection portion in the deep-shallow-hole bridging solution).

As disclosed above, for the deep hole connection portion in the deep-shallow-hole bridging solution, when the first through-hole 702 and the second through-hole 302 are formed in same process, the first conductive pattern 802 may have slope cracking risk at the deep hole. To solve above-mentioned problem, in one embodiment, the second blocking pattern 602 may be configured in the first conductive layer 60. The second blocking pattern 602 may be configured as an etch blocking structure for the first insulating layer 70. After the first through-hole 702 is formed, the second blocking pattern 602 may protect underlying second insulating layer 30 from etching. On the basis of without affecting the formation process of the second through-hole 302, the diameter dimension of the second through-hole 302 may be not completely affected by the diameter dimension of the first through-hole 702, thereby further realizing that the orthographic projection of the first through-hole 702 on the substrate 10 is greater than the orthographic projection of the second through-hole 302 on the substrate. The steps may be formed on the inner walls of the deep hole, which may decrease the slope (extending) difficulty of the second conductive layer 80 and reduce the cracking problem of the first conductive pattern 802 at the deep hole.

The deep-shallow-hole bridging solution described in the present disclosure may be applied to positions in the array substrate where electrical connection between structures in the first metal layer and structures in the source-drain electrode layer are needed, such as applied to the gate drive circuits providing scan signals to scan lines, anti-static circuits, and the like.

As disclosed above, optionally, at the position of at least a portion of the contour of the second through hole 302, the cutoff position of the second blocking pattern 602 may be substantially identical as the cutoff position of the second insulating layer 30.

As an optional implementation manner, referring to FIGS. 10-11, optionally, the second blocking pattern 602 may be configured with the first opening 6111; and the first opening 6111 may be overlapped with the second through hole 302 along the first direction Z. In such scenario, along entire contour of the second through hole 302, the cutoff position of the second blocking pattern 602 may be substantially identical as the cutoff position of the second insulating layer 30; and the diameter dimension of the second through hole 302 may be completely defined by the diameter dimension of the first opening 6111.

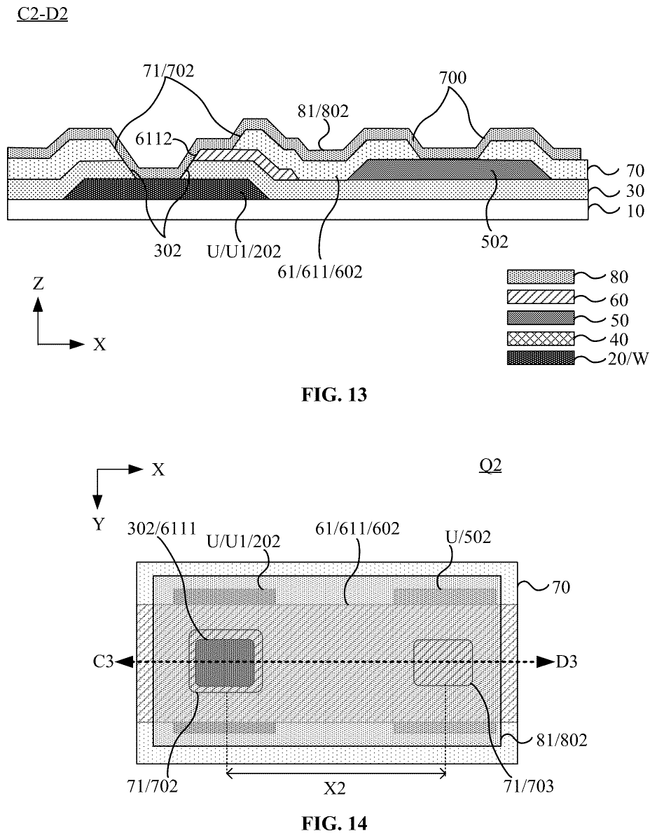

As an optional implementation manner, FIG. 12 illustrates another enlarged structural schematic of a Q2 region in FIG. 1; and FIG. 13 illustrates a cross-sectional structural schematic of the array substrate along a cross-sectional line C2-D2 in FIG. 12. Referring to FIGS. 12-13, optionally, the second blocking pattern 602 may be configured with the first notch 6112; and along the first direction Z, the first notch 6112 may be overlapped with the second through hole 302. In such scenario, at the position of a portion of the contour of the second through hole 302, the cutoff position of the second blocking pattern 602 may be substantially identical as the cutoff position of the second insulating layer 30; and the diameter of the second through hole 302 may be defined by both the first through hole 702 and the first notch 6112.

Exemplarily, referring to FIG. 12, taking both the first through-hole 702 and the first notch 6112 being rectangular as an example, the second through-hole 302 in a top view may have the shape of a combination of two rectangles; the left half contour of the second through-hole 302 may be same as the first through-hole 702; and the right half contour of the second through-hole 302 may be same as the first notch 6112. At the position of the right half contour of the second through-hole 302, the cutoff position of the first type blocking pattern 611 (the second blocking pattern 602) may be substantially identical as the cutoff position of the second insulating layer 30.

As described above, when the pixel electrode 14 is in a direct contact with the first electrode 111, the film layer where the pixel electrode 14 is located (the first conductive layer 60) may be located on the side of the film layer where the first electrode 111 is located (the source-drain electrode layer 50) away from the substrate 10; or the source-drain electrode layer 50 may be located on the side of the first conductive layer 60 away from the substrate 10. Hereinafter, the deep-shallow-hole bridging solution of the present disclosure is further described by taking the first conductive layer 60 being on the side of the source-drain electrode layer 50 away from the substrate 10 as an example for illustration.

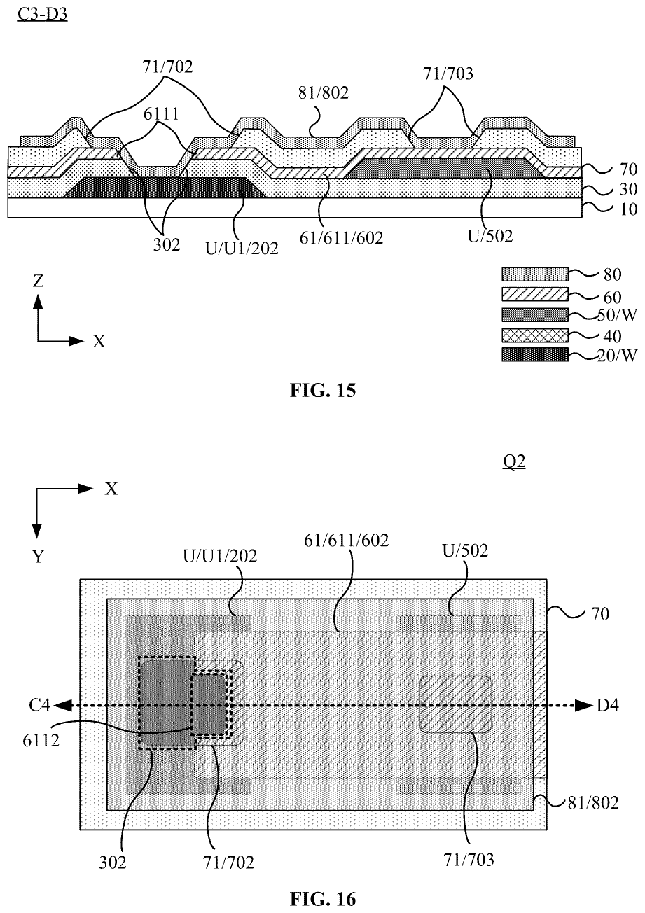

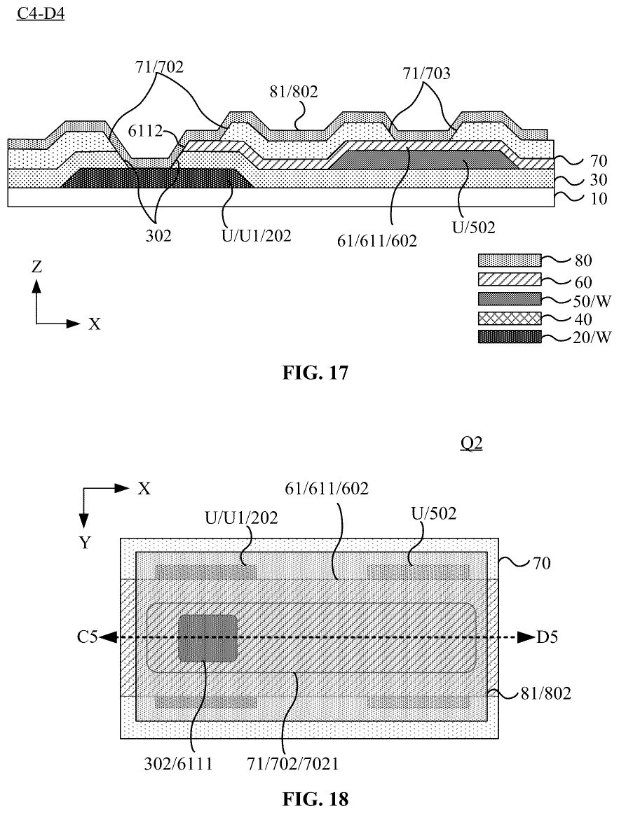

FIG. 14 illustrates another enlarged structural schematic of a Q2 region in FIG. 1; FIG. 15 illustrates a cross-sectional structural schematic of the array substrate along a cross-sectional line C3-D3 in FIG. 14; FIG. 16 illustrates another enlarged structural schematic of a Q2 region in FIG. 1; and FIG. 17 illustrates a cross-sectional structural schematic of the array substrate along a cross-sectional line C4-D4 in FIG. 16. Referring to FIGS. 14-17, optionally, the source-drain electrode layer 50 may be located between the gate metal layer 20 and the first conductive layer 60; along the direction in parallel with the plane where the substrate 10 is located, the second blocking pattern 602 may extend from at least a portion of the contour of the second through-hole 302 to the region where the second metal pattern 502 is located; the first conductive pattern 802 may be electrically connected to the second metal pattern 502 via the second blocking pattern 602; the second blocking pattern 602 may be in a contact with the second metal pattern 502 and the first conductive pattern 802, respectively; and along the first direction Z, the second metal pattern 502, the second blocking pattern 602, and the first conductive pattern 802 may be overlapped with each other.

In one embodiment, the second blocking pattern 602 may extend from at least a portion of the contour of the second through-hole 302 to the region where the second metal pattern 502 is located, such that the second blocking pattern 602 may cover at least a portion of the second metal pattern 502, which may only need to satisfy that the second metal pattern 502, the second blocking pattern 602, and the first conductive pattern 802 are overlapped with each other along the first direction Z; and the first conductive pattern 802 may be not directly and electrically connected to the second metal pattern 502 but indirectly and electrically connected to the second metal pattern 502 via the second blocking pattern 602.

Referring to FIG. 13, for the deep-shallow-hole bridging solution, since the depth of the through-hole corresponding to the first metal pattern 202 (hereinafter referred to as the deep hole) is greater than the depth of the through-hole corresponding to the second metal pattern 502 (hereinafter referred to as the shallow hole), when the first through-hole 702 and the second through-hole 302 are formed in same process, the processing time for the deep hole may be longer than the processing time for the shallow hole. That is, the deep hole may be completed before the shallow hole is completed. Therefore, the first conductive pattern 802 may be in a contact with the second metal pattern 502 at the stage of after the shallow hole is completed and before the deep hole is completed, such that the second metal pattern 502 may be exposed to the etching gas (oxygen) for a prolonged period, which may result in oxidation of the second metal pattern 502 (e.g., molybdenum or aluminum), thereby increasing the contact impedance between the second metal pattern 502 and the first conductive pattern 802, and adversely affecting electrical signal transmission.

To solve above-mentioned problem, referring to FIGS. 14-15, in one embodiment, the second blocking pattern 602 may be configured to extend from at least a portion of the contour of the second through-hole 302 to the region where the second metal pattern 502 is located. In such way, the second blocking pattern 602 may cover at least a portion of the second metal pattern 502, and the first conductive pattern 802 may be not in a contact with the second metal pattern 502. Instead, by increasing the coverage area of the second blocking pattern 602, the second blocking pattern 602 may be in a contact with both the second metal pattern 502 and the first conductive pattern 802, thereby achieving indirect electrical connection between the first conductive pattern 802 and the second metal pattern 502 via the second blocking pattern 602. In such way, the slope cracking problem of the first conductive pattern 802 at the deep hole may be reduced; and during deep-shallow-hole processing, the etch blocking effect of the second blocking pattern 602 may be utilized to protect underlying second metal pattern 502, which may prevent etching gas from contacting the second metal pattern 502, and further preventing the increase of the connection impedance in the shallow hole due to oxidation of the second metal pattern 502 by the etching gas.

Referring to FIGS. 16-17, when the second blocking pattern 602 is configured with the first notch 6112 and extends to the region where the second metal pattern 502 is located, the first notch 6112 may be configured at the edge of the second blocking pattern 602 facing toward the first metal pattern 202.

In one embodiment, the configuration (i.e., design) manner of deep and shallow holes is further described hereinafter.

Referring to FIG. 14-17, as a feasible deep-shallow-hole design manner, optionally, the first conductive pattern 802 and the first metal pattern 202 may be in a contact with and electrically connected to each other through the first through-hole 702 and the second through-hole 302 which are connected to each other; the first insulating layer 70 may be further configured with the third through-hole 703; the third through-hole 703 may expose a portion of the second blocking pattern 602; the first conductive pattern 802 may be in a contact with the second blocking pattern 602 via the third through-hole 703; and the first through-hole 702 and the third through-hole 703 may be configured to be spaced apart from each other.

In one embodiment, the first through-hole 702 and the second through-hole 302 which are connected to each other may be above-mentioned deep holes; and the third through-hole 703 may be above-mentioned shallow hole. The third through-hole 703 may expose a portion of the second blocking pattern 602; the second metal pattern 502, the second blocking pattern 602, and the first conductive pattern 802 may be overlapped with each other along the first direction Z; and the first conductive pattern 802 may be in a contact with the second blocking pattern 602 through the third through-hole 703 and may be electrically connected to the second blocking pattern 602 and the second metal pattern 502, respectively. Furthermore, the source-drain electrode layer 50 where the second metal pattern 502 is located may be on the side of the first conductive layer 60 adjacent to the substrate 10. Therefore, in one embodiment, the third through-hole 703 same as the first through-hole 702 may also belong to the first type through-hole 71; and the source-drain electrode layer 50 same as the gate metal layer 20 may also belong to the first metal layer W.

As shown in FIGS. 14-17, optionally, the orthographic projection range of the second blocking pattern 602 on the substrate may be greater than the orthographic projection range of the third through-hole 703 on the substrate. In such way, during deep-shallow-hole processing, the second blocking pattern 602 may be configured to protect the second metal pattern 502, prevent the third through-hole 703 (the shallow hole) from exposing the second metal pattern 502 which may result in oxidation, and avoid increasing the connection impedance between the second metal pattern 502 and the first conductive pattern 802.

It should be noted that the coverage area of the second blocking pattern 602 shown in FIGS. 14 and 16 may be for illustrative purposes only and may be not intended to be limitation, which may only need to satisfy that the second blocking pattern 602 may at least cover the portion exposed by the third through-hole 703 when extending to the region where the second metal pattern 502 is located, and may ensure the first conductive pattern 802 to be not in a contact with the second metal pattern 502 through the third through-hole 703.

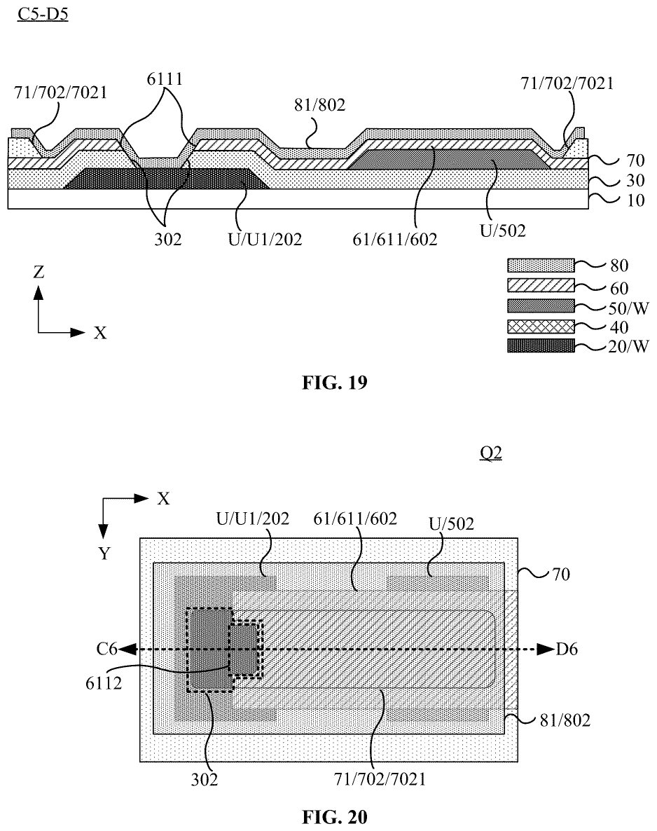

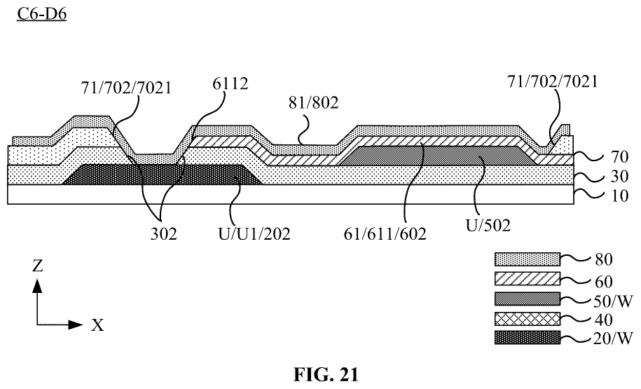

FIG. 18 illustrates another enlarged structural schematic of a Q2 region in FIG. 1; FIG. 19 illustrates a cross-sectional structural schematic of the array substrate along a cross-sectional line C5-D5 in FIG. 18; FIG. 20 illustrates another enlarged structural schematic of a Q2 region in FIG. 1; and FIG. 21 illustrates a cross-sectional structural schematic of the array substrate along a cross-sectional line C6-D6 in FIG. 20. Referring to FIGS. 18-21, optionally, along the direction in parallel with the plane where the substrate 10 is located, the first through-hole 702 may extend from the region where the first metal pattern 202 is located to the region where the second metal pattern 502 is located.

In FIGS. 18-21, the label “7021” may indicate the contour of the first through-hole 702, that is, the cutoff position of the first insulating layer 70 corresponding to the first through-hole 702, which may be applied similarly in the following description. In FIGS. 18 and 19, the second blocking pattern 602 may be configured with the first opening 6111, which may be taken as an example for illustration; and in FIGS. 20 and 21, the second blocking pattern 602 may be configured with the first notch 6112, which may be taken as an example for illustration.

Comparing FIG. 19 with FIG. 15, the difference between the deep-shallow-hole design in one embodiment and above-mentioned deep-shallow-hole design may be that the region, where the first through-hole 702 is located, may be expanded. For example, the region, where the first through-hole 702 is located, may be extended from the region where the first metal pattern 202 is located to the region where the second metal pattern 502 is located. In such way, the orthographic projection of the region, where the first through-hole 702 is located, on the substrate 10 may be overlapped with both the orthographic projection of the first metal pattern 202 on the substrate 10 and the orthographic projection of the second metal pattern 502 on the substrate 10. In such scenario, the first metal pattern 202 and the first conductive pattern 802 may be electrically connected through the first through-hole 702 and the second through-hole 302 which are connected to each other; the second metal pattern 502 and the first conductive pattern 802 may be electrically connected through the first through-hole 702; and the third through-hole 703 may not need to be designed (configured).

For above-mentioned configuration, the first through-hole 702 with relatively large diameter may be configured in the first insulating layer 70 to complete the design of the through-hole portion of the deep hole and the shallow hole passing through the first insulating layer 70; and there may be no need to configure separate through-holes in the first insulating layer 70 corresponding to the first metal pattern 202 and the second metal pattern 502, thereby reducing the needs for process precision.

Furthermore, by comparing FIG. 19 with FIG. 15, it may be seen that in one embodiment, based on that the second blocking pattern 602 is extended from at least a portion of the contour of the second through-hole 302 to the region where the second metal pattern 502 is located, the first through-hole 702 may be correspondingly extended from the region where the first metal pattern 202 is located to the region where the second metal pattern 502 is located. Although such solution may not form steps at the deep hole, the first insulating layer between the deep hole and the shallow hole may be removed, thereby further reducing the slope (i.e., slope extending) height of the first conductive pattern 802. In such way, the slope (i.e., slope extending) height of the first conductive pattern 802 in the region where the second through-hole 302 is located may only be the sum of the thicknesses of the first insulating layer 30 and the first conductive layer 60, which may further reduce the cracking risk of the first conductive pattern 802, thereby ensuring product reliability. Furthermore, the first through-hole 702 in one embodiment may have relatively large opening area, the second blocking pattern 602 may cover relatively large area, and the first conductive pattern 802 may be in a contact with and electrically connected to the second blocking pattern 602 via the first through-hole 702. In such way, the contact area between the first conductive pattern 802 and the second blocking pattern 602 may be increased, the first conductive pattern 802 and the second blocking pattern 602 may be overlapped and covered with each other, and the thickness of the connecting bridge between the first metal pattern 202 and the second metal pattern 502 may be further increased, and the connection impedance may be further reduced.

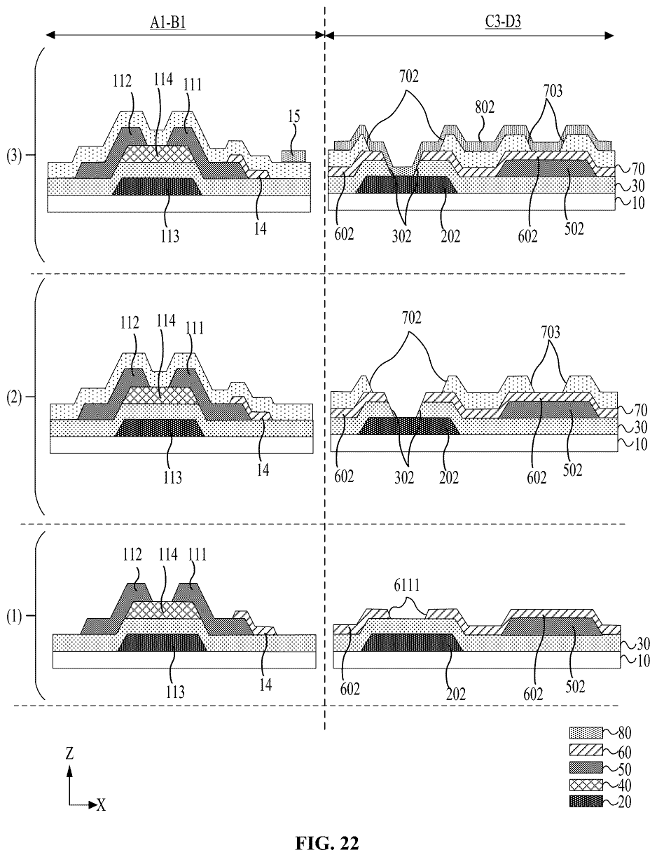

Exemplarily, FIG. 22 illustrates a flowchart of a formation process of an array substrate according to various embodiments of the present disclosure. The left part of FIG. 22 illustrates main formation process of the structure shown in FIG. 5, and the right part of FIG. 22 illustrates main formation process of the structure shown in FIG. 15. Referring to FIG. 22, taking the deep-shallow-hole bridging solution as an example, the first electrode 111 and the second electrode 112 may be directly in a contact with the active layer pattern 114 respectively; the first electrode 111 may be in a direct contact with the pixel electrode 14; the pixel electrode 14 may be located on the side of the first electrode 111 away from the substrate 10; the first insulating layer 70 may be configured with the first through hole 702; the second insulating layer 30 may be configured with the second through hole 302; and the first through hole 702 and the second through hole 302 may be formed in same process. Above formation processes are further described in detail in embodiments of the present disclosure.

In the formation process of the array substrate, referring to exemplary step (1) in FIG. 22, the gate metal layer 20, the second insulating layer 30, the active layer 40, the source-drain electrode layer 50 and the first conductive layer 60 may be first formed on the substrate 10 in sequence. In one embodiment, when forming the gate metal layer 20, a wet etching process may be used to form the gate electrode 113 of the thin-film transistor, the scan line, and the metal patterns, including the first metal pattern 202 and the like, in the gate metal layer 20; when forming the second insulating layer 30, no treatment may be performed on the second insulating layer 30, that is, the second insulating layer may cover the gate metal layer 20 and the substrate 10; when forming the active layer 40, the active layer pattern 114 of the thin-film transistor may be formed; when forming the source-drain electrode layer 50, a wet etching process may be used to form the first electrode 111 and the second electrode 112 of the thin-film transistor, and the metal patterns, including the second metal pattern 502 and the like, in the source-drain electrode layer 50; and when forming the first conductive layer 60, a wet etching process may be used to form the pixel electrode 14 and the patterns, including the second blocking pattern 602 and the like, in the first conductive layer 60. As shown in the right part of exemplary step (1) in FIG. 22, corresponding to the position of the first metal pattern 202, the first opening 6111 may be configured in the second blocking pattern 602. The first opening 6111 may expose a portion of the second insulating layer 30, which may facilitate subsequent configuration of the second through hole 302 in the second insulating layer 30.

Referring to exemplary step (2) in FIG. 22, the first insulating layer 70 may be subsequently formed on the side of the first conductive layer 60 away from the substrate 10, and the through holes may be formed in the first insulating layer 70 and the second insulating layer 30 as needed. For example, in one embodiment, the first through hole 702 and the third through hole 703 may be configured in the first insulating layer 70, and the second through hole 302 may be configured in the second insulating layer 30. It may be understood that the first through hole 702, the second through hole 302 and the third through hole 703 may be formed in same process. In one embodiment, the first through hole 702 and the second through hole 302 may be connected to each other and expose a portion of the first metal pattern 202; and the first through hole 702 and the third through hole 703 may expose a portion of the second blocking pattern 602.

Referring to exemplary step (3) in FIG. 22, the second conductive layer 80 may be subsequently formed on the side of the first insulating layer 70 away from the substrate 10. Similarly, through a wet etching process, the common electrode 15 and the patterns including the first conductive pattern 802 may be formed in the second conductive layer 80. The first conductive pattern 802 may be in a contact with the first metal pattern 202 and the second blocking pattern 602, respectively, and may be electrically connected to the second metal pattern 502 via the second blocking pattern 602, thereby achieving bridging between the first metal pattern 202 and the second metal pattern 502.

Referring to exemplary step (2) in FIG. 22, during the formation process of the first through hole 702, the second through hole 302, and the third through hole 703, if the third through hole 703 exposes the second metal pattern 502, after the first through hole 702 and the third through hole 703 are completely formed, the second metal pattern 502 may be exposed to the etching gas (oxygen) during the formation process of the second through hole 302, which may result in oxidation of the second metal pattern 502. To solve above problem, by configuring the second blocking pattern 602 to cover at least a portion of the second metal pattern 502, the second blocking pattern 602 in the first conductive layer 60 may be used to protect the second metal pattern 502 from oxidation. Furthermore, at the position of at least a portion of the contour of the second through-hole 302, the cutoff position of the second blocking pattern 602 may be configured to be substantially identical as the cutoff position of the second insulating layer 30, and the second blocking pattern 602 may be used to protect the second insulating layer 30. In such way, the diameter dimension of the second through-hole 302 may be not completely affected by the diameter dimension of the first through-hole 702, which may realize that the orthographic projection of the first through-hole 702 on the substrate is greater than the orthographic projection of the second through-hole 302 on the substrate. Such step formation manner may reduce the slope (extending) difficulty of the second conductive layer 80 and reduce the cracking risk of the first conductive pattern 802, thereby ensuring product reliability.

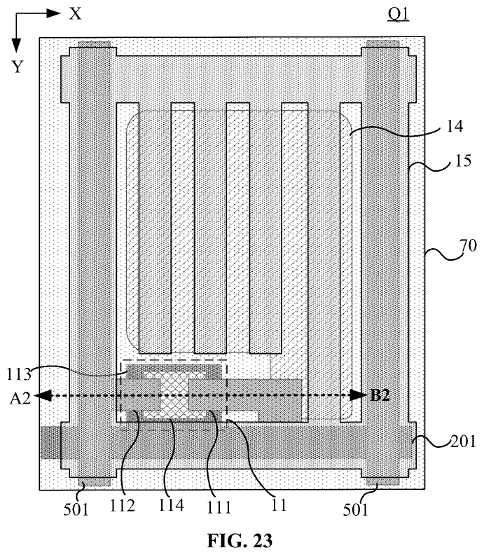

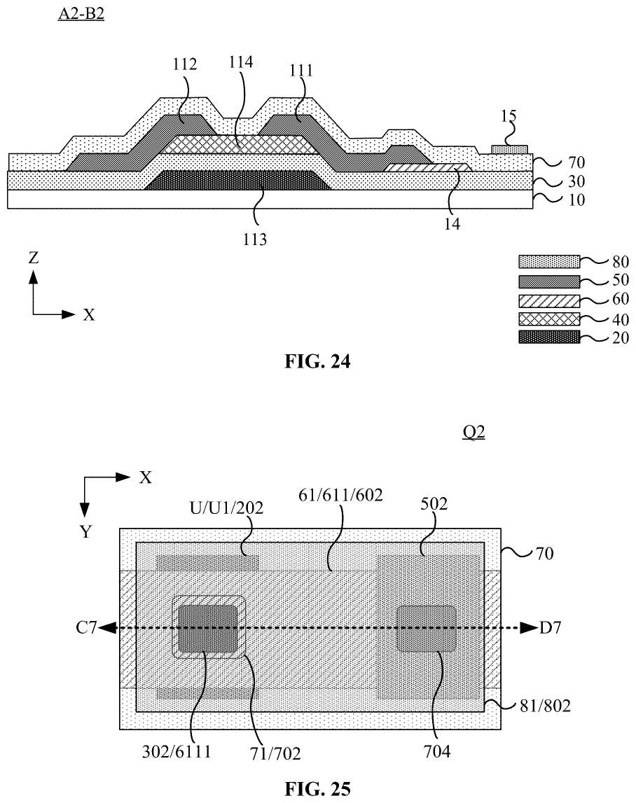

FIG. 23 illustrates another enlarged structural schematic of a Q1 region in FIG. 1; and FIG. 24 illustrates a cross-sectional structural schematic of the array substrate along a cross-sectional line A2-B2 in FIG. 23. Referring to FIGS. 23 and 24, when the first electrode 111 is in a direct contact with the pixel electrode 14, optionally, the film layer (the source-drain electrode layer 50) where the first electrode 111 is located may be on the side of the film layer (the first conductive layer 60), where the pixel electrode 14 is located, away from the substrate 10. The thickness of the first conductive layer 60 may be optionally less than the thickness of the source-drain electrode layer 50. Such configuration may prevent the pixel electrode 14 from extending from the sidewalls of the first electrode 111, thereby ensuring reliable connection between the pixel electrode 14 and the first electrode 111.

Hereinafter, based on the film layer design that the pixel electrode 14 is in the first conductive layer 60 and in a direct contact with the first electrode 111, and the source-drain electrode layer 50 is =on the side of the first conductive layer 60 away from the substrate 10, the deep-shallow-hole bridging solution of the present disclosure is further described.

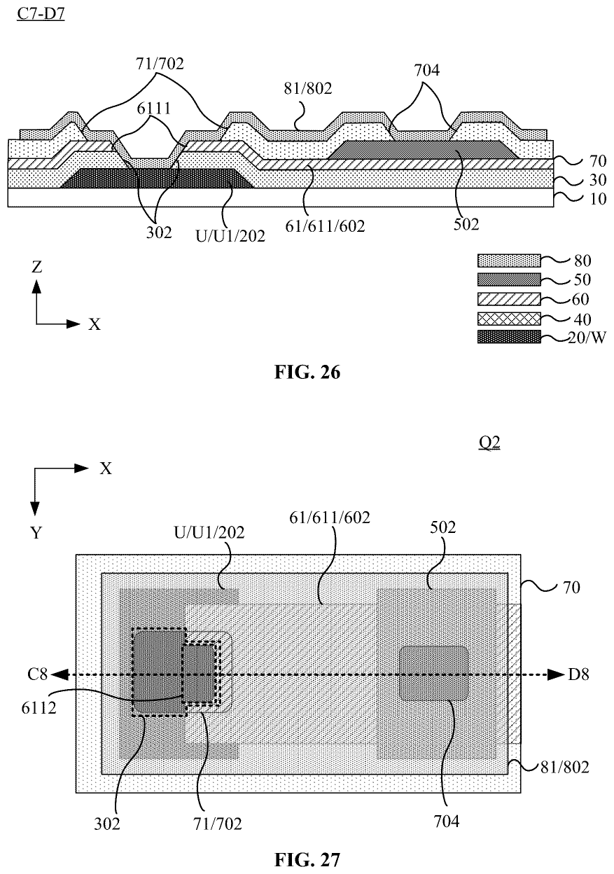

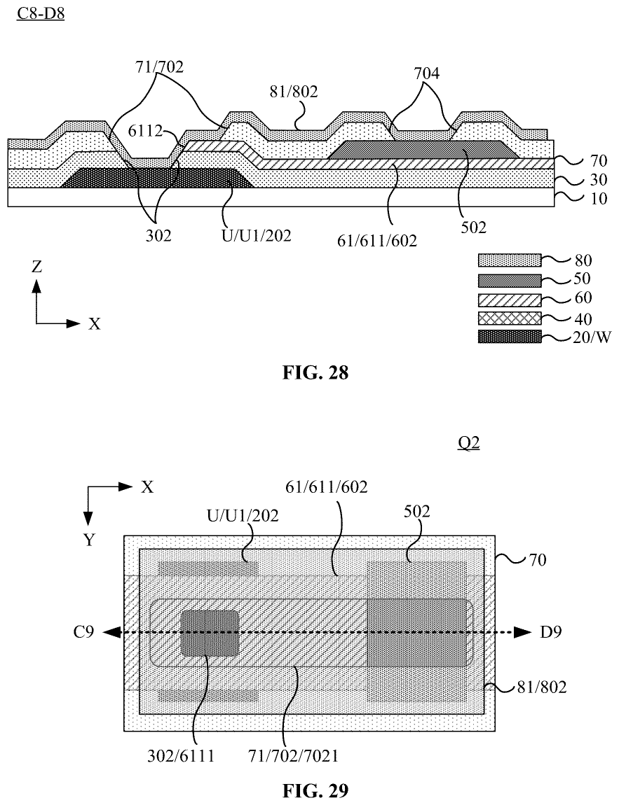

FIG. 25 illustrates another enlarged structural schematic of a Q2 region in FIG. 1; FIG. 26 illustrates a cross-sectional structural schematic of the array substrate along a cross-sectional line C7-D7 in FIG. 25; FIG. 27 illustrates another enlarged structural schematic of a Q2 region in FIG. 1; and FIG. 28 illustrates a cross-sectional structural schematic of the array substrate along a cross-sectional line C8-D8 in FIG. 27. Referring to FIGS. 25-28, optionally, the first conductive layer 60 may be located between the gate metal layer 20 and the source-drain electrode layer 50; along the direction in parallel with the plane where the substrate 10 is located, the second blocking pattern 602 may extend from the position of at least a portion of the contour of the second through-hole 302 to the region where the second metal pattern 502 is located; the first conductive pattern 802 may be electrically connected to the second blocking pattern 602 via the second metal pattern 502; the second metal pattern 502 may be in a contact with the first conductive pattern 802 and the second blocking pattern 602, respectively; and along the first direction Z, the second blocking pattern 602, the second metal pattern 502, and the first conductive pattern 802 may be overlapped with each other.

In one embodiment, the first conductive layer 60 may be located on the side of the source-drain electrode layer 50 adjacent to the substrate 10. By extending the second blocking pattern 602 from the position of at least a portion of the contour of the second through-hole 302 to the region where the second metal pattern 502 is located, the second metal pattern 502 may be in a contact with the first conductive pattern 802 and the second blocking pattern 602, respectively. In such way, the slope cracking problem of the first conductive pattern 802 at the deep hole may be reduced, and the connection path between the first metal pattern 202 and the second metal pattern 502 may be also increased. The second blocking pattern 602 may be configured as the second guarantee for bridging the first metal pattern 202 and the second metal pattern 502, which may further ensure the connection reliability between the first metal pattern 202 and the second metal pattern 502. Furthermore, the second blocking pattern 602 may be connected in parallel with the first conductive pattern 802, which may reduce the impedance of the connection structure between the first metal pattern 202 and the second metal pattern 502.

Regarding the principle of the second blocking pattern 602 acting as the second guarantee, for example, the thickness of the first insulating layer 70 may be greater than the thickness of the second insulating layer 30, if the first conductive pattern 802 breaks on the inner walls of the first through-hole 702, or if the first conductive pattern 802 and the second metal pattern 502 are poorly connected to each other, the first metal pattern 202 may be electrically connected to the second blocking pattern 602 through the portion of the first conductive pattern 802 on the inner walls of the second through-hole 302, and then electrically connected to the second metal pattern 502 through the second blocking pattern 602, which may provide double guarantee for the bridging the first metal pattern 202 and the second metal pattern 502, thereby ensuring the connection reliability of the first metal pattern 202 and the second metal pattern 502. Furthermore, in one embodiment, since the first conductive layer 60 is located on the side of the source-drain electrode layer 50 adjacent to the substrate 10, the second blocking pattern 602 may not need slope (extending), thereby preventing the second blocking pattern 602 from breaking, thereby further ensuring the reliability of the second blocking pattern 602 as the second guarantee.

In one embodiment, the first opening 6111 (as shown in FIGS. 25-26) or the first notch 6112 (as shown in FIGS. 27-28) may also be configured in the second blocking pattern 602, which may not be described in detail herein.

It should be noted that the dimensional relationship between the second metal pattern 502 and the second blocking pattern 602 in FIGS. 25 and 27 may be merely illustrative and may not limit the present disclosure, which may only need to ensure the contact between the second blocking pattern 602 and the second metal pattern 502. Obviously, large contact area between the second blocking pattern 602 and the second metal pattern 502 may be preferred Increasing the contact area may be beneficial for reducing the connection impedance between the second blocking pattern 602 and the second metal pattern 502.

Hereinafter, the design (configuration) of the deep hole and the shallow hole is further described in detail in one embodiment.

Referring to FIGS. 25-28, optionally, the first conductive pattern 802 and the first metal pattern 202 may be in a contact with and electrically connected to each other via the first through-hole 702 and the second through-hole 302 which are connected to each other; the first insulating layer 70 may be also configured with the fourth through-hole 704; the fourth through-hole 704 may expose a portion of the second metal pattern 502; the first conductive pattern 802 may be in a contact with the second metal pattern 502 via the fourth through-hole 704; and the first through-hole 702 and the fourth through-hole 704 may be configured to be spaced apart from each other.

In one embodiment, the first through-hole 702 and the second through-hole 302 which are connected to each other may be above-mentioned deep holes, and the fourth through-hole 704 may be above-mentioned shallow hole. The difference between above-mentioned embodiments and one embodiment is that, in one embodiment, the fourth through-hole 704 may expose a portion of the second metal pattern 502; and in above-mentioned embodiments, the third through-hole 703 may expose a portion of the second blocking pattern 602.

Referring to FIG. 25, in one embodiment, the orthographic projection of the region where the fourth through-hole 704 is located on the substrate 10 may be in the orthographic projection of the second metal pattern 502 on the substrate 10. As disclosed above, the first through-hole 702, the fourth through-hole 704, and the second through-hole 302 may be formed in same process.

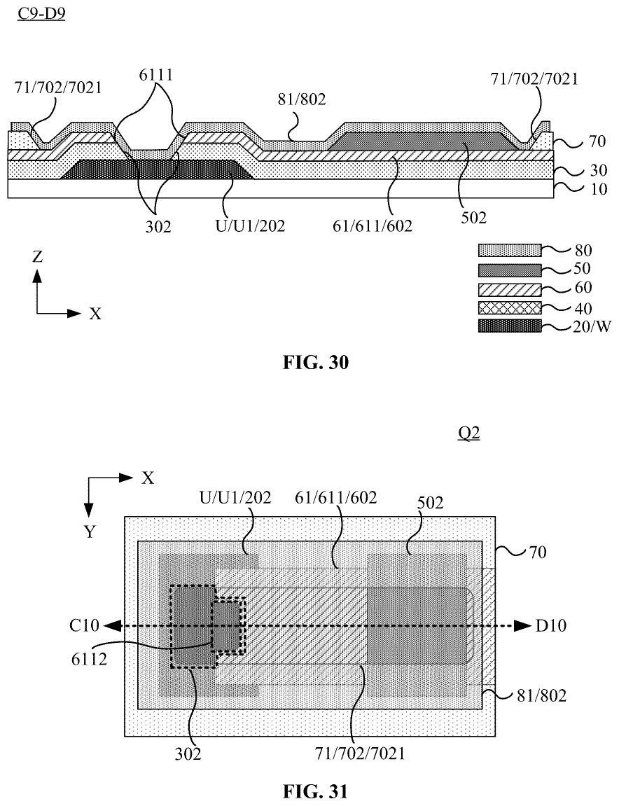

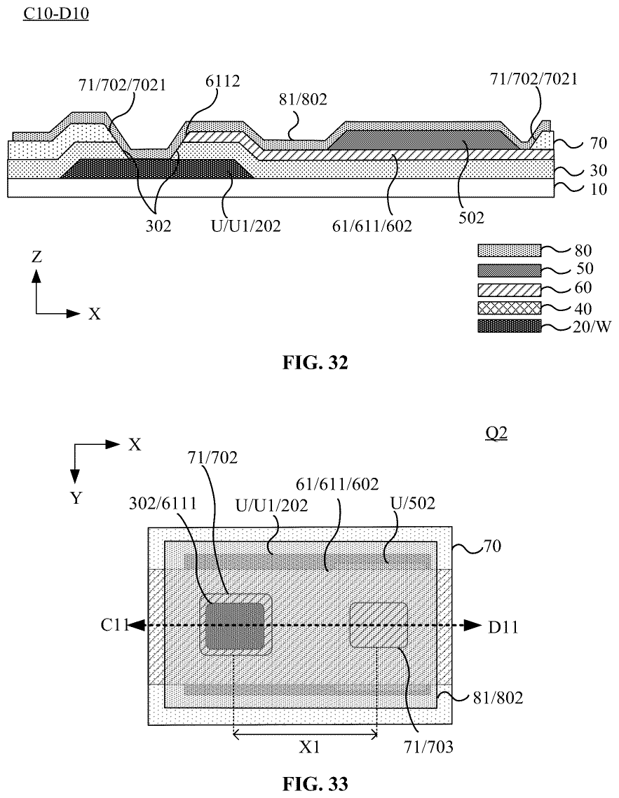

FIG. 29 illustrates another enlarged structural schematic of a Q2 region in FIG. 1; FIG. 30 illustrates a cross-sectional structural schematic of the array substrate along a cross-sectional line C9-D9 in FIG. 29; FIG. 31 illustrates another enlarged structural schematic of a Q2 region in FIG. 1; and FIG. 32 illustrates a cross-sectional structural schematic of the array substrate along a cross-sectional line C10-D10 in FIG. 31. Referring to FIGS. 29-32, optionally, along the direction in parallel with the plane of the substrate, the first through-hole 702 may extend from the region where the first metal pattern 202 is located to the region where the second metal pattern 502 is located.

As disclosed above, in one embodiment, the design of the through-hole portion of the deep and shallow holes passing through the first insulating layer 70 may be implemented by providing a first through-hole 702 with a larger diameter in the first insulating layer 70; and there may be no need to configured separate through-holes in the first insulating layer 70 corresponding to the first metal pattern 202 and the second metal pattern 502, thereby reducing the needs for process precision.

Furthermore, by comparing FIG. 30 with FIG. 26, in one embodiment, it can be seen that in addition to extending the second blocking pattern 602 from the position of at least a portion of the contour of the second through-hole 302 to the region where the second metal pattern 502 is located, the first through-hole 702 may be correspondingly extended from the region where the first metal pattern 202 is located to the region where the second metal pattern 502 is located, which may further reduce the slope (i.e., slope extending) height of the first conductive pattern 802. In such way, the slope (slope extending) height of the first conductive pattern 802 in the region where the second through-hole 302 is located may only be the sum of the thicknesses of the first insulating layer 30 and the first conductive layer 60, which may further reduce the cracking risk of the first conductive pattern 802, thereby ensuring product reliability. Furthermore, the second blocking pattern 602 may cover a relatively large region, and the orthographic projection of the contour of the first through-hole 702 on the substrate may be in the orthographic projection of the second blocking pattern 602 on the substrate. Therefore, the second blocking pattern 602 may be used to protect underlying second insulating layer 30 from etching. In addition, a portion of the second blocking pattern 602 may be in a contact with the first conductive pattern 802, which may further improve the connection reliability between the first metal pattern 202 and the second metal pattern 502.

In one embodiment, similarly, the first opening 6111 (as shown in FIGS. 29-30) or the first notch 6112 (as shown in FIGS. 31-32) may also be configured in the second blocking pattern 602, which may not be described in detail herein.

When the first through-hole 702 and the second through-hole 302 are formed in same process, the formation process of the first electrode 111 (the source-drain electrode layer 50) located on the side of the pixel electrode 14 (the first conductive layer 60) away from the substrate 10 may be substantially identical as the formation process for the pixel electrode 14 (the first conductive layer 60) located on the side of the first electrode 111 (the source-drain electrode layer 50) away from the substrate 10 described above. The only difference may be the formation order of the first conductive layer 60 and the source-drain electrode layer 50, which may not be described in detail herein.

Referring to FIGS. 10-32, in above-mentioned embodiments of the deep-shallow-hole bridging solution, the first metal pattern 202 and the second metal pattern 502 may be not overlapped with each other along the first direction Z.

For example, the first metal pattern 202 and the second metal pattern 502 may be not overlapped with each other along the first direction Z, such that the maximum slope height of the second conductive layer 80 may be less than or equal to the sum of the thicknesses of the second insulating layer 30, the first conductive layer 60, and the first insulating layer 70. Exemplarily, when the orthographic projection of the region, where the first through-hole 702 is located, on the substrate is in the orthographic projection of the first metal pattern 202 on the substrate, the maximum slope height of the second conductive layer 80 may be equal to the sum of the thicknesses of the second insulating layer 30, the first conductive layer 60, and the first insulating layer 70. When the orthographic projection of the region, where the first through-hole 702 is located, on the substrate exceeds the orthographic projection of the first metal pattern 202 on the substrate, the maximum slope height of the second conductive layer 80 may be less than the sum of the thicknesses of the second insulating layer 30, the first conductive layer 60, and the first insulating layer 70. For example, when the first through-hole 702 extends from the region where the first metal pattern 202 is located to the region where the second metal pattern 502 is located, the maximum slope height of the second conductive layer 80 may be equal to the sum of the thicknesses of the second insulating layer 30 and the first conductive layer 60.

Such configuration may make the slope of the second conductive layer 80 to be relatively small. Furthermore, the design of the blocking pattern 61 in the present disclosure may further reduce the slope (extending) difficulty of the second conductive layer 80 by the manners including forming steps at the deep hole, removing the first insulating layer 70 at the deep hole and/or the like, thereby being beneficial for ensuring the connection reliability between the first metal pattern 202 and the second metal pattern 502.

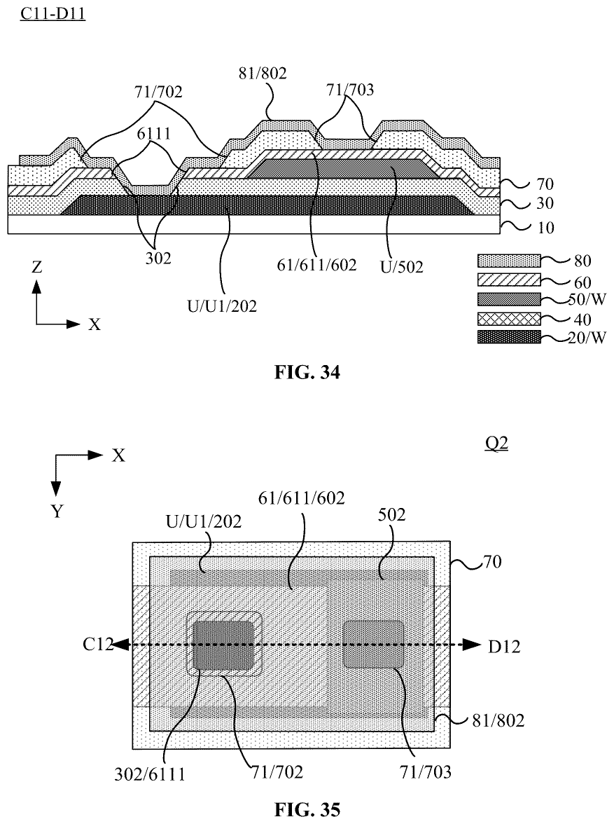

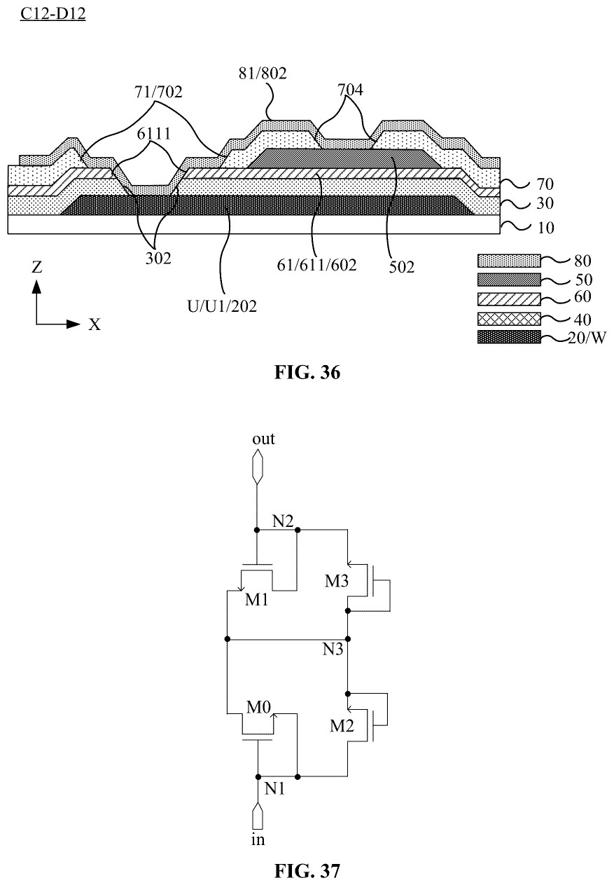

FIG. 33 illustrates another enlarged structural schematic of a Q2 region in FIG. 1; FIG. 34 illustrates a cross-sectional structural schematic of the array substrate along a cross-sectional line C11-D11 in FIG. 33; FIG. 35 illustrates another enlarged structural schematic of a Q2 region in FIG. 1; and FIG. 36 illustrates a cross-sectional structural schematic of an array substrate along a cross-sectional line C12-D12 in FIG. 35. Referring to FIGS. 33-36, when the first conductive layer 60 is located on the side of the source-drain electrode layer 50 away from the substrate 10 (FIGS. 33-34) , or when the source-drain electrode layer 50 is located on the side of the first conductive layer 60 away from the substrate 10 (FIGS. 35-36) , optionally, the first metal pattern 202 and the second metal pattern 502 may be overlapped with other along the first direction Z. In above-mentioned drawings, the orthographic projection of the first metal pattern 202 on the substrate may be overlapped with the orthographic projection of the second metal pattern 502 on the substrate, which may be taken as an example for illustration.

For example, by comparing FIG. 33 wit FIG. 14, with other designs remaining same, in one embodiment, the first metal pattern 202 and the second metal pattern 502 may be configured to be overlapped with each other along the first direction Z, such that the distance X1 between the deep hole (the first through-hole 702 and the second through-hole 302 which are connected to each other) and the shallow hole (the third through-hole 703) may be less than the distance X2 between the deep hole (the first through-hole 702 and the second through-hole 302 which are connected to each other) and the shallow hole (the third through-hole 703) when the first metal pattern 202 and the second metal pattern 502 are not overlapped with each other along the first direction Z, which may be beneficial for reducing the space occupied by the deep-shallow-hole bridging design (i.e., configuration).

For example, referring to FIG. 14, along the first direction Z, when the first metal pattern 202 and the second metal pattern 502 are not overlapped with each other, a certain gap (spacing distance) may be needed between the first metal pattern 202 and the second metal pattern 502, thereby avoiding that too small gap between the first metal pattern 202 and the second metal pattern 502 may result in spikes in the second conductive layer 80 during the slope extending process and increase cracking risk. Therefore, the distance between the deep hole and the shallow hole may be relatively large and occupy relatively large space, but the slope height of the second conductive layer 80 may be relatively small.

Referring to FIGS. 33-34, along the first direction Z, the first metal pattern 202 and the second metal pattern 502 may be overlapped with each other. The film layer in the formation region of the second metal pattern 502 may be relatively flat, which may reduce the distance between the second metal pattern 502 and the deep hole, that is, reduce the distance between the shallow hole and the deep hole, thereby further reducing the space occupied by the deep-shallow-hole bridging design (i.e., configuration).

Referring to FIGS. 33-36, along the first direction Z, the first metal pattern 202 may be overlapped with the second metal pattern 502. The first metal pattern 202 may extend from the deep hole region to the shallow hole region and may be located below the second metal pattern 502. Between the deep hole and the shallow hole, the first metal pattern 202 may provide a flat surface for the second insulating layer 30, which may be also beneficial for the installation (formation) of the first conductive layer 60. The maximum slope height of the second conductive layer 80 may be less than or equal to the sum of the thicknesses of the second insulating layer 30, the source-drain electrode layer 50, the first conductive layer 60, and the first insulating layer 70. In FIGS. 33-36, the orthographic projection of the region where the first through hole 702 is located on the substrate may be in the orthographic projection of the first metal pattern 202 on the substrate, which may be only taken as an example for illustration. In such scenario, the maximum slope height of the second conductive layer 80 may be equal to the sum of the thicknesses of the second insulating layer 30, the source-drain electrode layer 50, the first conductive layer 60, and the first insulating layer 70. Although the second conductive layer 80 has a slightly increased slope height, the design of blocking pattern 61 in the present disclosure may reduce the slope (extending) difficulty and reduce the cracking risk in the second conductive layer 80.

It should be noted that in one embodiment, the design that the orthographic projection of the first metal pattern 202 on the substrate covers the orthographic projection of the second metal pattern 502 on the substrate may be applicable to the deep-shallow-hole bridging solution described in any of above-mentioned embodiments, which may not be described in detail herein.

As disclosed above, at above-mentioned embodiments, in conjunction with both the simple deep hole connection solution (e.g., the solution connecting the common electrode and the common signal line via the deep hole) and the deep-shallow-hole bridging solution, the formation of the first through-hole 702 and the second through-hole 302 in same process may be taken as an example to describe the technical solutions of the present disclosure. When the first through-hole 702 and the second through-hole 302 are formed in same process, the quantity of expensive masks needed during the array substrate formation may be reduced. The first through-hole 702 and the second through-hole 302 may be configured to be formed in same process, which may effectively reduce product formation costs.

It should be noted that, in the array substrate, the deep-shallow-hole bridging solution and/or the simple deep hole connection solution may be designed based on actual needs. Such two deep hole connection solutions may not affect each other and exist independently or simultaneously, which may be not limited in embodiments of the present disclosure. It should be understood that when the array substrate includes both the deep-shallow-hole bridging design and the simple deep hole connection design (the common electrode is electrically connected to the common signal line), the first through-holes corresponding to different designs may be spaced apart and may be not same through-hole; and the second through-holes corresponding to different designs may be spaced apart and may be not same through-hole. In other words, in any embodiment of the present disclosure, the first through-hole and the second through-hole may refer to the through-holes in the first insulating layer and the second insulating layer respectively, which are used to connect the second conductive layer with the gate metal layer. The connection structures may be determined based on actual conditions, which may be not limited in embodiments of the present disclosure.

Based on the design that the first through-hole 702 and the second through-hole 302 are formed in same process, some examples of the deep-shallow-hole bridging design are described hereinafter.

Exemplarily, an electrostatic protection circuit may be optionally configured within the non-display region na of the array substrate to provide electrostatic protection for signal lines within the array substrate, such as the data lines and control signal lines of the gate drive circuit. The deep-shallow-hole bridging solution may be applied to the design of the electrostatic protection circuit.

Exemplarily, FIG. 37 illustrates a circuit principle diagram of an electrostatic protection circuit in an array substrate according to various embodiments of the present disclosure. Referring to FIG. 37, the electrostatic protection circuit may include two parallel diodes (positive and negative) formed by four transistors (M0, M1, M2, and M3). The input terminal (in) of the electrostatic protection circuit may be connected to the signal line such as the data line or the like, and the output terminal (out) of the electrostatic protection circuit may be connected to a fixed potential signal (e.g., the common signal). In such way, when abnormal charge on a signal line occurs, the abnormal charge may be diverted away by the electrostatic protection circuit, thereby achieving the electrostatic protection function.

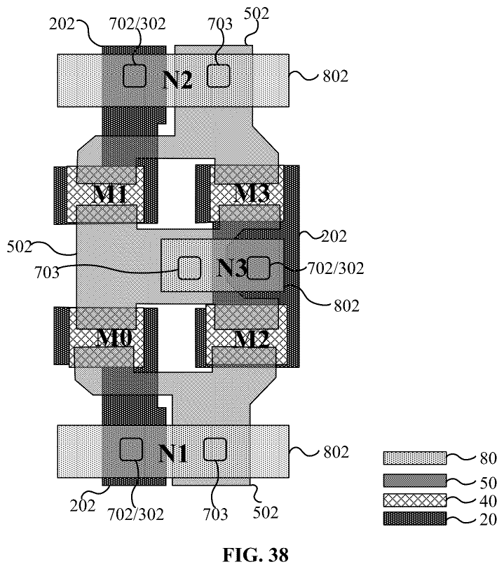

FIG. 38 illustrates a layout structural schematic of the electrostatic protection circuit in FIG. 37. Referring to FIGS. 37-38, at the positions such as the first node N1, the second node N2, and the third node N3 of the electrostatic protection circuit, the metal pattern in the gate metal layer 20 and the metal pattern in the source-drain electrode layer 50 may need to be bridged via the second conductive layer 80.

Taking the first node N1 as an example, the source-drain patterns of the thin-film transistors (M0 and M1) may be electrically connected to the gate pattern of the thin-film transistor (M0). Therefore, at the first node N1, the first metal pattern 202 may exemplarily refer to a portion of the gate pattern of the thin-film transistor (M0) (i.e., the portion of the gate pattern corresponding to the deep hole); and the second metal pattern 502 may exemplarily refer to a portion of the source-drain pattern of the thin-film transistors (M0 and/or M1) (i.e., the portion of the source-drain pattern corresponding to the shallow hole). The first metal pattern 202 and the second metal pattern 502 may be bridged via the first conductive pattern 802, which may be like other node positions and may not be described in detail herein.

It should be noted that FIG. 38 only exemplarily illustrates that the first metal pattern 202 may be electrically connected to the first conductive pattern 802 via the first through-hole 702 and the second through-hole 302; and the second metal pattern 502 may be electrically connected to the first conductive pattern 802 via the third through-hole 703, thereby realizing the bridge connection between the first metal pattern 202 and the second conductive pattern 802. Furthermore, FIG. 38 only exemplarily illustrates approximate positions of the first through-hole 702, the second through-hole 302, and the third through-hole 703, may not illustrate the dimension relationship between the first through-hole 702 and the second through-hole 302, or may not illustrate the second blocking pattern in the first conductive layer. The bridge connection between the first metal pattern 202 and the second metal pattern 502 at above-mentioned node positions may refer to above-mentioned embodiments for the deep-shallow-hole bridge connection. The configuration (design) of the film structures of the first insulating layer 70, the first conductive layer 60, and the second insulating layer 30 may be not described in detail herein. Subsequent embodiments may only illustrate the application positions of the deep-shallow-hole bridge connection; and the configuration (design) of the blocking pattern and the through-holes may refer to above-mentioned description.

In FIG. 38, the orthographic projections of the first metal pattern 202 and the second metal pattern 502 on the substrate are not overlapped with each other, which may be taken as an example for illustration. In other embodiments, the orthographic projection of the first metal pattern 202 on the substrate may be configured to cover the orthographic projection of the second metal pattern 502 on the substrate. Such configuration may reduce the space occupied by the electrostatic protection circuits, thereby reducing the frame width.

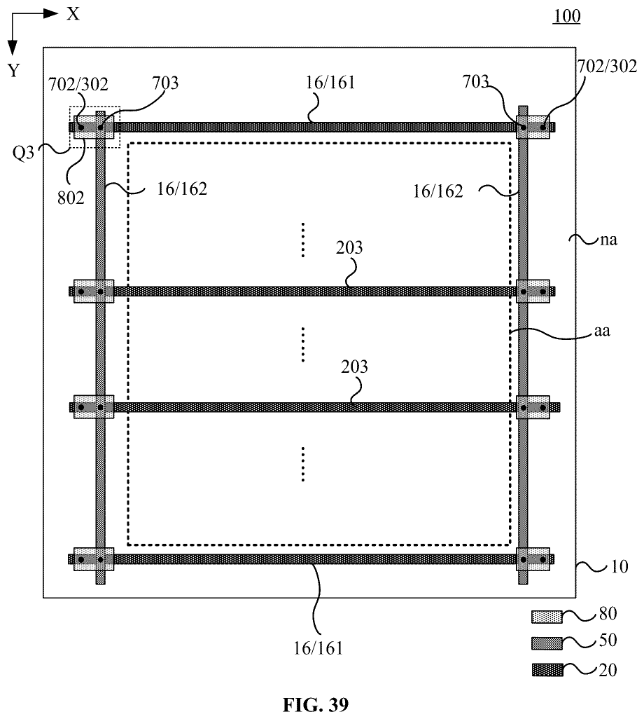

FIG. 39 illustrates another top-view structural schematic of an array substrate according to various embodiments of the present disclosure. Referring to FIG. 39, in addition to the common signal lines 203, the array substrate 100 may further include a peripheral common lines 16 within the non-display region na. The peripheral common line 16 may be configured to be electrically connected to the common signal line 203 within the display region aa, thereby transmitting the common signal from the non-display region na to the display region aa, and then to the common electrode.

Referring to FIGS. 1 and 39, optionally, the peripheral common line 16 may include the first peripheral wiring 161 on at least one side of the display region aa along the third direction Y, and the second peripheral wiring 162 on at least one side of the display region aa along the second direction X. The extension direction of the first peripheral wiring 161 may be same as the extension direction of the scan line 201, and the extension direction of the second peripheral wiring 162 may be same as the extension direction of the data line 501.

Referring to FIG. 39, optionally, one of the first peripheral wiring 161 and the second peripheral wiring 162 may be in the gate metal layer 20, and another one of the first peripheral wiring 161 and the second peripheral wiring 162 may be in the source-drain electrode layer 50. In FIG. 39, the first peripheral wiring 161 is in the gate metal layer 20, and the second peripheral wiring 162 is in the source-drain electrode layer 50, which may be taken as an example for illustration. In other embodiments, the first peripheral wiring 161 may be in the source-drain electrode layer 50, and the second peripheral wiring 162 may be in the gate metal layer 20.

Referring to FIG. 39, the film layer of the second peripheral wiring 162 may be different from the film layer of the first peripheral wiring 161 and the film layer of the common signal line 203. Therefore, the second peripheral wiring 162 and the first peripheral wiring 161 may be bridged using the deep or shallow holes; and the second peripheral wiring 162 and the common signal line 203 may be bridged using the deep or shallow holes. Such deep-shallow-hole bridging design may be applied to electrical connections between wirings on different layers for transmitting the common signals.

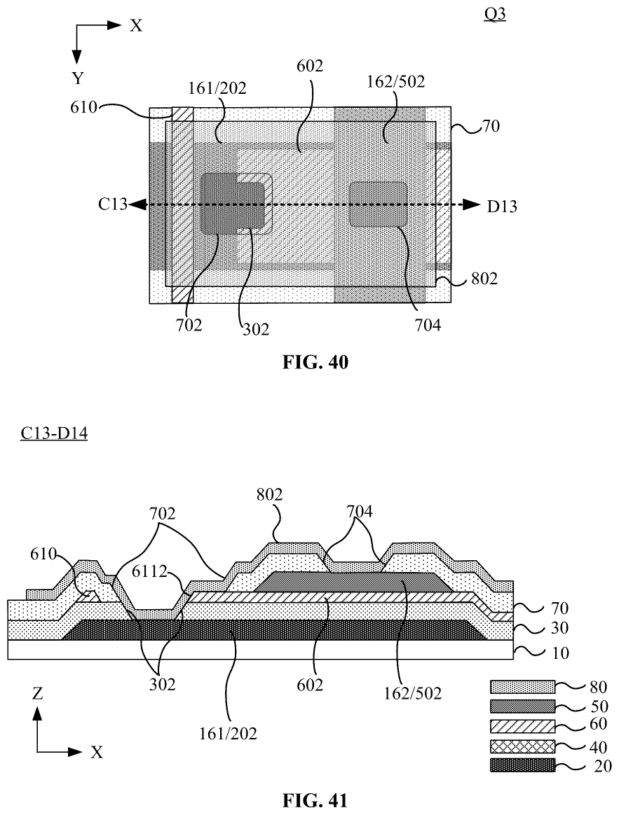

Exemplarily, FIG. 40 illustrates an enlarged structural schematic of a Q3 region in FIG. 39; and FIG. 41 illustrates a cross-sectional structural schematic of an array substrate along a cross-sectional line C13-D13 in FIG. 40. Referring to FIGS. 40-41, in one embodiment, the first metal pattern 202 may exemplarily refer to the portion of the first peripheral wiring 161 that may be electrically connected to the first conductive pattern 802 via the deep holes (e.g., the first through-hole 702 and the second through-hole 302); and the second metal pattern 502 may exemplarily refer to the portion of the second peripheral wiring 162 that may be electrically connected to the first conductive pattern 802 via the shallow holes (e.g., the fourth through-hole 704). The first conductive pattern 802 may bridge the first peripheral wiring 161 and the second peripheral wiring 162.

Optionally, in one embodiment, the first conductive pattern 802 may transmit the common signal. Therefore, the first conductive pattern 802 and the common electrode 15 may be connected or spaced apart from each other, which may be not limited in embodiments of the present disclosure.

Furthermore, referring to FIGS. 40-41, in one embodiment, the second peripheral wirings 162 may be at the left and right border regions, and the circuit structure and the wiring layout may be complex. Therefore, the design that the second blocking pattern 602 is configured with the first notch 6112 may be used. Such configuration may improve poor bridging between deep and shallow holes and realize avoidance of other structures in the first conductive layer 60. 610 is configured to label the connecting line or the capacitor structure. For example, the connecting line 610 or the capacitor structure 610 in FIGS. 40-41 may be avoided; or the structures located outside the first conductive layer 60 may be avoided.

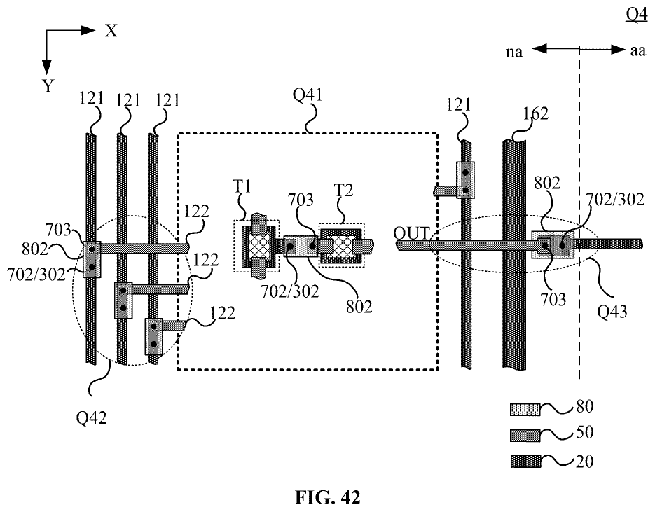

Moreover, referring to FIG. 1, the gate drive circuit 12 may be electrically connected to the scan line 201. For example, the gate drive circuit 12 may include multiple cascaded shift register circuit modules; and the output terminal of the shift register circuit module may be electrically connected to the scan line 201. FIG. 42 illustrates an enlarged structural schematic of a Q4 region in FIG. 1. FIG. 42 illustrates partial layout structure of the region where the first-stage shift register circuit module is located. As shown in FIG. 42, the shift register circuit module may be in the central region Q41 and formed by the plurality of thin-film transistors and capacitors. In the shift register circuit module, the gate of one transistor may be electrically connected to the source-drain electrode of another transistor. However, the gate electrode and the source-drain electrode of such transistors may be in different film layers. Therefore, the deep-shallow-hole bridging design may be configured to electrically connect the gate electrodes and the source-drain electrodes of different transistors in the shift register circuit module. For example, FIG. 42 illustrates two transistors, that is, the first transistor T1 and the second transistor T2, where the gate electrode of the first transistor T1 may be bridged with the source-drain electrode of the second transistor T2 via the first conductive pattern 802. In one embodiment, the first metal pattern 202 may exemplarily refer to a portion of the gate pattern of the first transistor T1, and the second metal pattern 502 may exemplarily refer to a portion of the source-drain pattern of the second transistor T2.

Referring to FIG. 42, the plurality of signal lines may be configured on the left and right sides of the shift register circuit module. Such signal lines may include the first signal line 121 for providing an operating signal to the shift register circuit module. Other signal lines such as the peripheral common line (the second peripheral wiring 162) shown in FIG. 42 may be also included. In one embodiment, the first signal line 121 may provide signals such as level signals, clock signals and reset signals for controlling the operation of the shift register circuit module. Referring to the left region Q42 in FIG. 42, the plurality of first signal lines 121 are arranged side by side along the second direction X. Therefore, the connecting line 122 between the first signal line 121 and the internal component of the shift register circuit may need to be arranged in other film layers to cross over other first signal lines 121. Since the first signal line 121 and the connecting line 122 are in different film layers, the deep-shallow-hole bridging design may be applied to the electrical connection between the first signal line 121 and the connecting line 122. For example, in FIG. 42, the first signal line 121 may be in the gate metal layer 20, and the connecting line 122 between the first signal line 121 and the shift register circuit module may be in the source-drain electrode layer 50 and bridged by the first conductive pattern 802 in the second conductive layer 80, which may be taken as an example for illustration. In one embodiment, the first metal pattern 202 may exemplarily refer to a portion of the first signal line 121, and the second metal pattern 502 may exemplarily refer to a portion of the connecting line 122.

Furthermore, referring to the region Q43 on the right side of FIG. 42, it may be understood that the output terminal of the shift register circuit module is the output terminal electrode (the source electrode or the drain electrode) of one of the thin-film transistors. The source electrode and the drain electrode of the thin-film transistor may be in the source-drain electrode layer 50, and the scan line 201 may be in the gate metal layer 20. Therefore, the output terminal (OUT) of the shift register circuit module may be electrically connected to the scan line 201, which may need bridging connection between the source-drain electrode layer 50 and the gate metal layer 20 through the second conductive layer 80. That is, the deep-shallow-hole bridging solution may be used to bridge the output electrode of the shift register circuit module and the scan line 201. In one embodiment, the first metal pattern 202 may exemplarily refer to a portion of the scan line 201, and the second metal pattern 502 may exemplarily refer to a portion of the wiring extending from the output electrode of the shift register circuit module.

In the regions Q42 and Q43 of FIG. 42, optionally, the orthographic projection of the first metal pattern in the gate metal layer 20 on the substrate may cover the orthographic projection of the second metal pattern in the source-drain electrode layer 50 on the substrate, which may be beneficial for reducing the space occupied by the deep and shallow holes, thereby reducing the border width.

The above provides some embodiments of deep-shallow-hole bridging. Obviously, application scenarios of the deep-shallow-hole bridging design may be not limited in the present disclosure and may be configured based on actual needs.

Hereinafter, the first through-hole 702 and the second through-hole 302 formed in different processes is taken as an example to further explain the principle of improving the reliability of deep holes in the present disclosure.

As disclosed above, the first through-hole 702 and the second through-hole 302 may be formed in different processes, that is, formed sequentially in different processes. For example, the second through-hole 302 may be processed immediately after entire second insulating layer 30 is formed; and the first through-hole 702 may be processed immediately after entire first insulating layer 70 is formed. Although such process increases costs, the through-holes in the second insulating layer 30 and the through-holes in the first insulating layer 70 may be flexibly designed (configured) based on actual needs, which may allow the through-holes in two film layers to be independently configured without interfering with each other.

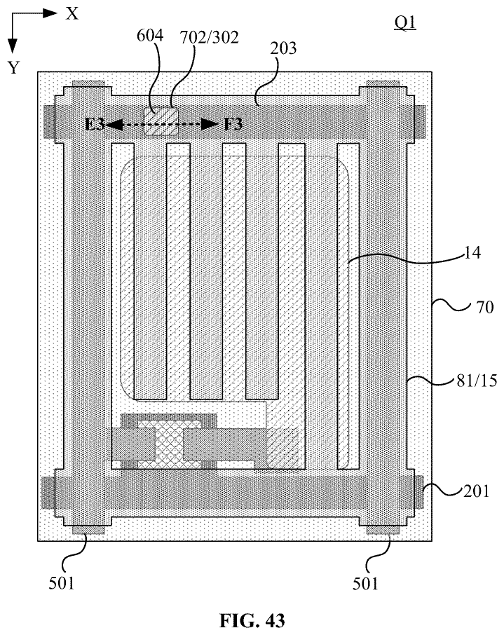

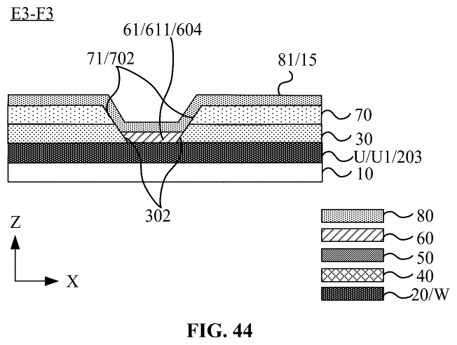

FIG. 43 illustrates another enlarged structural schematic of a Q1 region in FIG. 1; and FIG. 44 illustrates a cross-sectional structural schematic of the array substrate along a cross-sectional line E3-F3 in FIG. 43. Referring to FIGS. 43-44, optionally, the first type blocking patterns 611 may include the third blocking pattern 604; the third blocking pattern 604 may be configured to be insulated from the pixel electrode 14; at least a portion of the third blocking pattern 604 may be within the second through-hole 302; the third blocking pattern 604 may be in a contact with the first type metal pattern U1 and the conductive pattern 81, respectively; and the conductive pattern 81 may be electrically connected to the first type metal pattern U1 via the third blocking pattern 604.

In one embodiment, the first type metal pattern U1 and the conductive pattern 81 electrically connected to each other through the first through hole 702 and the second through hole 302 may be not directly and electrically connected. Instead, the third blocking pattern 604 may be configured in the first conductive layer 60, such that at least a portion of the third blocking pattern 604 may be within the second through hole 302, and the third blocking pattern 604 may be in a contact with the first type metal pattern U1 and the conductive pattern 81, respectively. In such way, the conductive pattern 81 may be indirectly and electrically connected to the first type metal pattern U1 via the third blocking pattern 604.

In one embodiment, based on the formation manner that the first through-hole 702 and the second through-hole 302 are formed in different processes, by configuring at least a portion of the third blocking pattern 604 within the second through-hole 302, the slope depth of the second conductive layer 80 at the first through-hole 702 and the second through-hole 302 may be reduced, thereby lowering the cracking risk in the second conductive layer 80. Furthermore, the first type metal pattern U1 may be covered by the third blocking pattern 604. Therefore, oxidation problem of the first type metal pattern U1 during the formation of the first through-hole 702 may be reduced, and the conductive pattern 81 may overlap and cover the third type blocking pattern 604, which may reduce the connection impedance between the conductive pattern 81 and the first type metal pattern U1.

Exemplarily, referring to FIGS. 43-44, the conductive pattern 81 may be the common electrode 15, the first type metal pattern U1 may be the common signal line 203, and the common electrode 15 and the common signal line 203 may be electrically connected to each other via the first through-hole 702 and the second through-hole 302, which may be taken as an example for illustration. The third blocking pattern 604 may be configured, such that at least a portion of the third blocking pattern 604 may be within the second through-hole 302. In such way, the third blocking pattern 604 may be in a contact with the common electrode 15 and the common signal line 203, respectively. Therefore, indirect electrical connection between the common electrode 15 and the common signal line 203 may be implemented, which may reduce the slope depth of the common electrode 15, and decrease the cracking risk of the common electrode 15. Furthermore, the common electrode 15 may overlap and cover the third blocking pattern 604, which may be beneficial for reducing the connection impedance between the common electrode 15 and the common signal line 203.

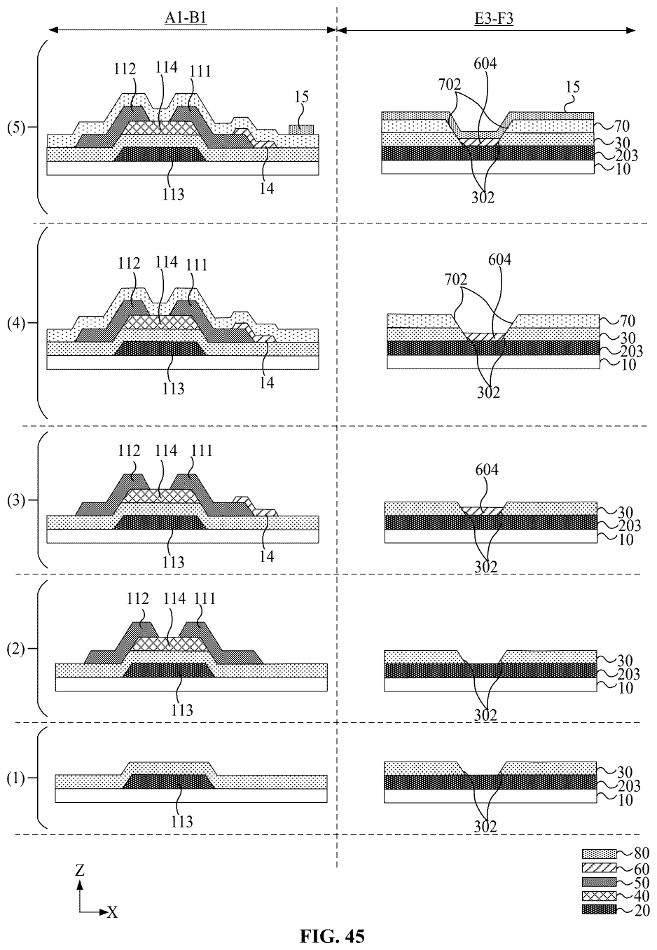

Exemplarily, FIG. 45 illustrates another flowchart of a formation process of an array substrate according to various embodiments of the present disclosure. The left part of FIG. 45 illustrates the main formation process of the structure shown in FIG. 5, and the right part of FIG. 45 illustrates the main formation process of the structure shown in FIG. 44. Referring to FIG. 45, the first through hole 702 may be configured in the first insulating layer 70; the second through hole 302 may be configured in the second insulating layer 30; and the formation process that the first through hole 702 and the second through hole 302 are formed in different processes is further described in detail.

In the formation process of the array substrate, referring to exemplary step (1) in FIG. 45, the gate metal layer 20 and the second insulating layer 30 may be first formed on the substrate 10 in sequence. When forming the gate metal layer 20, the metal patterns, such as the gate electrode 113 of the thin-film transistor, the scan line and the common signal line 203, may be formed in the gate metal layer 20 by a wet etching process. When forming the second insulating layer 30, the through hole, such as the second through hole 302, passing through the second insulating layer 30 may be formed by a dry etching process. In one embodiment, the second through hole 302 may expose a portion of the common signal line 203. In other embodiments, other through holes may be formed in the second insulating layer 30 according to actual needs, which may not be limited in embodiments of the present disclosure. When the deep-shallow-hole bridging solution (i.e., design) is applied, the first metal pattern may also be formed in the gate metal layer 20.

Referring to exemplary step (2) of FIG. 45, the active layer 40 and the source-drain electrode layer 50 may be then formed in sequence on the side of the second insulating layer 30 away from the substrate. When the active layer 40 is formed, the active layer pattern 114 of the thin-film transistor may be formed; and when the source-drain electrode layer 50 is formed, the metal patterns, such as the first electrode 111 and the second electrode 112 of the thin-film transistor and the data line, may be formed in the source-drain electrode layer 50 by a wet etching process. After the source-drain electrode layer 50 is formed, a portion of the second insulating layer 30 may be covered by the metal pattern in the source-drain electrode layer 50, and another portion of the second insulating layer 30 may be exposed. When the deep-shallow-hole bridging solution is applied, the second metal pattern may also be formed in the source-drain electrode layer 50.

Referring to exemplary step (3) of FIG. 45, the first conductive layer 60 may be then formed on the side of the source-drain electrode layer 50 away from the substrate 10. When forming the first conductive layer 60, the patterns, such as the pixel electrode 14 and the third blocking pattern 604, may be formed in the first conductive layer 60 by a wet etching process. As shown in the right part of exemplary step (3) in FIG. 45, the second through hole 302 may be formed in the second insulating layer 30, and the third blocking pattern 604 may be formed in the first conductive layer 60 in one embodiment. Therefore, at least a portion of the third blocking pattern 604 may be in the second through hole 302. The third blocking pattern 604 may be used to fill a portion of the second through hole 302, which may reduce subsequent the slope depth of the second conductive layer at such position.

Referring to exemplary step (4) in FIG. 45, the first insulating layer 70 may be then formed on the side of the first conductive layer 60 away from the substrate 10, and the through hole may be formed in the first insulating layer 70 as needed. In one embodiment, the first through hole 702 may be configured in the first insulating layer 70. The first through hole 702 and the second through hole 302 may be connected to each other, and the first through hole 702 may expose the third blocking pattern 604.

Referring to exemplary step (5) of FIG. 45, the second conductive layer 80 may be then formed on the side of the first insulating layer 70 away from the substrate 10. Similarly, through a wet etching process, the pattern such as the common electrode 15 may be formed in the second conductive layer 80. The common electrode 15 may be in a contact with the third blocking pattern 604 and indirectly and electrically connected to the common signal line 203 through the third blocking pattern 604. Since the third blocking pattern 604 fills a portion of the second through hole 302, the slope (extending) difficulty of the common electrode 15 at the first through hole 702 and the second through hole 302 may be reduced, which may reduce the cracking risk. Furthermore, the common electrode 15 may also overlap and cover the third blocking pattern 604, which may reduce the connection impedance between the common electrode 15 and the common signal line 203. When the deep-shallow-hole bridging design is applied, the conductive pattern for bridging the first metal pattern and the second metal pattern may also be formed in the second conductive layer 80.

Referring to FIG. 44, it should be noted that FIG. 44 only illustrates that the third blocking pattern 604 is entirely within the second through-hole 302. In such scenario, the conductive pattern 81 may be in a contact with the third blocking pattern 604 via the first through-hole 702 and the second through-hole 302 which are connected to each other; and the first through-hole 702 may expose entire third blocking pattern 604. In other embodiments, a portion of the third blocking pattern 604 may be located within the second through-hole 302.

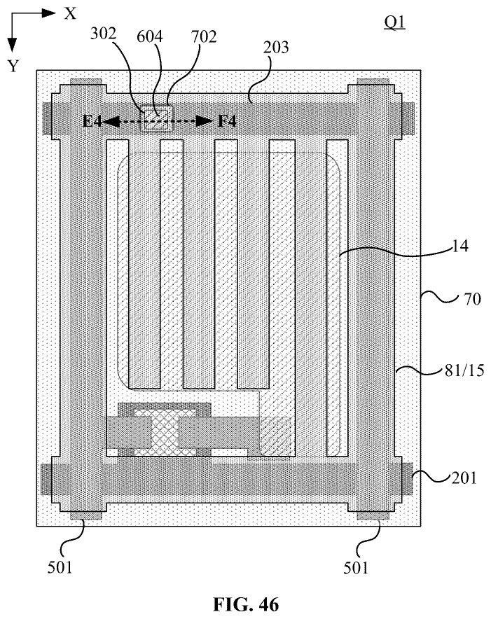

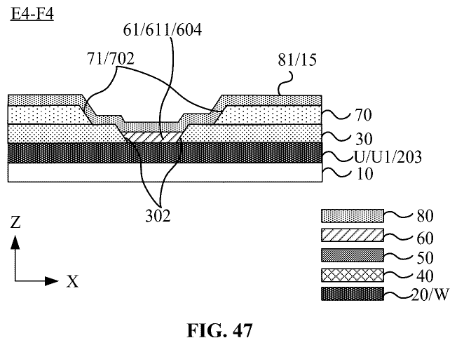

Referring to FIG. 44, it should be noted that when the third blocking pattern 604 is entirely within the second through-hole 302, FIG. 44 only illustrate that the inner walls of the first through-hole 702 and the second through-hole 302 are continuous, and the opening area of the lower opening of the first through-hole 702 is equal to the opening area of the upper opening of the second through-hole 302. FIG. 46 illustrates another enlarged structural schematic of a Q1 region in FIG. 1; and FIG. 47 illustrates a cross-sectional structural schematic of the array substrate along a cross-sectional line E4-F4 in FIG. 46. Referring to FIGS. 46-47, in other embodiments, the first through-hole 702 and the second through-hole 302 may be formed in different processes, such that the etching time may be controlled to ensure that the first through-hole 702 is processed just in time. In such way, even if the third blocking pattern 604 is entirely within the second through-hole 302, and the second insulating layer 30 is not protected by the blocking pattern, the opening area of the lower opening of the first through-hole 702 may be realized to be greater than the opening area of the upper opening of the second through-hole 302, thereby being beneficial for the formation of steps on the inner wall of the deep hole (the part of the upper surface of the second insulating layer 30 forms a step surface) and for further reducing the slope cracking risk of the second conductive layer 80.

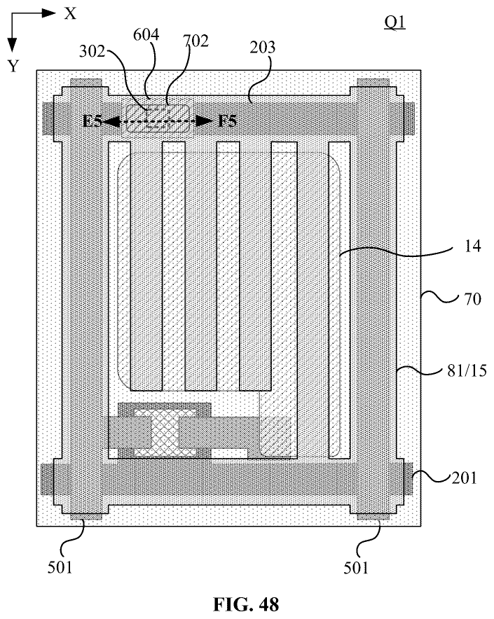

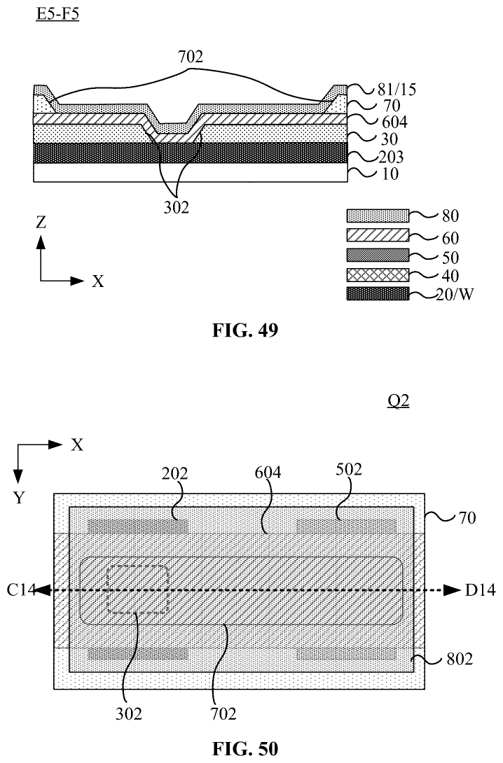

FIG. 48 illustrates another enlarged structural schematic of a Q1 region in FIG. 1; and FIG. 49 illustrates a cross-sectional structural schematic of an array substrate along a cross-sectional line E5-F5 in FIG. 48. Referring to FIGS. 48-49, optionally, the orthographic projection of the region,, where the first through-hole 702 is located,, on the substrate 10 may be greater than the orthographic projection of the region, where the second through-hole 302 is located, on the substrate 10; and the orthographic projection of the third blocking pattern 604 on the substrate 10 may be greater than the orthographic projection of the region,, where the first through-hole 702 is located,, on the substrate 10.

Referring to FIGS. 48-49, by configuring that the orthographic projection of the region,, where the first through-hole 702 is located,, on the substrate 10 is greater than the orthographic projection of the region, where the second through-hole 302 is located, on the substrate 10, the opening area of the lower opening of the first through-hole 702 may be greater than the opening area of the upper opening of the second through-hole 302, thereby forming steps on the inner walls of the deep hole and being beneficial for reducing the slope (extending) difficulty of the second conductive layer 80 (e.g., the common electrode 15) and reducing the cracking risk. Furthermore, by configuring that the orthographic projection of the third blocking pattern 604 on the substrate 10 is greater than the orthographic projection of the region, where the first through-hole 702 is located, the first conductive layer 60 may be configured as an etch blocking structure for the first insulating layer 70, thereby protecting the second insulating layer 30. For example, the opening area of the first through-hole 702 may be relatively large. If the first insulating layer 70 corresponding to the region, where the first through-hole 702 is located, is in a contact with the second insulating layer 30, over-etching the second insulating layer 30 may occur during the formation process of the first through-hole 702 if the etching time is not accurately controlled. In one embodiment, while increasing the opening area of the first through-hole 702, the dimension of the third blocking pattern 604 may be also increased. In such way, the third blocking pattern 604 may be used to protect the second insulating layer 30 below the third blocking pattern 604, which may prevent over-etching of the second insulating layer 30 and reduce the needs for process precision; furthermore, the contact area between the second conductive layer 80 (e.g., the common electrode 15) and the third blocking pattern 604 may be increased, which may further reduce the connection impedance.

As disclosed above, in above-mentioned embodiments, the electrical connection between the common electrode and the common signal line via the deep holes may be taken as an example to describe technical solutions for forming the first through-holes and the second through-holes in different processes. Regarding the deep-shallow-hole bridging solution, when the first through-holes and the second through-holes are formed in different processes, it may be difficult to adjust the pattern shapes of the metal patterns, which need to be connected in the source-drain electrode layer and the gate metal layer, to achieve the electrical connection only via the through-holes passing through the second insulating layer. In such scenario, the second conductive layer may still be used to realize the bridging of the metal patterns in the source-drain electrode layer and the gate metal layer.

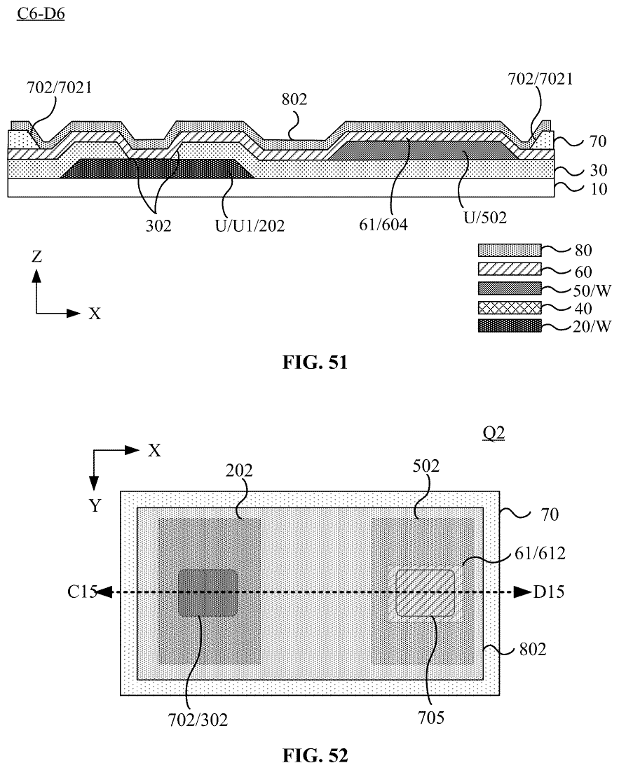

Exemplarily, FIG. 50 illustrates another enlarged structural schematic of a Q2 region in FIG. 1; and FIG. 51 illustrates a cross-sectional structural schematic of the array substrate along a cross-sectional line C14-D14 in FIG. 50. Referring to FIGS. 50-51, when the gate metal layer 20 includes the first metal pattern 202, the source-drain electrode layer 50 includes the second metal pattern 502, and the second conductive layer 80 includes the first conductive pattern 802, and when the first metal pattern 202 and the second metal pattern 502 are bridged via the first conductive pattern 802, optionally, the first conductive layer 60 may include the third blocking pattern 604, at least a portion of the third blocking pattern 604 may be located within the second through-hole 302, and the third blocking pattern 604 may be in a contact with the first metal pattern 202 and the first conductive pattern 802, respectively. Such configuration may reduce the slope cracking problem of the first conductive pattern 802 at the deep hole. Such solution may be applied to any of above-mentioned embodiments of the deep-shallow-hole bridging solution, which may not be described in detail herein.

Referring to FIGS. 50-51, furthermore, optionally, the orthographic projection of the region, where the first through-hole 702 is located, on the substrate 10 may be greater than the orthographic projection of the region, where the second through-hole 302 is located, on the substrate 10; and the orthographic projection of the third blocking pattern 604 on the substrate 10 may be greater than the orthographic projection of the region, where the first through-hole 702 is located, on the substrate 10. In such way, the slope cracking problem of the first conductive pattern 802 at the deep hole may be reduced, and the second insulating layer 30 may be protected through the third blocking pattern 604, which may prevent over-etching of the second insulating layer 30 and reduce the process precision needs. Furthermore, the contact area between the first conductive pattern 802 and the third blocking pattern 604 may be increased, and the connection impedance between the first metal pattern 202 and the second metal pattern 502 may be reduced. Moreover, referring to FIGS. 50-51, when the first conductive layer 60 is located on the side of the source-drain electrode layer 50 away from the substrate, the third blocking pattern 604 may also protect the second metal pattern 502, which may prevent oxidation problem of the second metal pattern 502.

It should be noted that, for the shallow-hole bridging solution illustrated in FIGS. 50-51, the third blocking pattern 604 may extend from the region of the first metal pattern 202 to the region of the second metal pattern 502, which may be taken as an example for illustration. As disclosed above, such configuration may improve the connection reliability between the first metal pattern 202 and the second metal pattern 502 and be beneficial for reducing the connection impedance therebetween. In other embodiments, the third blocking pattern 604 may be also not overlapped with the second metal pattern 603 along the first direction Z.

It should also be noted that in FIGS. 50-51, the first through-hole 702 may extend from the region of the first metal pattern 202 to the region of the second metal pattern 502 and may be overlapped with the first metal pattern 202 and the second metal pattern 502 respectively along the first direction Z, which may be taken as an example for illustration. Such configuration may significantly increase the contact area between the first conductive pattern 802 and the third blocking pattern 604 and reduce the connection impedance. In other embodiments, as described above, the first insulating layer 70 may also include the first through-hole 702 and the third through-hole 302 which are spaced apart from each other, which may be not described in detail herein.

It should also be noted that in FIGS. 50-51, the first conductive layer 60 where the pixel electrode is located may be on the side of the source-drain electrode layer 50 away from the substrate. In other embodiments, when the source-drain electrode layer 50 is located on the side of the first conductive layer 60 away from the substrate, such configuration may also be adopted. When the first through-hole 702 and the second through-hole 302 are formed in different processes, at least a portion of the third blocking pattern 604 may be configured within the second through-hole 302, such that the first conductive pattern 802 may be in a contact with the first metal pattern 202 via the third blocking pattern 604. Furthermore, the third blocking pattern 604 may be extended to the region where the second metal pattern 502 is located, such that the second metal pattern 502 may be in a contact with the first conductive pattern 802 and the third blocking pattern 604, respectively.

As disclosed above, in above-mentioned embodiments, taking the formation of the first through-hole 702 and the second through-hole 302 in same process and the formation of the first through-hole 702 and the second through-hole 302 in different processes as examples, the film layer design in the array substrate is described in detail, combined with the deep hole connection solutions needed (e.g., simple deep hole connection and the deep-shallow-hole bridging).

Referring to FIGS. 2-3, in some embodiments, in addition to bridging with the metal patterns in the gate metal layer 20, some metal patterns in the source-drain electrode layer 50 may also be electrically connected to the conductive patterns in the second conductive layer 80 simply through the first type through-hole 71 in the first insulating layer 70 (refer to the shallow hole connection solution). In such scenario, corresponding blocking pattern 61 may be configured in the first conductive layer 60 to reduce oxidation problem of such metal patterns by the etching gas.

Referring to FIGS. 2-3, when the first conductive layer 60 is located on the side of the source-drain electrode layer 50 away from the substrate, optionally, the first metal layer W may include the source-drain electrode layer 50; the metal patterns U may include the second type metal pattern U2 in the source-drain electrode layer 50; the first type through-holes 71 may include the fifth through-hole 705; the blocking patterns 61 may include the second type blocking pattern 612; the fifth through-hole 705 may expose a portion of the second type blocking pattern 612; and the second type blocking pattern 612 may be in a contact with and electrically connected to the second type metal pattern U2, and may be in a contact with and electrically connected to the conductive pattern 81 via the fifth through-hole 705.

The second type metal pattern U2 may refer to a metal pattern in the source-drain electrode layer 50 that needs to be electrically connected to the conductive pattern 81 in the second conductive layer 80 through a shallow hole, regardless of whether the second type metal pattern U2 needs to be bridged with a metal pattern in the gate metal layer 20.

The second type blocking pattern 612 may refer to a blocking pattern in the first conductive layer 60 exposed by a shallow hole (e.g., the fifth through-hole 705) in the first insulating layer 70.

For example, in one embodiment, the orthographic projection of the region, where the fifth through hole 705 is located, on the substrate 10 may be in the orthographic projection of the second type blocking pattern 612 on the substrate 10. The second type blocking pattern 612 may cover at least a portion of the second type metal pattern U2, which may only need to ensure that the second type metal pattern U2 is not exposed by the fifth through hole 705. Such configuration may prevent the second type metal pattern U2 from being oxidized by the etching gas, which may refer to above description for detail and may not be described in detail herein.

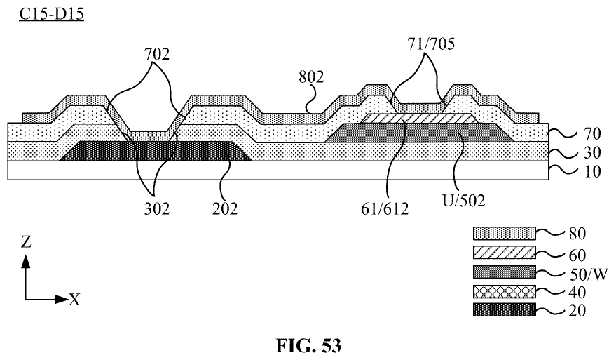

FIG. 52 illustrates another enlarged structural schematic of a Q2 region in FIG. 1; and FIG. 53 illustrates a cross-sectional structural schematic of the array substrate along a cross-sectional line C15-D15 in FIG. 52. Referring to FIGS. 52-53, when the gate metal layer 20 includes the first metal pattern 202, the source-drain electrode layer 50 includes the second metal pattern 502, and the second conductive layer 80 includes the first conductive pattern 802, and when the first metal pattern 202 and the second metal pattern 502 are bridged via the first conductive pattern 802, optionally, the first conductive layer 60 may include the second type blocking pattern 612; the first insulating layer 70 may include the first through-hole 702 and the fifth through-hole 705 which are spaced apart from each other; the second insulating layer 30 may include the second through-hole 302; the first through-hole 702 and the second through-hole 302 may be configured to be connected to each other; the first conductive pattern 802 may be electrically connected to the first metal pattern 202 via the first through-hole 702 and the second through-hole 302; the fifth through-hole 705 may expose a portion of the second type blocking pattern 612; and the second type blocking pattern 612 may be in a contact with and electrically connected to the second metal pattern 502, and may be in a contact with and electrically connected to the first conductive pattern 802 via the fifth through-hole 705.

For example, in one embodiment, for the deep-shallow-hole bridging solution, the blocking pattern (the second type blocking pattern 612) may be configured only for the shallow hole (the fifth through-hole 705), which may reduce the oxidation problem of the metal patterns of the source-drain electrode layer corresponding to the shallow hole by the etching gas in the deep-shallow-hole bridging solution. Above-mentioned problem may be particularly severe when the first through-hole 702 and the second through-hole 302 are formed in same process, which may be effective reduced by adopting above-mentioned solution, that is, the blocking pattern (the second type blocking pattern 612) may be configured only for the shallow hole (the fifth through-hole 705).

As disclosed above, for the deep-shallow-hole bridging solution, regardless of whether the first through-hole 702 and the second through-hole 302 are formed in same process, when the first conductive layer 60 is located on the side of the source-drain electrode layer 50 away from the substrate 10, the blocking pattern 61 may be configured only for the deep holes (the first through-hole 702 and the second through-hole 302 which are connected to each other) to reduce the slope cracking problem of the second conductive layer 80 at the deep hole (as shown in FIG. 11); or the blocking pattern 61 may be configured only for the shallow hole (the fifth through-hole 705) to reduce the oxidation problem of the metal pattern (the second metal pattern 502) in the source-drain electrode layer 50 by the etching gas and reduce the connection impedance (as shown in FIG. 53; or the blocking pattern may be configured to be overlapped with both the first metal pattern 202 and the second metal pattern 502, such that, the reliability problems at the deep and shallow holes may be reduced (as shown in FIGS. 15 and 51).

As disclosed above, based on the film layer design that the first electrode 111 and the second electrode 112 are in a direct contact with the active layer pattern 114, respectively, and the pixel electrode 14 is in the first conductive layer 60 and in a direct contact with the first electrode 111, the arrangement manners of the through holes in each insulating layer and the blocking patterns in the first conductive layer for the simple deep hole connection solution, the simple shallow hole connection solution, and the deep-shallow-hole bridging solution in the array substrate are described in detail.

In other embodiments, optionally, the pixel electrode 14 and the first electrode 111 may be not in direct contact, that is, the insulating layer may be between the film layers where the pixel electrode 14 and the first electrode 111 are located; and the pixel electrode 14 and the first electrode 111 may be electrically connected via the through holes passing through such insulating layer.

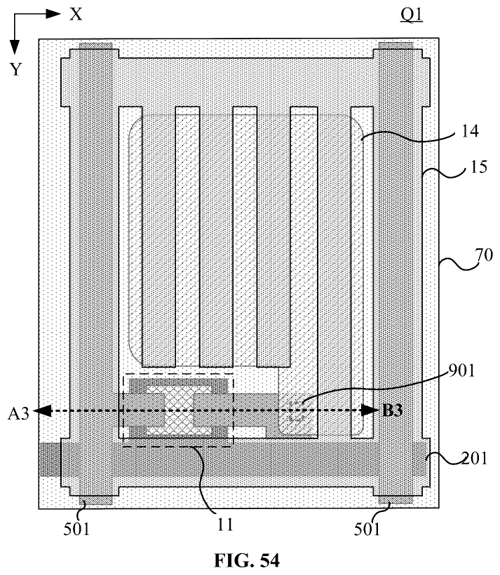

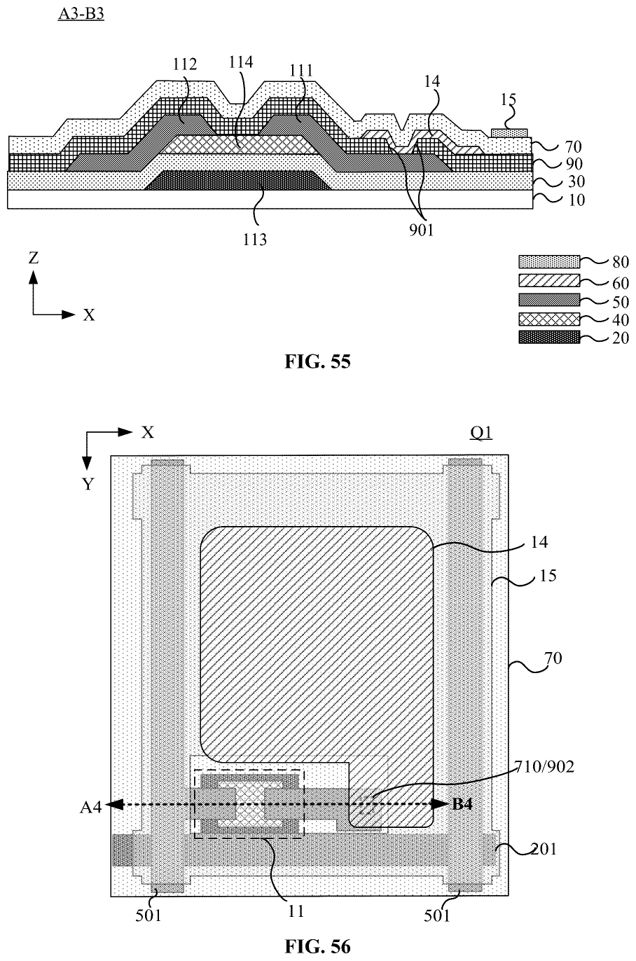

Exemplarily, FIG. 54 illustrates another enlarged structural schematic of a Q1 region in FIG. 1; and FIG. 55 illustrates a cross-sectional structural schematic of the array substrate along a cross-sectional line A3-B3 in FIG. 54. Referring to FIGS. 54-55, optionally, the first conductive layer 60 may include the pixel electrode 14; the second conductive layer 80 may include the common electrode 15; the array substrate may further include the third insulating layer 90 located between the source-drain electrode layer 50 and the first conductive layer 60; and the pixel electrode 14 and the first electrode 111 may be electrically connected via the through-holes (the through-hole 901 in FIG. 55) passing through the third insulating layer 90.

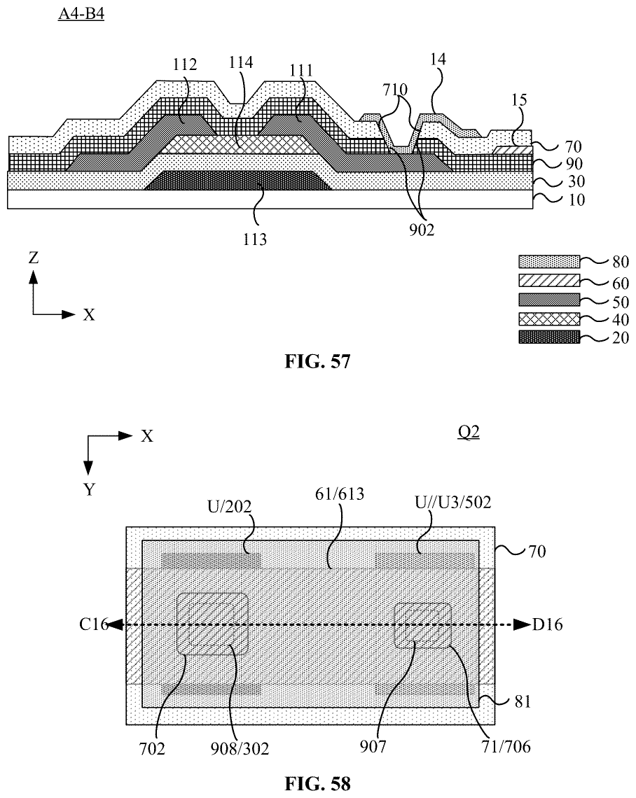

Exemplarily, FIG. 56 illustrates another enlarged structural schematic of a Q1 region in FIG. 1; and FIG. 57 illustrates a cross-sectional structural schematic of an array substrate along a cross-sectional line A4-B4 in FIG. 56. Referring to FIGS. 56-57, optionally, the first conductive layer 60 may include the common electrode 15; the second conductive layer 80 may include the pixel electrode 14; the array substrate may further include the third insulating layer 90 located between the source-drain electrode layer 50 and the first conductive layer 60; and the pixel electrode 14 and the first electrode 111 may be electrically connected via through-holes (the through-hole 710 and the through-hole 902 in FIG. 55) passing through the first insulating layer 70 and the third insulating layer 90.

As disclosed above, when the pixel electrode 14 and the first electrode 111 are not in direct contact but electrically connected via the through-hole, optionally, the pixel electrode 14 may be in the first conductive layer 60, and the common electrode 15 may be in the second conductive layer 80 (FIG. 55); or the pixel electrode 14 may be in the second conductive layer 80, and the common electrode 15 may be in the first conductive layer 60.

Furthermore, based on the film layer design that the pixel electrode 14 and the first electrode 111 are not in a contact with each other, the configuration manner of the blocking pattern in the first conductive layer is further described hereinafter.

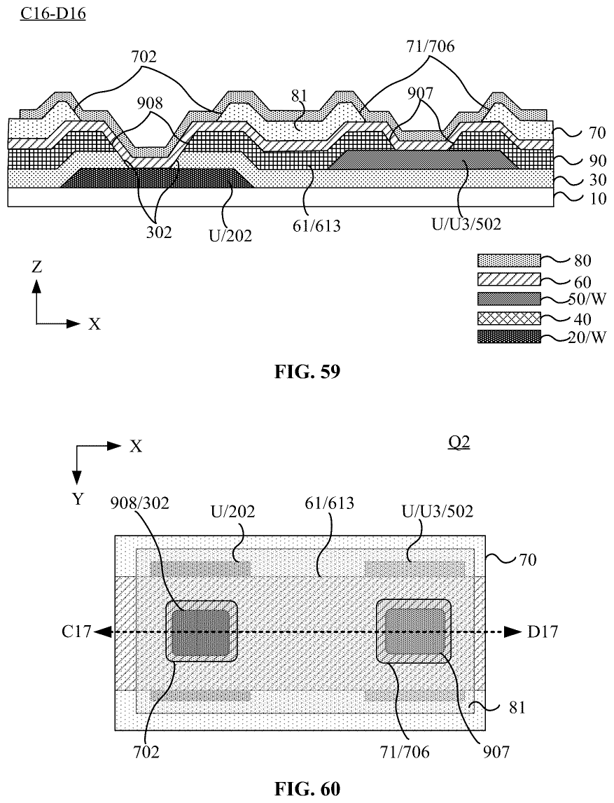

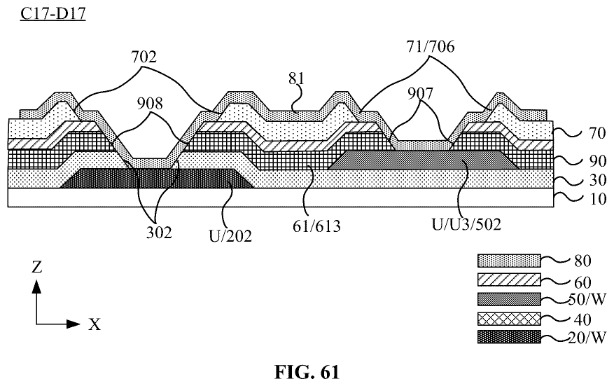

FIG. 58 illustrates another enlarged structural schematic of a Q2 region in FIG. 1; FIG. 59 illustrates a cross-sectional structural schematic of an array substrate along a cross-sectional line C16-D16 in FIG. 58; FIG. 60 illustrates another enlarged structural schematic of a Q2 region in FIG. 1; and FIG. 61 illustrates a cross-sectional structural schematic of an array substrate along a cross-sectional line C17-D17 in FIG. 60. Referring to FIGS. 58-61, optionally, the first metal layer W may at least include the source-drain electrode layer 50 which may include the first electrode 111 and the second electrode 112 of the thin-film transistor 11; the metal patterns U may include the third type metal pattern U3 in the source-drain electrode layer 50; the metal-like pattern U3 may be configured to be insulated from the first electrode 111 and the second electrode 112 of the thin-film transistor 11; the first type through-holes 71 may include the sixth through-hole 706; the third insulating layer 90 may be configured with the seventh through-hole 907; the sixth through-hole 706 and the seventh through-hole 907 may be configured to be connected to each other; the blocking patterns 61 may include the third type blocking pattern 613; the sixth through-hole 706 may expose at least a portion of the third type blocking pattern 613; and a portion of the conductive pattern 81 may be in a contact with and electrically connected to the third type blocking pattern 613 via at least the sixth through-hole 706 and may be also electrically connected to the third type metal pattern U3 via the sixth through-hole 706 and the seventh through-hole 907 which are connected to each other.

For example, referring to FIGS. 59 and 61, in one embodiment, the quantity of insulating layers may be increased (the third insulating layer 90 is added); the sixth through-hole 706 and the seventh through-hole 907 which are connected to each other may form the shallow hole; the third type metal pattern U3 may refer to the metal pattern in the source-drain electrode layer 50 corresponding to the shallow hole; and the third type metal pattern U3 may be electrically connected to the conductive pattern 81 in the second conductive layer 80 via the sixth through-hole 706 and the seventh through-hole 907 which are connected to each other.

Similarly, in one embodiment, the third type metal pattern U3 may or may not be bridged with the metal pattern in the gate metal layer 20 via the conductive pattern 81; and FIGS. 58-61 illustrate former deep-shallow-hole bridging solution as an example for illustration.

FIGS. 58-59, corresponding to FIGS. 54-55, illustrate the configuration manner of the blocking patterns 61 and the through-holes in each insulating layer when the pixel electrode 14 is in the first conductive layer 60 and the common electrode 15 is in the second conductive layer 80. In such scenario, the blocking pattern 61 (the third type blocking pattern 613) may be configured to be insulated from the pixel electrode 14 in same layer. The film layer originally used to form the pixel electrode 14 may be reused as the etch blocking structure layer for the first insulating layer 70, thereby reducing the reliability problems of the through-holes.

Referring to FIG. 55, when the pixel electrode 14 is in the first conductive layer 60, the third insulating layer 90 may need to be configured with a separate through-hole (901) for the electrical connection between the pixel electrode 14 and the first electrode 111. Therefore, the through-holes in the third insulating layer 90 and the first insulating layer 70 may need to be formed in different processes. Accordingly, referring to FIG. 59, in the deep-shallow-hole bridging solution, at the position of the shallow hole, the sixth through-hole 706 and the seventh through-hole 907 may be formed in different processes; at least a portion of the third type blocking pattern 613 may be located within the seventh through-hole 907; the third type blocking pattern 613 may be in a contact with the conductive pattern 81 and the third type metal pattern U3 (e.g., the second metal pattern 502 described above), respectively; and the conductive pattern 81 may be indirectly and electrically connected to the third type metal pattern U3 via the third type blocking pattern 613.

Furthermore, referring to FIG. 59 and above description, the third type blocking pattern 613 may extend into the deep hole region, which may reduce the slope cracking problem of the conductive pattern 81 at the deep hole. For example, at the deep hole position, the first insulating layer 70 may include the first through-hole 702; the third insulating layer 90 may include the eighth through-hole 908; the second insulating layer 30 may include the second through-hole 302; and the first through-hole 702, the eighth through-hole 908, and the second through-hole 302 may be sequentially connected to each other. The first through-hole 702 and the eighth through-hole 908 may be formed in different processes; and the second through-hole 302 and the eighth through-hole 908 may be formed in same process or in different processes, which may be not limited in embodiments of the present disclosure. Regardless of whether the second through-hole 302 and the eighth through-hole 908 are formed in same process, the second through-hole 302 and the eighth through-hole 908 may already exist when the third type blocking pattern 613 is formed in the first conductive layer 60. Therefore, if the third type blocking pattern 613 is extended to the deep hole region, a portion of the third type blocking pattern 613 may be located within the second through-hole 302 and the eighth through-hole 908 and in a contact with the first metal pattern 202 in the gate metal layer 20; and the conductive pattern 81 may be then indirectly and electrically connected to the first metal pattern 202 through the third type blocking pattern 613.

FIGS. 60-61, corresponding to FIGS. 56-57, illustrate the configuration manner of the blocking pattern 61 and the through-holes in various insulating layers when the common electrode 15 is in the first conductive layer 60 and the pixel electrode 14 is in the second conductive layer 80. In such scenario, the blocking pattern 61 (the third type blocking pattern 613) may be configured to be insulated from the common electrode 15 in same layer. The film layer originally used to form the common electrode 15 (the first conductive layer 60) may be reused as an etch blocking layer for the first insulating layer 70, thereby reducing the reliability problems of the through-holes.

Referring to FIG. 57, when the pixel electrode 14 is in the second conductive layer 80, the connecting through-hole between the pixel electrode 14 and the first electrode 111 must pass through both the first insulating layer 70 and the third insulating layer 90. In such scenario, the interconnected through-holes in the third insulating layer 90 and the first insulating layer 70 may be formed in different processes or in same process. Accordingly, referring to FIG. 61, in the deep-shallow-hole bridging solution, at the shallow hole position, the sixth through hole 706 and the seventh through hole 907 may be formed in same process, thereby effectively reducing formation costs. As shown in FIG. 61, when the sixth through hole 706 and the seventh through hole 907 are formed in same process, the seventh through hole 907 may expose a portion of the third type metal pattern U3 (e.g., the second metal pattern 502 described above). Due to the etch blocking effect of the third type blocking pattern 613, for the position of at least a portion of the contour of the seventh through hole 907, the cutoff position of the third type blocking pattern 613 may be substantially identical as the cutoff position of the third insulating layer 90. The conductive pattern 81 may be in a contact with the third type blocking pattern 613 via the sixth through hole 706 and may be in a contact with and electrically connected to the third type metal pattern U3 via the sixth through hole 706 and the seventh through hole 907 which are connected to each other.

Furthermore, referring to FIG. 61 and above description, the third type blocking pattern 613 may extend to the deep hole region, thereby reducing the slope fracture problem of the conductive pattern 81 at the deep hole. For example, at the position of the deep hole, the first insulating layer 70 may include the first through hole 702; the third insulating layer 90 may include the eighth through hole 908; the second insulating layer 30 may include the second through hole 302; and the first through hole 702, the eighth through hole 908, and the second through hole 302 may be connected in sequence. The first through hole 702 and the eighth through hole 908 may be formed in same process, and the second through hole 302 and the eighth through hole 908 may also be formed in same process. In such way, only one process may be needed to form deep holes and shallow holes, thereby reducing formation costs and improving production efficiency. When the first through-hole 702, the eighth through-hole 908, and the second through-hole 302 are formed in same process, due to the etch blocking effect of the third type blocking pattern 613, at the position of at least a portion of the contour of the eighth through-hole 908, the cutoff position of the third type blocking pattern 613 may be substantially identical as the cutoff position of the third insulating layer 90. The conductive pattern 81 may be in a contact with the third type blocking pattern 613 via the first through-hole 702 and may be in a contact with and electrically connected to the first metal pattern 202 via the first through-hole 702, the eighth through-hole 908, and the second through-hole 302 which are sequentially connected to each other.

It should be noted that FIGS. 59 and 61 only illustrate that the first insulating layer 70 includes the first through-hole 702 and the sixth through-hole 706 which are spaced apart from each other. In other embodiments, the first through-hole 702 and the sixth through-hole 706 may be connected to form a relatively large through-hole, thereby reducing the slope height of the second conductive layer 80.

As disclosed above, in above-mentioned embodiments, various film layer designs may be used as examples to describe the technical solutions of the present disclosure that the blocking pattern is in the first conductive layer to reduce the reliability problem of the through-holes.

In addition to above-mentioned reliability problems at the through-holes, when the pixel electrode and the first electrode of the thin-film transistor are in a direct contact with each other, certain reliability problems may be between the connection of the pixel electrode and the first electrode of the thin-film transistor. The technical solutions of embodiments of the present disclosures are described in detail to address such problem. The structural similarities with above-mentioned embodiments are not described in detail herein.

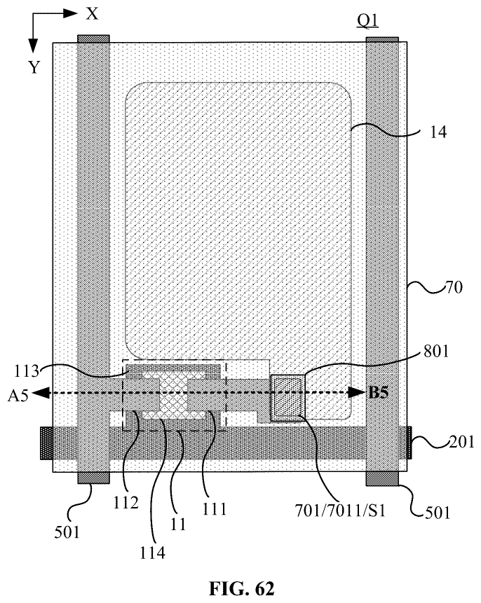

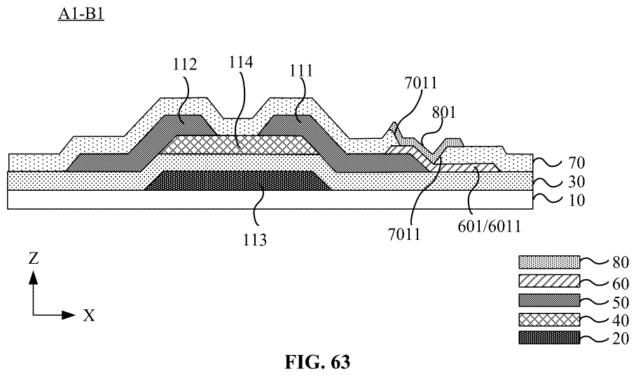

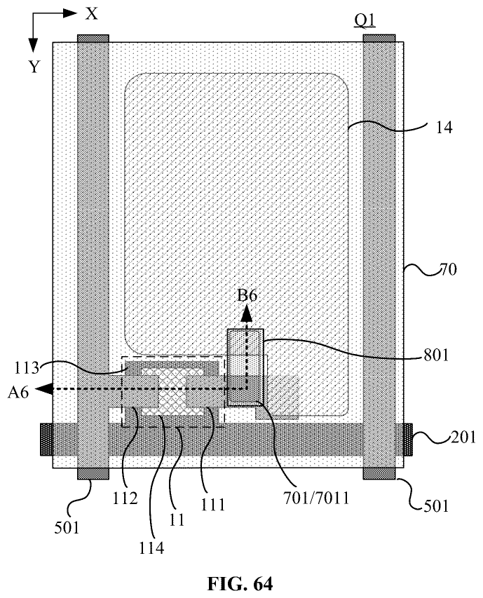

For example, FIG. 62 illustrates another enlarged structural schematic of a Q1 region in FIG. 1; and FIG. 63 illustrates a cross-sectional structural schematic of the array substrate along a cross-sectional line A5-B5 in FIG. 62. Referring to FIGS. 62-63, optionally, the array substrate may include the substrate 10, the source-drain electrode layer 50 and the first conductive layer 60 arranged in different layers, the first insulating layer 70, and the second conductive layer 80; the source-drain electrode layer 50 and the first conductive layer 60 may be both located on one side of the substrate 10; the source-drain electrode layer 50 may include the first electrode 111 and the second electrode 112 of the thin-film transistor 11; the first conductive layer 60 may include the pixel electrode 14; the pixel electrode 14 may be directly connected to the first electrode 111; the first insulating layer 70 may be located on the side of the source-drain electrode layer 50 and the first conductive layer 60 away from the substrate 10; the first insulating layer 70 may include the first through-hole 701; along the first direction Z, the first through-hole 701 may be overlapped with both the pixel electrode 14 and the first electrode 111; the first direction Z may be perpendicular to the plane where the substrate 10 is located; the first through-hole 701 may expose at least a portion of the pixel electrode 14; the second conductive layer 80 may be located on the side of the first insulating layer 70 away from the substrate 10; the second conductive layer 80 may include the first conductive sub-portion 801; and at least a portion of the first conductive sub-portion 801 may be located within the first through-hole 701 and in a contact with the pixel electrode 14.

Furthermore, referring to FIG. 63 and above description, optionally, the array substrate may further include the gate metal layer 20, the second insulating layer 30, and the active layer 40; the gate metal layer 20 may include the gate electrode 113 of the thin-film transistor 11; the active layer 40 may be located between the substrate 10 and the source-drain electrode layer 50; the active layer 40 may include the active layer pattern 114 of the thin-film transistor 11; and the first electrode 111 and the second electrode 112 may be in a direct contact with the active layer pattern 114.

The second insulating layer 30 may be configured as the gate insulating layer and may optionally be made of at least one of silicon oxide, silicon nitride, and silicon oxynitride.

Referring to FIGS. 62-63, the active layer pattern 114 of the thin-film transistor 11 may be the channel layer of the thin-film transistor 11, which may provide a channel for carrier flow. When the thin-film transistor is turned on for conduction, carriers may flow between the first electrode 111 and the second electrode 112 through the active layer pattern 114, thereby realizing the signal (data) transmission.

Optionally, the material of the active layer 40 may include any one of amorphous silicon, single crystal silicon, polycrystalline silicon, and metal oxide. For example, when the thin-film transistor 11 is a P-type transistor, the material of the active layer 40 may include polycrystalline silicon, such as low-temperature polysilicon (LTPS); and when the thin-film transistor 11 is an N-type transistor, the material of the active layer 40 may include a metal oxide, such as indium gallium zinc oxide (IGZO).

As described above, when the pixel electrode 14 is in a direct contact with the first electrode 111, the first conductive layer 60 where the pixel electrode 14 is located may be on the side of the source-drain electrode layer 50 where the first electrode 111 is located away from the substrate 10; or the source-drain electrode layer 50 where the first electrode 111 is located may be on the side of the first conductive layer 60 where the pixel electrode 14 is located away from the substrate. Hereinafter, the technical solutions of embodiments of the present disclosure are described based on the film layer design that the first conductive layer 60 where the pixel electrode 14 is located is on the side of the source-drain electrode layer 50 where the first electrode 111 is located away from the substrate 10.

Referring to in FIGS. 62-63, in one embodiment, the first insulating layer 70 and the second conductive layer 80 may be further configured on the side of the source-drain electrode layer 50 and the first conductive layer 60 away from the substrate 10. The first insulating layer 70 may include the first through-hole 701. Along the first direction Z, the first through-hole 701 may be overlapped with both the pixel electrode 14 and the first electrode 111; and may expose at least a portion of the pixel electrode 14. The second conductive layer 80 may include the first conductive sub-portion 801; and at least a portion of the first conductive sub-portion 801 may be located within the first through-hole 701 and in a contact with the pixel electrode 14.

The first insulating layer 70 may have passivation effect and protect underlying devices and circuits. As shown in FIGS. 62-63, in the first insulating layer 70, except a portion of the pixel electrode 14 exposed by the first through-hole 701, majority of the pixel electrode 14 may be covered by the first insulating layer 70. To balance the passivation effect and light transmittance of the first insulating layer 70, optionally, the material of the first insulating layer 70 may include polyparaxylene polymer, such as Parylene. Or silicon nitride, silicon oxide, or a composite material of silicon nitride and silicon oxide may be used for the material of the insulating layer 70.

Referring to FIG. 63, along the first direction Z, the first through-hole 701 may be overlapped with both the pixel electrode 14 and the first electrode 111. That is, the first through-hole 701 may be overlapped with both the pixel electrode 14 and the first electrode 111 along the first direction Z. Referring to FIG. 62, from a top view, the orthographic projection of the first through-hole 701 on the substrate may be overlapped with both the orthographic projection of the pixel electrode 14 and the orthographic projection of the first electrode 111 on the substrate. It should be noted that, along the first direction Z, the portion of the pixel electrode 14 overlapped with the first through-hole 701 may be or may not be overlapped with the portion of the first electrode 111 overlapped with the first through-hole 701, which may be not limited in embodiments of the present disclosure.

Referring to FIG. 63, the thickness of the first conductive layer 60 may be thinner than the thickness of the source-drain electrode layer 50. Therefore, for the solution that the pixel electrode 14 is on the first electrode 111 and in a direct contact with the first electrode 111, the pixel electrode 14 may need to extend (climb) to a certain height, which may pose a cracking risk and affect the connection reliability therebetween. In one embodiment, the first through-hole 701 may be configured in the first insulating layer 70, such that the first through-hole 701 may expose at least a portion of the pixel electrode 14. In addition, the first conductive sub-portion 801 may be then filled within the first through-hole 701, such that the first conductive sub-portion 801 may be in a contact with the pixel electrode 14. The first conductive sub-portion 801 may be used to improve the connection reliability between the first electrode 111 and the pixel electrode 14, thereby ensuring normal data signal transmission. Different overlapping configurations of the first through-hole 701, the first electrode 111, and the pixel electrode 14 are further described in detail hereinafter.

Referring to FIG. 62, the first electrode 111 may be divided into a portion which is in a contact with the pixel electrode 14 and a portion which is not in a contact with the pixel electrode 14. Similarly, the pixel electrode 14 may be divided into a portion which is in a contact with the first electrode 111 and a portion which is not in a contact with the first electrode 111. Referring to FIGS. 62-63, the pixel electrode 14 may be in a contact with a portion of the top surface and side surfaces of the first electrode 111 to form the contact region.

As an optional implementation manner, referring to FIGS. 62-63, optionally, the orthographic projection of the region, where the first through-hole 701 is located, on the substrate 10 may be overlapped with the orthographic projection of the contact region between the pixel electrode 14 and the first electrode 111 on the substrate 10. In such scenario, along the first direction Z, the first through-hole 701, the pixel electrode 14, and the first electrode 111 may be overlapped with each other, which may satisfy above-mentioned requirement that “the first through-hole 701 may be overlapped with both the pixel electrode 14 and the first electrode 111.” The label “7011” in FIG. 63 may indicate the position of the contour of the first through-hole 701, that is, the cutoff position of the first insulating layer 70 corresponding to the first through-hole 701; and same rule may be applied to the following description.

Furthermore, when the first through-hole 701, the pixel electrode 14, and the first electrode 111 are overlapped along the first direction Z, the pixel electrode 14 may be located above the first electrode 111 in the contact region between the pixel electrode 14 and the first electrode 111. Therefore, the first through-hole 701 may expose at least a portion of the pixel electrode 14. Whether the first through-hole 701 exposes the first electrode 111 may be not limited in embodiments of the present disclosure. FIG. 63 only illustrates that the first through-hole 701 exposes the portion of the pixel electrode 14 which is in a contact with the first electrode 111. Based on the above, the second conductive layer 80 may be configured, and the first conductive sub-portion 801 may be formed in the second conductive layer 80. At least a portion of the first conductive sub-portion 801 may be within the first through-hole 701, such that the first conductive sub-portion 801 may be in a contact with the pixel electrode 14. In such way, even if the portion of the pixel electrode 14 contacting the first electrode 111 breaks, the first conductive sub-portion 801 may connect the broken pixel electrode 14, thereby improving the connection reliability between the first electrode 111 and the pixel electrode 14. Furthermore, referring to FIG. 63, such solution may make the portion of the pixel electrode 14 contacting the first electrode 111 to be overlapped with the first conductive sub-portion 801 along the first direction Z, which may be equivalent to effectively increasing the thickness of the portion of the pixel electrode 14 contacting the first electrode 111, such that the connection impedance between the first electrode 111 and the pixel electrode may be increased, and the voltage drop (IR drop) of the data signal may be reduced.

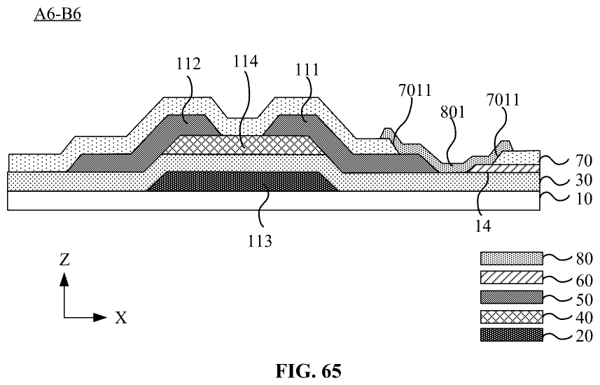

As another optional implementation manner, FIG. 64 illustrates another enlarged structural schematic of a Q1 region in FIG. 1; and FIG. 65 illustrates a cross-sectional structural schematic of the array substrate along a cross-sectional line A6-B6 in FIG. 64. Referring to FIGS. 64-65, in other embodiments, along the first direction Z, the portion of the pixel electrode 14 overlapped with the first through-hole 701 may be not overlapped with the portion of the first electrode 111 overlapped with the first through-hole 701. In such scenario, the first through-hole 701 may expose a portion of the pixel electrode 14 and a portion of the first electrode 111; and the first conductive sub-portion 801 may be in a contact with the pixel electrode 14 and the first electrode 111, respectively. In such way, in addition to direct contact between the first electrode 111 and the pixel electrode 14 to achieve electrical connection, the first electrode 111 may also be electrically connected to the pixel electrode 14 via the first conductive sub-portion 801, which may increase the connection path between the first electrode 111 and the pixel electrode 14. Even if the portion of the pixel electrode 14 contacting the first electrode 111 breaks, the first conductive sub-portion 801 may still maintain electrical connection between the first electrode 111 and the pixel electrode 14, which may reduce the risk of disconnection between the first electrode 111 and the pixel electrode 14 and improve the connection reliability of the first electrode 111 and the pixel electrode 14.

It should be noted that FIGS. 63 and 65 only illustrate that a portion of the first conductive sub-portion 801 is located within the first through-hole 701. In other embodiments, entire first conductive sub-portion 801 may also be located within the first through-hole 701, which may be not limited in embodiments of the present disclosure.

It should be noted that, for the solution of improving the connection reliability of the pixel electrode and the first electrode, the second conductive layer 80 may or may not include the common electrode, which may be not limited in embodiments of the present disclosure. When the second conductive layer 80 includes the common electrode, it may need to ensure that the first conductive sub-portion 801 is insulated from the common electrode.

Furthermore, when the second conductive layer 80 includes the common electrode, optionally, the material of both the first conductive layer 60 and the second conductive layer 80 may include transparent conductive materials, such as indium tin oxide.

As disclosed above, in embodiments of the present disclosure, when the pixel electrode in the first conductive layer is in a direct contact with the first electrode of the thin-film transistor, the first through-hole may be configured in the first insulating layer on the side of the source-drain electrode layer and the first conductive layer away from the substrate, such that the first through-hole may be overlapped with both the pixel electrode and the first electrode along the direction perpendicular to the plane of the substrate and expose at least a portion of the pixel electrode. The second conductive layer may be also configured on the side of the first insulating layer away from the substrate, and the first conductive sub-portion may be formed in the second conductive layer to fill the first through-hole, such that the first conductive sub-portion may be in a contact with the pixel electrode. In such way, the first conductive sub-portion may improve the connection reliability between the first electrode and the pixel electrode, thereby ensuring normal data signal transmission.

Hereinafter, based on the film layer design that the first conductive layer 60 is located on the side of the source-drain electrode layer 50 away from the substrate 10, the technical solutions of the present disclosure are further described using the example of the overlapping of the first through-hole 701, the pixel electrode 14, and the first electrode 111 along the first direction Z.

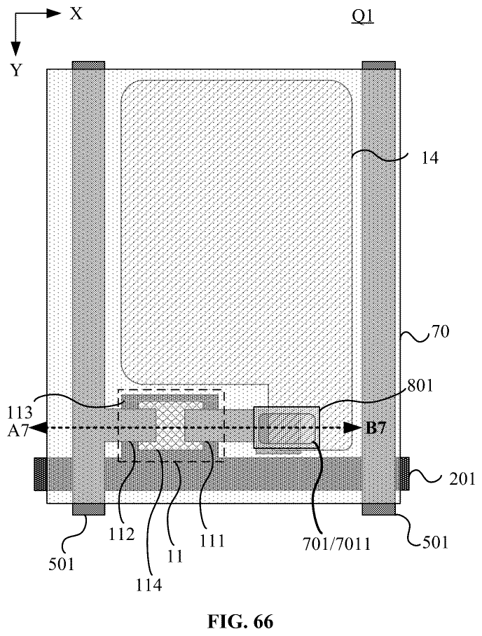

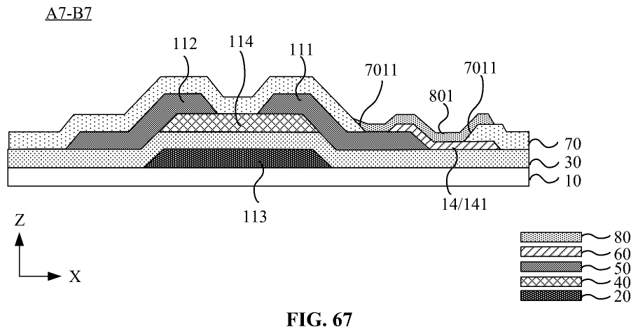

FIG. 66 illustrates another enlarged structural schematic of a Q1 region in FIG. 1; and FIG. 67 illustrates a cross-sectional structural schematic of an array substrate along a cross-sectional line A7-B7 in FIG. 66. Referring to FIGS. 66-67, optionally, the first through-hole 701 may expose at least a portion of the first electrode 111, and the first conductive sub-portion 801 may be in a contact with the first electrode 111. Such configuration may make the region of the first through-hole 701 to be relatively large, which may be beneficial for reducing the process precision needs of the first through-hole 701. Furthermore, the first conductive sub-portion 801 may be configured to be in a contact with both the first electrode 111 and the pixel electrode 14, which may be beneficial for further improving the connection reliability between the first electrode 111 and the pixel electrode 14.

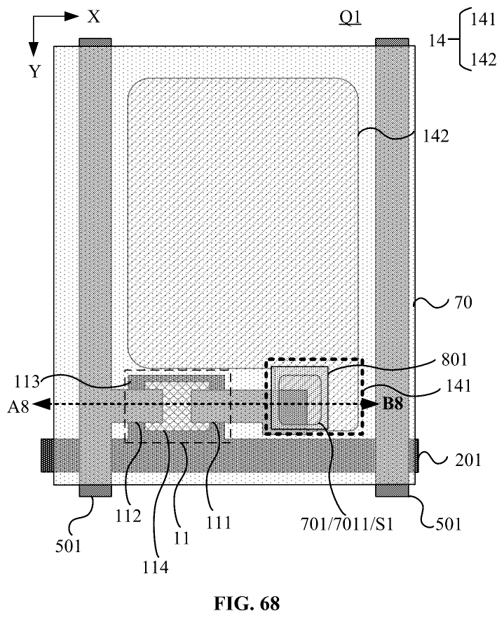

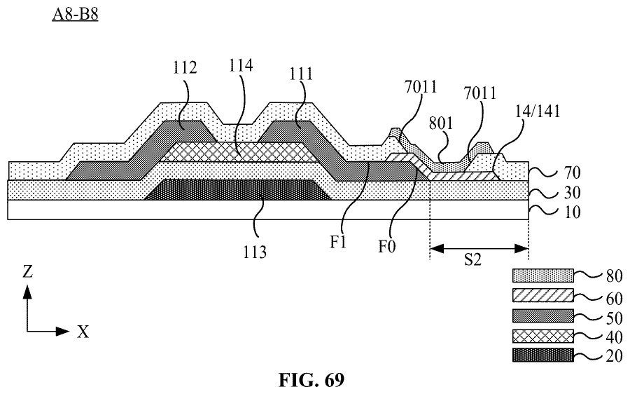

FIG. 68 illustrates another enlarged structural schematic of a Q1 region in FIG. 1; and FIG. 69 illustrates a cross-sectional structural schematic of the array substrate along a cross-sectional line A8-B8 in FIG. 68. Referring to FIGS. 68 and 69, the region exposed by the first through-hole 701 may be the first region S1, and the pixel electrode 14 may extend from the first region S1 to the region covered by the first insulating layer 70.

The region exposed by the first through-hole 701 may be the first region S1, that is, the region not covered by the first insulating layer 70. In one embodiment, the pixel electrode 14 may extend from the first region S1 to the region covered by the first insulating layer 70, which may indicate that the coverage region of the pixel electrode 14 is greater than the first region S1. In such scenario, the first through-hole 701 may only expose a portion of the pixel electrode 14 and may not expose the first electrode 111.

When forming the first through-hole 701 in the first insulating layer 70, a dry etching process may be used, and the etching gas may include oxygen. When the material of the first electrode 111 includes a metal such as molybdenum or aluminum, if the first through-hole 701 exposes the first electrode 111, oxygen may cause certain oxidation of the first electrode 111, which may increase the impedance of the first electrode 111. In one embodiment, the pixel electrode 14 may extend from the region exposed by the first through-hole 701 to the region covered by the first insulating layer 70, such that the first conductive layer 60 may be used as an etch blocking layer for the first insulating layer to protect the first electrode 111. For example, the pixel electrode 14 may be used to block oxygen from oxidizing the first electrode 111, thereby preventing an increase in the IR drop of the data signal due to increased impedance of the first electrode 111.

Referring to FIG. 69, optionally, the region exposed by the first electrode 111 may be the second region S2; the first electrode 111 may include a side surface F0 and a first surface F1 which are connected; the first surface F1 may be the surface of the first electrode 111 away from the substrate 10; the pixel electrode 14 may include a step connecting portion 141; the step connecting portion 141 may be in a contact with the first electrode 111 and extend from the second region S2 through the side surface F0 to the first surface F1; and along the first direction Z, the first conductive sub-portion 801 may be overlapped with the step connecting portion 141.

The region exposed by the first electrode 111, that is, the second region S2, may exemplarily refer to the region of the second insulating layer 30 not covered by the metal in the source-drain electrode layer 50 (e.g., the first electrode 111, the second electrode 112, and the data line 501).

Referring to FIG. 68, the pixel electrode 14 may include the step connecting portion 141 and a main portion 142 which are formed in a single piece. The main portion 142 may correspond to the light-transmitting region and be in the second region S2 of the second insulating layer 30. The step connecting portion 141 may be in a contact with the first electrode 111, which may be configured to connect the main portion 142 of the pixel electrode 14 to the first electrode 111. Therefore, the step connecting portion 141 may extend from the second region S2 to the first surface F1 of the first electrode 111 through the side surface F0 of the first electrode 111.

In one embodiment, the first conductive sub-portion 801 may be configured to be overlapped with the step connecting portion 141, the first conductive sub-portion 801 may cover at least a portion of the step connecting portion 141. For example, the first conductive sub-portion 801 may cover the position of the step connecting portion 141 that is in a contact with the side surface F0 (i.e., the slope extending position), thereby avoiding disconnection problem due to the slope crack of the pixel electrode 14, improving the connection reliability between the pixel electrode 14 and the first electrode 111 and ensuring normal data signal transmission.

Referring to FIG. 69, it should be noted that in the drawings of embodiments of the present disclosure described above, the contact area between the step connecting portion 141 and the first surface F1 of the first electrode 111 may be only for illustration and may be not limited in embodiments of the present disclosure. Referring to FIG. 69, in other embodiments, the step connecting portion 141 may continue to extend toward the direction of the active layer pattern 114 to cover more area of the first surface F1, which may increase the contact area between the first electrode 111 and the pixel electrode 14, reduce the connection impedance between the first electrode 111 and the pixel electrode 14, and lower the IR drop of the data signal. Accordingly, the opening area of the first through-hole 701 may be increased to increase the contact area between the first conductive sub-portion 801 and the pixel electrode 14, which may reduce the connection impedance between the first conductive sub-portion 801 and the pixel electrode 14.

As disclosed above, in above-mentioned embodiments, based on the first conductive layer 60 being located on the side of the source-drain electrode layer 50 away from the substrate, the solution of the present disclosure for improving the connection reliability between the pixel electrode and the first electrode is described in detail.

Based on the film layer design that the source-drain electrode layer 50 is located on the side of the first conductive layer 60 away from the substrate 10, the technical solutions of the present disclosure are further described in detail.

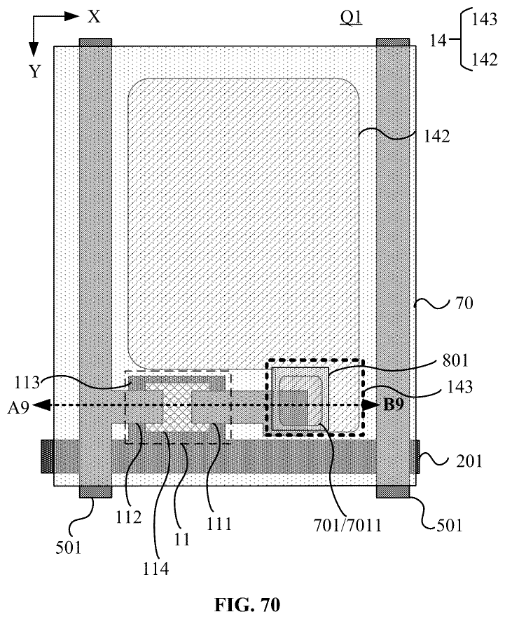

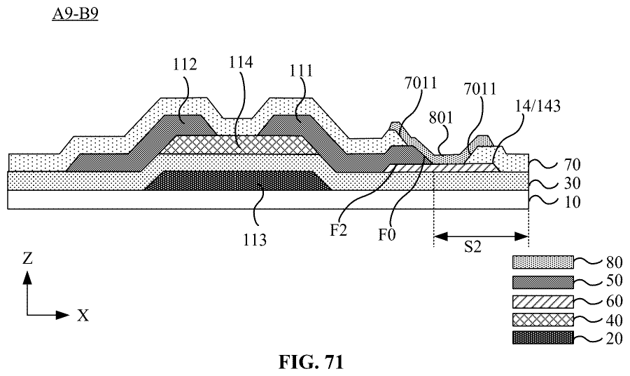

FIG. 70 illustrates another enlarged structural schematic of a Q1 region in FIG. 1; and FIG. 71 illustrates a cross-sectional structural schematic of the array substrate along a cross-sectional line A9-B9 in FIG. 70. Referring to FIGS. 70-71, when the source-drain electrode layer 50 is located on the side of the first conductive layer 60 away from the substrate 10, optionally, the first through-hole 701 may expose at least a portion of the first electrode 111 and also expose a portion of the pixel electrode 14; and the first conductive portion 801 may be in a contact with both the pixel electrode 14 and the first electrode 111.

When the source-drain electrode layer 50 is located on the side of the first conductive layer 60 away from the substrate 10, the pixel electrode 14 may be formed on the second insulating layer 30. In such way, the slope extending problem may not exist, but poor connection between the pixel electrode 14 and the first electrode 111 may occur due to process problems. In one embodiment, the first through-hole 701 may be configured in the first insulating layer 70, such that the first through-hole 701 may expose a portion of the pixel electrode 14 and a portion of the first electrode 111. In addition, the first conductive sub-portion 801 may be formed in the second conductive layer 80 to fill the first through-hole 701. In such way, the first conductive sub-portion 801 may be in a contact with the pixel electrode 14 and the first electrode 111, respectively; and the first conductive sub-portion 801 may improve the connection reliability between the first electrode 111 and the pixel electrode 14.

Referring to FIGS. 70-71, optionally, the region exposed by the first electrode 111 may be the second region S2; the first electrode 111 may include the side surface F0 and the second surface F2 connected to each other; the second surface F2 may be the surface of the first electrode 111 on the side closest to the substrate 10; the pixel electrode 14 may include a planar connecting portion 143; the planar connecting portion 143 may be in a contact with the first electrode 111 and extend from the second region S2 to the second surface F2; and the first conductive sub-portion 801 may be in a contact with the side surface F0 and the planar connecting portion 143, respectively.

For example, in one embodiment, the pixel electrode 14 may include the planar connecting portion 143 and the main portion 142. The main portion 142 may correspond to the light-transmitting region and be in the second region S2 of the second insulating layer 30. The planar connecting portion 143 may be in a contact with the first electrode 111, configured to connect the main portion 142 of the pixel electrode 14 to the first electrode 111. Therefore, the planar connecting portion 143 may extend from the second region S2 to the second surface F2 of the first electrode 111.

In one embodiment, the first conductive sub-portion 801 may be configured to be in a contact with the side surface F0 of the first electrode 111 and the planar connecting portion 143 of the pixel electrode 14, such that the first conductive sub-portion 801 may cover the connection portion of the first electrode 111 and the pixel electrode 14, for example, cover the side surface F0 of the first electrode 111 and a portion of the planar connecting portion 143 of the pixel electrode 14, which may provide protective covering for connection portion of the first electrode 111 and the pixel electrode 14, thereby improving the connection reliability of the pixel electrode 14 and the first electrode 111 and ensuring normal data signal transmission.

It should be noted that FIGS. 70-71 illustrate that the first through-hole 701, the first electrode 111, and the pixel electrode 14 are overlapped along the first direction Z, which may be taken as an example for illustration. In other embodiments, as shown in FIGS. 64-65, along the first direction Z, the portion of the pixel electrode 14 overlapped with the first through-hole 701 may be not overlapped with the portion of the first electrode 111 overlapped with the first through-hole 701. In such way, the first conductive sub-portion 801 may be configured to increase the connection path between the first electrode 111 and the pixel electrode 14. Even if poor connection occurs between the pixel electrode 14 and the first electrode 111, the first conductive sub-portion 801 may still maintain electrical connection between the first electrode 111 and the pixel electrode 14, thereby improving the connection reliability of the first electrode 111 and the pixel electrode 14.

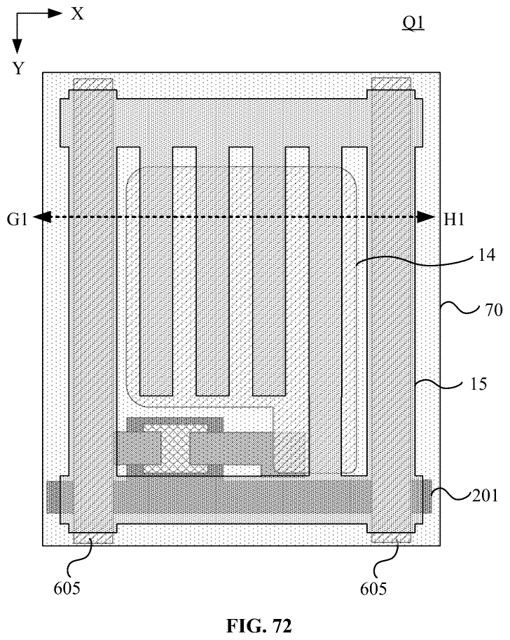

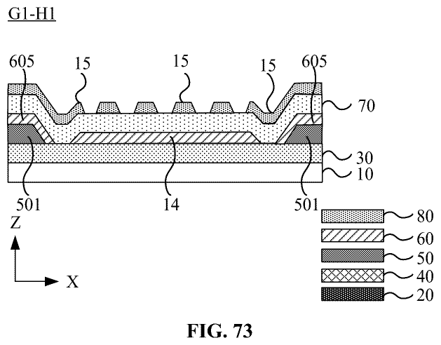

FIG. 72 illustrates another enlarged structural schematic of a Q1 region in FIG. 1; and FIG. 73 illustrates a cross-sectional structural schematic of an array substrate along a cross-sectional line G1-H1 in FIG. 72. Referring to FIGS. 72-73, the source-drain electrode layer 50 may include the data line 501. Optionally, the source-drain electrode layer 50 may be located between the substrate 10 and the first conductive layer 60; the source-drain electrode layer 50 may also include the data line 501; the first conductive layer 60 may also include the first pattern 605; and the first pattern 605 may be configured to be insulated from the pixel electrode 14 and cover the data line 501.

The first conductive layer 60 may be patterned using a wet etching process. The process flow may include the following. A complete layer of transparent conductive material may be formed first; a patterned photoresist may be then formed on the transparent conductive material layer, such that the conductive pattern to be retained in the transparent conductive material layer may be covered by the photoresist. Next, an etching solution (e.g., nitric acid) may be used to etch the transparent conductive material layer not covered by the photoresist. After etching, the photoresist may be removed to form the conductive pattern in the first conductive layer 60, such as the pixel electrode 14. In one embodiment, the first conductive layer 60 may be formed directly on the source-drain electrode layer 50. When the wet etching process is performed, due to process precision (e.g., the accuracy of controlling the etching time), the metal patterns (e.g., the data lines) which are electrically connected to the first conductive layer 60 and not needed in the source-drain electrode layer 50 may be in a contact with the etching solution after the first conductive layer above the metal patterns are removed, which may result in corrosion of the metal patterns to affect product reliability.

To avoid above-mentioned problem, in one embodiment, the first pattern 605 may be formed in the first conductive layer 60 to cover the data line 501, which may prevent corrosion of the data line 501 to ensure product reliability.

Similarly, when the source-drain electrode layer 50 further includes other metal patterns that are not originally needed to be electrically connected to the first conductive layer 60, accordingly, corresponding conductive patterns may also be formed in the first conductive layer 60 to cover the metal patterns and prevent corrosion by the etching solution, which may not be limited in embodiments of the present disclosure.

It is understood that the pixel electrode 14 and the first pattern 605 may be formed simultaneously during the patterning process of the first conductive layer 60.

It should be noted that in embodiments of the present disclosure, using the example of the second conductive layer 80 configured with the common electrode 15, FIGS. 72-73 illustrate the solution that the first conductive layer 60 may include the first pattern 605. In other embodiments, such solution may only involve improvements to the film layer of the first conductive layer 60 where the pixel electrode 14 is located, therefore the design solution may be also applicable even if the common electrode is not in the array substrate.

As disclosed above, above-mentioned embodiments provide a detailed description of the array substrate structure provided by the present disclosure, which may focus on improving the reliability of the through-holes, improving the connection reliability between the pixel electrodes and the thin-film transistors, and reducing the corrosion problems in the metal patterns in the source-drain electrode layers, such as the data lines. It should be noted that above-mentioned reliability improvement solutions may not affect or conflict with each other. The structural improvements to the array substrate proposed in above-mentioned embodiments for different reliability problems may be implemented separately or simultaneously, which may be not limited in embodiments of the present disclosure.

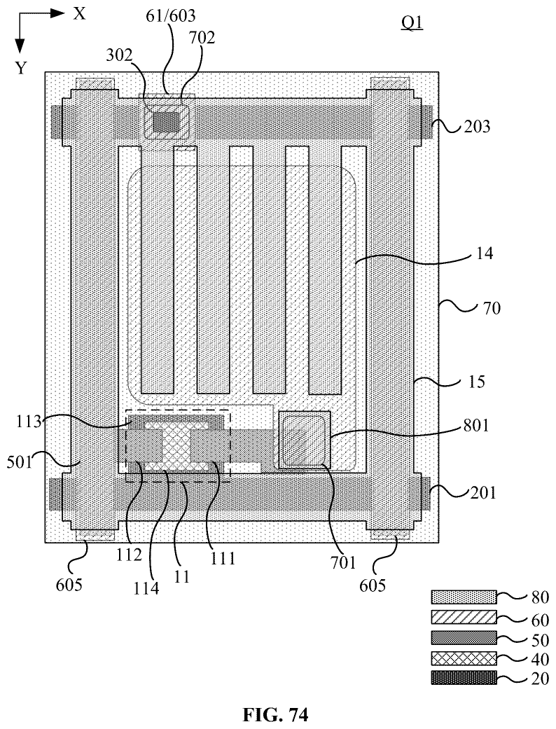

Exemplarily, FIG. 74 illustrates another enlarged structural schematic of a Q1 region in FIG. 1. Referring to FIG. 74, when the pixel electrode 14 is in the first conductive layer 60, the first conductive layer 60 may be located on the side of the source-drain electrode layer 50 away from the substrate, and the pixel electrode 14 may be in a direct contact with the first electrode 111 of the thin-film transistor 11. On the one hand, the blocking pattern 61 may be formed in the first conductive layer 60 corresponding to the position of the through hole (e.g., the first through hole 702 and/or the second through hole 302), thereby reducing the reliability problem at the through holes. For example, when the common electrode 15 in the second conductive layer 80 is electrically connected to the common signal line 203 in the gate metal layer 20 through the through hole, the slope cracking problem of the common electrode 15 may be reduced (the reliability problems of other through-holes refer to above description). On the other hand, the first through-hole 701 may be configured in the first insulating layer 70 corresponding to the connection position between the pixel electrode 14 and the first electrode 111; and the first conductive sub-portion 801 may be formed in the second conductive layer 80 to fill the first through-hole 701. The first conductive sub-portion 801 may be configured to improve the connection reliability between the pixel electrode 14 and the first electrode 111. Furthermore, the first pattern 605 may be formed in the first conductive layer 60. The first patterns 605 may be configured to cover the metal patterns that are not originally needed to be electrically connected to the first conductive layer 60 and belong to the data line 501, thereby reducing the corrosion problems associated with such metal patterns during the patterning process of the first conductive layer 60.

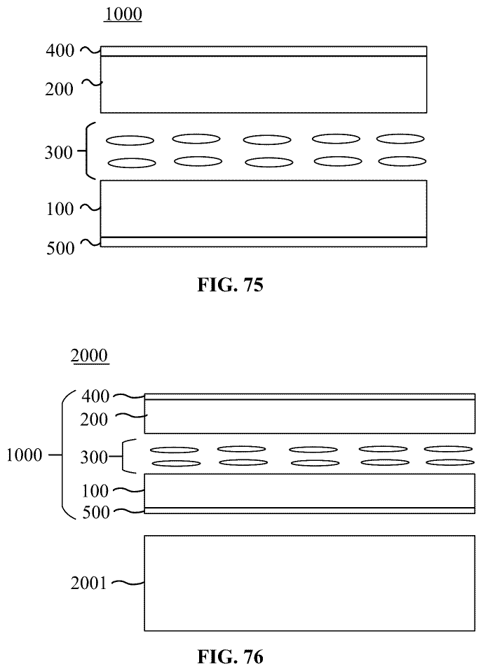

Based on same inventive concept, various embodiments of the present disclosure further provide a display panel. FIG. 75 illustrates a structural schematic of a display panel according to various embodiments of the present disclosure. Referring to FIG. 75, a display panel 1000 provided by embodiments of the present disclosure may include the array substrate 100 provided by any of above-mentioned embodiments of the present disclosure. The display panel 1000 may further include a counter substrate 200 and a liquid-crystal layer 300; and the liquid-crystal layer 300 may be located between the array substrate 100 and the counter substrate 200. In one embodiment, the display panel 1000 may further include an oppositely-disposed substrate and the liquid-crystal layer 300.

For example, the display panel 1000 provided in embodiments of the present disclosure may be a liquid-crystal display panel. The display panel 1000 provided in embodiments of the present disclosure may include the array substrate 100 provided in any of embodiments of the present disclosure. Therefore, the display panel 1000 may have same beneficial effects as above-mentioned array substrates, which may refer to the description in above-mentioned embodiment for details regarding the similarities and may not be described in detail herein.

As shown in FIG. 75, the display panel 1000 may further includes an upper polarizer 400 and a lower polarizer 500. The extension directions of the transmission axes of the upper polarizer 400 and the lower polarizer 500 may intersect, that is, the polarization directions of the light emitted by the upper polarizer 400 and the lower polarizer 500 may intersect, for example, may be orthogonal to each other. Under the backlight source provided by the backlight module, the liquid-crystal display panel may adjust the deflection angles of the liquid-crystal molecules by controlling the electric field between the pixel electrode and the common electrode. Combined with the polarization effect of the upper and lower polarizers on light, the light output (brightness) of the sub-pixels may be controlled, thereby displaying images.

The counter substrate 200 may be, for example, a color filter substrate. The color filter substrate may be configured with at least two different color resist units, which may transmit light of different colors, thereby achieving color display.

Based on same inventive concept, embodiments of the present disclosure further provide a display device. FIG. 76 illustrates a structural schematic of a display device according to various embodiments of the present disclosure. Referring to FIG. 76, a display device 2000 provided by embodiments of the present disclosure may include the display panel 1000 provided by above-mentioned embodiment and a backlight module 2001, where the backlight module 2001 may be configured to provide a backlight source for the display panel.

For example, the display device may be a liquid-crystal display device. Furthermore, the display device provided by embodiments of the present disclosure may be any electronic product with a display function, including but not limited to the following categories: mobile phones, televisions, laptops, desktop monitors, tablet computers, digital cameras, smart bracelets, smart glasses, in-vehicle displays, medical equipment, industrial control equipment, touch-screen interactive terminals and the like, which may not be limited in embodiments of the present disclosure.

It may be seen from above-mentioned embodiments that the present disclosure may at least achieve the following beneficial effects.

For the technical solutions in embodiments of the present disclosure, the first conductive layer may be configured between the first metal layer and the first insulating layer; the blocking pattern may be formed in the first conductive layer; the first type through-hole in the first insulating layer may expose at least a portion of the blocking pattern; and the conductive pattern may be in a contact with the blocking pattern at least through the first type through-hole. Furthermore, the conductive pattern, the blocking pattern, and the metal pattern may be overlapped with each other along the first direction; and the conductive pattern may be electrically connected to the blocking pattern and the metal pattern, respectively. In such way, the blocking pattern in the first conductive layer may configured as an etch blocking structure of the first insulating layer; and after dry etching the first insulating layer to form the first type through-hole, the blocking pattern may prevent the etching gas from further etching the portion of underlying film layer covered by the blocking pattern, thereby improving the reliability of the through-holes.

Furthermore, for the technical solutions in embodiments of the present disclosure, when the pixel electrode in the first conductive layer is in a direct contact with the first electrode of the thin-film transistor, the first through-hole may be configured in the first insulating layer on the side of the source-drain electrode layer and the first conductive layer away from the substrate, such that the first through-hole may be overlapped with both the pixel electrode and the first electrode along the direction perpendicular to the plane of the substrate and expose at least a portion of the pixel electrode. The second conductive layer may be also configured on the side of the first insulating layer away from the substrate, and the first conductive sub-portion may be formed in the second conductive layer to fill the first through-hole, such that the first conductive sub-portion may be in a contact with the pixel electrode. In such way, the first conductive sub-portion may improve the connection reliability between the first electrode and the pixel electrode, thereby ensuring normal data signal transmission.

Above-mentioned implementation manners or embodiments may not limit the protection scope of the present disclosure. Those skilled in the art should understand that various modifications, combinations, sub-combinations, and substitutions may be made based on design needs and other factors. Any modifications, equivalent substitutions, and improvements made within the spirit and principles of the present disclosure should be included in the protection scope of the present disclosure.

What is claimed is

1. An array substrate, comprising:
a substrate;
a first metal layer, on a side of the substrate, wherein the first metal layer includes metal patterns;
a first conductive layer, on a side of the first metal layer away from the substrate, wherein the first conductive layer includes blocking patterns;
a first insulating layer, on a side of the first conductive layer away from the substrate, wherein the first insulating layer is configured with first type through-holes; and a first type through-hole exposes at least a portion of a blocking pattern; and
a second conductive layer, on a side of the first insulating layer away from the substrate, wherein the second conductive layer includes conductive patterns; a conductive pattern is electrically connected to the blocking pattern and a metal pattern, respectively; the conductive pattern is in a contact with the blocking pattern at least through the first type through-hole; along a first direction, the conductive pattern, the blocking pattern, and the metal pattern are overlapped with each other; and the first direction is perpendicular to a plane of the substrate.

2. The array substrate according to claim 1, wherein:
the first metal layer includes a gate metal layer; the metal patterns include first type metal patterns at the gate metal layer;
the array substrate further includes a second insulating layer between the gate metal layer and the first conductive layer; the first type through-holes include first through-holes; the second insulating layer is configured with second through-holes; and a first through-hole is configured to be connected to a second through-hole;
the blocking patterns include first type blocking patterns, and the first through-hole exposes at least a portion of a first type blocking pattern; and
a portion of the conductive pattern is in a contact with and electrically connected to the first type blocking pattern at least via the first through-hole and electrically connected to a first type metal pattern via the first through-hole and the second through-hole which are connected to each other.

3. The array substrate according to claim 2, wherein:
at a position of at least a portion of a contour of the second through-hole, a cutoff position of the first type blocking pattern is substantially identical as a cutoff position of the second insulating layer.

4. The array substrate according to claim 2, wherein:
the first type blocking pattern is configured with a first opening; and along the first direction, the first opening is overlapped with the second through-hole; or
the first type blocking pattern is configured with a first notch; and along the first direction, the first notch is overlapped with the second through-hole.

5. The array substrate according to claim 2, wherein:
the conductive pattern includes a common electrode; the first type metal pattern includes a common signal line; and the first type blocking patterns include first blocking patterns; and
the common electrode is in a contact with and electrically connected to a first blocking pattern via the first through-hole and is in a contact with and electrically connected to the common signal line via the first through-hole and the second through-hole which are connected to each other.

6. The array substrate according to claim 2, wherein:
the array substrate further includes a source-drain electrode layer on a side of the gate metal layer away from the substrate; and the source-drain electrode layer includes a first electrode and a second electrode of a thin-film transistor; and
the first conductive layer includes a pixel electrode which is in a direct contact with the first electrode of the thin-film transistor.

7. The array substrate according to claim 6, wherein:
the conductive patterns include first conductive patterns; the first type metal patterns include first metal patterns; the source-drain electrode layer includes second metal patterns; and a first metal pattern and a second metal pattern are bridged by a first conductive pattern;
the first type blocking patterns include second blocking patterns; and a second blocking pattern is insulated from the pixel electrode; and
the first conductive pattern is in a contact with and electrically connected to the second blocking pattern via the first through-hole, and is in a contact with and electrically connected to the first metal pattern via the first through-hole and the second through-hole which are connected to each other.

8. The array substrate according to claim 7, wherein:
the source-drain electrode layer is between the gate metal layer and the first conductive layer;
along a direction in parallel with the plane of the substrate, the second blocking pattern extends from the position of at least a portion of the contour of the second through-hole to a region where the second metal pattern is located; and
the first conductive pattern is electrically connected to the second metal pattern via the second blocking pattern; the second blocking pattern is in a contact with the second metal pattern and the first conductive pattern, respectively; and along the first direction, the second metal pattern, the second blocking pattern, and the first conductive pattern are overlapped with each other.

9. The array substrate according to claim 8, wherein:
the first insulating layer is further configured with third through-holes; a third through-hole exposes a portion of the second blocking pattern; and the first conductive pattern is in a contact with the second blocking pattern via the third through-hole; and the first through-hole and the third through-hole are configured to be spaced apart from each other; or
along the direction in parallel with the plane of the substrate, the first through-hole extends from a region where the first metal pattern is located to the region where the second metal pattern is located.

10. The array substrate according to claim 7, wherein:
the first conductive layer is between the gate metal layer and the source-drain electrode layer;
along a direction in parallel with the plane of the substrate, the second blocking pattern extends from the position of at least a portion of the contour of the second through-hole to a region where the second metal pattern is located; and
the first conductive pattern is electrically connected to the second blocking pattern via the second metal pattern; the second metal pattern is in a contact with the first conductive pattern and the second blocking pattern, respectively; and along the first direction, the second blocking pattern, the second metal pattern, and the first conductive pattern are overlapped with each other.

11. The array substrate according to claim 10, wherein:
the first insulating layer is further configured with fourth through-holes; a fourth through-hole exposes a portion of the second metal pattern; and the first conductive pattern is in a contact with the second metal pattern via the fourth through-hole; and the first through-hole and the fourth through-hole are configured to be spaced apart from each other; or
along the direction in parallel with the plane of the substrate, the first through-hole extends from a region where the first metal pattern is located to the region where the second metal pattern is located.

12. The array substrate according to claim 1, wherein:
the first metal layer includes a source-drain electrode layer; the source-drain electrode layer includes a first electrode and a second electrode of a thin-film transistor; and the first conductive layer includes a pixel electrode which is in a direct contact with the first electrode of the thin-film transistor; and
the metal patterns include second type metal patterns in the source-drain electrode layer; the first type through-holes include fifth through-holes; the blocking patterns include second type blocking patterns; a fifth through-hole exposes a portion of a second type blocking pattern; the second type blocking pattern is in a contact with and electrically connected to a second type metal pattern, and in a contact with and electrically connected to the conductive pattern via the fifth through-hole.

13. The array substrate according to claim 1, wherein:
the first metal layer at least includes a source-drain electrode layer; the source-drain electrode layer includes a first electrode and a second electrode of a thin-film transistor; the metal patterns include third type metal patterns at the source-drain electrode layer; and a third type metal pattern is insulated from the first electrode and the second electrode of the thin-film transistor;
the array substrate further includes a third insulating layer between the source-drain electrode layer and the first conductive layer; the first type through-holes include sixth through-holes;
the third insulating layer is configured with seventh through-holes; and a sixth through-hole is configured to be connected to a seventh through-hole;
the blocking patterns include third type blocking patterns, and the sixth through-hole exposes at least a portion of a third type blocking pattern; and
a portion of the conductive pattern is in a contact with and electrically connected to the third type blocking pattern at least via the sixth through-hole and electrically connected to the third type metal pattern via the sixth through-hole and the seventh through-hole which are connected to each other.

14. An array substrate, comprising:
a substrate;
a source-drain electrode layer and a first conductive layer, configured in separate layers, wherein the source-drain electrode layer and the first conductive layer are both on a side of the substrate; the source-drain electrode layer includes a first electrode and a second electrode of a thin-film transistor; and the first conductive layer includes a pixel electrode which is in a direct contact with the first electrode of the thin-film transistor;
a first insulating layer, on a side of the source-drain electrode layer and the first conductive layer away from the substrate, wherein the first insulating layer includes first through-holes; along a first direction, a first through-hole is overlapped with both the pixel electrode and the first electrode of the thin-film transistor; the first direction is a direction perpendicular to a plane of the substrate; and the first through-hole exposes at least a portion of the pixel electrode; and
a second conductive layer, on a side of the first insulating layer away from the substrate, wherein the second conductive layer includes a first conductive sub-portion; at least a portion of the first conductive sub-portion is in the first through-hole and in a contact with the pixel electrode.

15. The array substrate according to claim 14, wherein:
the first conductive layer is on a side of the source-drain electrode layer away from the substrate.

16. The array substrate according to claim 15, wherein:
the first through-hole further exposes at least a portion of the first electrode, and the first conductive sub-portion is further in a contact with the first electrode.

17. The array substrate according to claim 14, wherein:
the source-drain electrode layer is on a side of the first conductive layer away from the substrate; and
the first through-hole further exposes at least a portion of the first electrode, and the first conductive sub-portion is further in a contact with the first electrode.

18. The array substrate according to claim 14, wherein:
the source-drain electrode layer is between the substrate and the first conductive layer; and
the source-drain electrode layer further includes data lines; the first conductive layer further includes first patterns; and a first pattern is insulated from the pixel electrode and covers a data line.

19. A display panel, comprising:
an array substrate, comprising:
a substrate;
a first metal layer, on a side of the substrate, wherein the first metal layer includes metal patterns;
a first conductive layer, on a side of the first metal layer away from the substrate, wherein the first conductive layer includes blocking patterns;
a first insulating layer, on a side of the first conductive layer away from the substrate, wherein the first insulating layer is configured with first type through-holes; and a first type through-hole exposes at least a portion of a blocking pattern;
a second conductive layer, on a side of the first insulating layer away from the substrate, wherein the second conductive layer includes conductive patterns; a conductive pattern is electrically connected to the blocking pattern and a metal pattern, respectively; the conductive pattern is in a contact with the blocking pattern at least through the first type through-hole; along a first direction, the conductive pattern, the blocking pattern, and the metal pattern are overlapped with each other; and the first direction is perpendicular to a plane of the substrate; and
a counter substrate and a liquid-crystal layer, wherein the liquid-crystal layer is between the array substrate and the counter substrate.

20. A display device, comprising:
the display panel according to claim 19.
